(19) United States
(12) Patent Application Publication
(10) Pub. No.: US 2024/0260365 A1
(43) Pub. Date: Aug. 1, 2024

(54) DISPLAY DEVICE, DISPLAY MODULE, ELECTRONIC DEVICE, AND METHOD FOR MANUFACTURING DISPLAY DEVICE

(71) Applicant: SEMICONDUCTOR ENERGY LABORATORY CO., LTD., Atsugi-shi, Kanagawa-ken (JP)

(72) Inventors: Takayuki IKEDA, Atsugi, Kanagawa (JP); Yoshiaki OIKAWA, Atsugi, Kanagawa (JP); Natsuko TAKASE, Isehara, Kanagawa (JP); Kensuke YOSHIZUMI, Atsugi, Kanagawa (JP)

(21) Appl. No.: 18/289,646

(22) PCT Filed: Apr. 28, 2022
(86) PCT No.: PCT/IB2022/053938

§ 371 Date: Nov. 6, 2023

(30) Foreign Application Priority Data
May 14, 2021 (JP) 2021-082218

(51) Int. Cl. H10K 59/35

(52) U.S. Cl. CPC H10K 59/351; H10K 59/353

(57) ABSTRACT

A high-resolution display device having a light detection function is provided. The display device includes first to fourth subpixels arranged to be adjacent to one another in this order in a first direction; the first subpixel and the second subpixel emit light of the same color; the third subpixel and the fourth subpixel detect light of the same color; the first subpixel includes a first light-emitting device and a first coloring layer overlapping with the first light-emitting device; the second subpixel includes a second light-emitting device and the first coloring layer overlapping with the second light-emitting device; the third subpixel includes a first light-receiving device; the fourth subpixel includes a second light-receiving device; the first light-emitting device and the second light-emitting device have a function of being driven independently; and the first light-receiving device and the second light-receiving device have a function of being driven independently.

### TECHNICAL FIELD

One embodiment of the present invention relates to a display device, a display module, and an electronic device. One embodiment of the present invention relates to a method for manufacturing a display device.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), a driving method thereof, and a manufacturing method thereof.

### BACKGROUND ART

Recent display devices have been expected to be applied to a variety of uses. Usage examples of large-sized display devices include a television device for home use (also referred to as TV or television receiver), digital signage, and a PID (Public Information Display). In addition, a smartphone and a tablet terminal each including a touch panel, and the like, are being developed as portable information terminals.

Furthermore, higher-resolution display devices have been required. For example, devices for virtual reality (VR), augmented reality (AR), substitutional reality (SR), or mixed reality (MR) are given as devices required by high-resolution display devices and have been actively developed.

Light-emitting apparatuses including light-emitting devices (also referred to as light-emitting elements) have been developed as display devices, for example. Light-emitting devices (also referred to as EL devices or EL elements) utilizing electroluminescence (hereinafter referred to as EL) have features such as ease of reduction in thickness and weight, high-speed response to input signals, and driving with a constant DC voltage power source, and have been used in display devices.

Patent Document 1 discloses a display device using an organic EL device (also referred to as organic EL element) for VR.

### [Reference]

### [Patent Document]

[Patent Document 1] PCT International Publication No. 2018/087625

### SUMMARY OF THE INVENTION

### Problems to be Solved by the Invention

An object of one embodiment of the present invention is to provide a high-resolution display device that has a light detection function. An object of one embodiment of the present invention is to provide a high-definition display device that has a light detection function. An object of one embodiment of the present invention is to provide a highly reliable display device that has a light detection function.

An object of one embodiment of the present invention is to provide a method for manufacturing a high-resolution display device that has a light detection function. An object of one embodiment of the present invention is to provide a method for manufacturing a high-definition display device that has a light detection function. An object of one embodiment of the present invention is to provide a method for manufacturing a highly reliable display device that has a light detection function. An object of one embodiment of the present invention is to provide a method for manufacturing a display device with a high yield.

Note that the description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention is a display device including a first subpixel, a second subpixel, a third subpixel, and a fourth subpixel, which are arranged to be adjacent to one another in this order in a first direction; the first subpixel and the second subpixel emit light of the same color; the third subpixel and the fourth subpixel detect light of the same color; the first subpixel includes a first light-emitting device and a first coloring layer overlapping with the first light-emitting device; the second subpixel includes a second light-emitting device and the first coloring layer overlapping with the second light-emitting device; the third subpixel includes a first light-receiving device; the fourth subpixel includes a second light-receiving device; the first light-emitting device and the second light-emitting device have a function of driving independently; and the first light-receiving device and the second light-receiving device have a function of being driven independently.

One embodiment of the present invention is a display device including a first subpixel, a second subpixel, a third subpixel, and a fourth subpixel, which are arranged to be adjacent to one another in this order in a first direction. The display device includes the first subpixel, a fifth subpixel, a sixth subpixel, and a seventh subpixel, which are arranged to be adjacent to one another in this order in a second direction; the first direction and the second direction intersect with each other; the first subpixel, the second subpixel, and the fifth subpixel emit light of a first color; the third subpixel and the fourth subpixel detect light of the same color; the sixth subpixel and the seventh subpixel emit light of a second color; the first color and the second color are different from each other; the first subpixel includes a first light-emitting device and a first coloring layer overlapping with the first light-emitting device; the second subpixel includes a second light-emitting device and the first coloring layer overlapping with the second light-emitting device; the third subpixel includes a first light-receiving device; the fourth subpixel includes a second light-receiving device; the fifth subpixel includes a third light-emitting device and the first coloring layer overlapping with the third light-emitting device; the sixth subpixel includes a fourth light-emitting device and a second coloring layer overlapping with the fourth light-emitting device; the seventh subpixel includes a fifth light-emitting device and the second coloring layer overlapping with the fifth light-emitting device; the first to fifth light-emitting devices have a function of emitting light of the same color; the first to fifth light-emitting devices have a function of being driven independently; the first light-receiving device and the second light-receiving device have a function of being driven independently; and the first coloring layer and the second coloring layer transmit light of different colors.

One embodiment of the present invention is a display device including a first subpixel, a second subpixel, a third subpixel, a fourth subpixel, a fifth subpixel, and a sixth subpixel; the first subpixel, the second subpixel, and the third subpixel emit light of the same color; the fourth subpixel, the fifth subpixel, and the sixth subpixel detect light of the same color; the first subpixel is adjacent to the second subpixel in a first direction and is adjacent to the third subpixel in a second direction; the fourth subpixel is adjacent to the fifth subpixel in the first direction and is adjacent to the sixth subpixel in the second direction; the first direction and the second direction intersect with each other; the first subpixel includes a first light-emitting device and a first coloring layer overlapping with the first light-emitting device; the second subpixel includes a second light-emitting device and the first coloring layer overlapping with the second light-emitting device; the third subpixel includes a third light-emitting device and the first coloring layer overlapping with the third light-emitting device; the fourth subpixel includes a first light-receiving device; the fifth subpixel includes a second light-receiving device; the sixth subpixel includes a third light-receiving device; the first to third light-emitting devices have a function of emitting light of the same color; the first to third light-emitting devices have a function of being driven independently; and the first to third light-receiving devices have a function of being driven independently.

The first light-emitting device preferably emits white light.

The first light-emitting device preferably includes an island-shaped first EL layer, and the second light-emitting device preferably includes an island-shaped second EL layer.

It is preferable that an insulating layer be further included in the display device having any of the above-described structures. The insulating layer preferably covers at least part of the side surface of the first EL layer and at least part of the side surface of the second EL layer. The insulating layer preferably includes an inorganic insulating layer in contact with at least part of the side surface of the first EL layer and part of the side surface of the second EL layer. The insulating layer preferably includes an organic insulating layer overlapping with at least part of the side surface of the first EL layer and part of the side surface of the second EL layer.

The first light-emitting device preferably includes a common layer over the first EL layer; the second light-emitting device preferably includes the common layer over the second EL layer; and the common layer preferably includes at least one of a hole-injection layer, a hole-transport layer, a hole-blocking layer, an electron-blocking layer, an electron-transport layer, and an electron-injection layer.

One embodiment of the present invention is a display module including the display device having any of the above-described structures and is, for example, a display module provided with a connector such as a flexible printed circuit (hereinafter referred to as an FPC) or a TCP (Tape Carrier Package), or a display module on which an integrated circuit (IC) is mounted by a COG (Chip On Glass) method, a COF (Chip On Film) method, or the like.

One embodiment of the present invention is an electronic device including the above-described display module and at least one of a housing, a battery, a camera, a speaker, and a microphone.

One embodiment of the present invention is a method for manufacturing a display device including forming a first pixel electrode, a second pixel electrode, a third pixel electrode, and a fourth pixel electrode so as to be arranged in this order in a first direction; forming a first film comprising a light-emitting layer over the first pixel electrode and over the second pixel electrode using a first metal mask; forming a second film comprising an active layer over the third pixel electrode and over the fourth pixel electrode using a second metal mask; processing the first film and the second film using a photolithography method to form a first layer over the first pixel electrode, a second layer over the second pixel electrode, a third layer over the third pixel electrode, and a fourth layer over the fourth pixel electrode; forming a common electrode over the first to fourth layers; and providing a coloring layer overlapping with the first pixel electrode and the second pixel electrode over the common electrode.

### Effect of the Invention

One embodiment of the present invention can provide a high-resolution display device that has a light detection function. One embodiment of the present invention can provide a high-definition display device that has a light detection function. One embodiment of the present invention can provide a highly reliable display device that has a light detection function.

One embodiment of the present invention can provide a method for manufacturing a high-resolution display device that has a light detection function. One embodiment of the present invention can provide a method for manufacturing a high-definition display device that has a light detection function. One embodiment of the present invention can provide a method for manufacturing a highly reliable display device that has a light detection function. One embodiment of the present invention can provide a method for manufacturing a display device with a high yield.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a top view illustrating an example of a display device. FIG. 1B is a cross-sectional view illustrating the example of the display device.

FIG. 2A to FIG. 2D are cross-sectional views illustrating examples of a display device.

FIG. 3A to FIG. 3C are cross-sectional views illustrating examples of a display device.

FIG. 4A to FIG. 4C are cross-sectional views illustrating examples of a display device.

FIG. 5A and FIG. 5B are cross-sectional views illustrating examples of a display device.

FIG. 6A to FIG. 6F are cross-sectional views illustrating examples of a display device.

FIG. 7A to FIG. 7C are top views illustrating an example of a method for manufacturing a display device.

FIG. 8A to FIG. 8D are top views illustrating an example of a method for manufacturing a display device.

FIG. 9A to FIG. 9D are cross-sectional views illustrating an example of a method for manufacturing a display device.

FIG. 10A to FIG. 10D are cross-sectional views illustrating an example of a method for manufacturing a display device.

FIG. 11A to FIG. 11C are cross-sectional views illustrating an example of a method for manufacturing a display device.

FIG. 12A to FIG. 12D are cross-sectional views illustrating an example of a method for manufacturing a display device.

FIG. 13 is a top view illustrating an example of a display device.

FIG. 14 is a top view illustrating an example of a display device.

FIG. 15 is a perspective view illustrating an example of a display device.

FIG. 16A is a cross-sectional view illustrating an example of a display device. FIG. 16B and FIG. 16C are cross-sectional views illustrating examples of transistors.

FIG. 17 is a cross-sectional view illustrating an example of a display device.

FIG. 18A to FIG. 18D are cross-sectional views illustrating examples of a display device.

FIG. 19A and FIG. 19B are perspective views illustrating an example of a display module.

FIG. 20A to FIG. 20C are cross-sectional views illustrating examples of a display device.

FIG. 21 is a cross-sectional view illustrating an example of a display device.

FIG. 22 is a cross-sectional view illustrating an example of a display device.

FIG. 23 is a cross-sectional view illustrating an example of a display device.

FIG. 24 is a cross-sectional view illustrating an example of a display device.

FIG. 25A to FIG. 25F are diagrams illustrating structure examples of a light-emitting device.

FIG. 26A to FIG. 26D are diagrams illustrating examples of electronic devices.

FIG. 27A to FIG. 27F are diagrams illustrating examples of electronic devices.

FIG. 28A to FIG. 28G are diagrams illustrating examples of electronic devices.

FIG. 29A to FIG. 29F are diagrams illustrating examples of electronic devices.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in the structures of the invention described below, the same portions or portions having similar functions are denoted by the same reference numerals in different drawings, and description of such portions is not repeated. The same hatching pattern is applied to portions having similar functions, and the portions are not especially denoted by reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that the term “film” and the term “layer” can be used interchangeably depending on the case or the circumstances. For example, the term “conductive layer” can be replaced with the term “conductive film”. As another example, the term “insulating film” can be replaced with the term “insulating layer”.

In this specification and the like, a device manufactured using a metal mask or an FMM (fine metal mask, a high resolution metal mask) may be referred to as a device having an FMM structure or a device having an MM (metal mask) structure. In this specification and the like, a device manufactured without using a metal mask or an FMM may be referred to as a device having an MML (metal maskless) structure.

### Embodiment 1

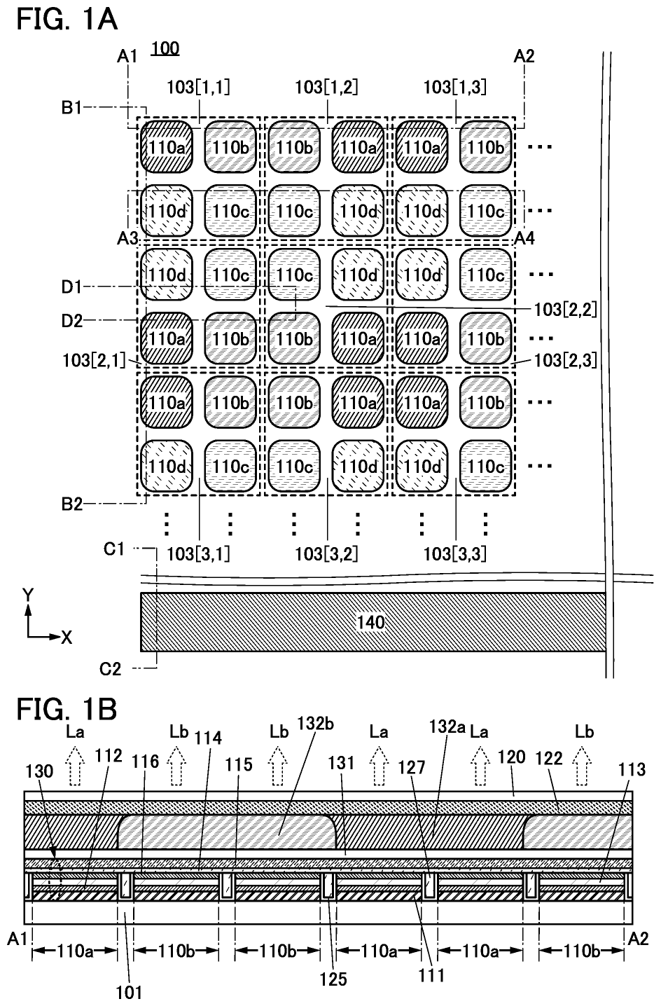

In this embodiment, a display device of one embodiment of the present invention is described with reference to FIG. 1 to FIG. 14.

The display device of one embodiment of the present invention includes a first subpixel, a second subpixel, a third subpixel, and a fourth subpixel, which are arranged to be adjacent to one another in this order in a first direction. The first subpixel and the second subpixel exhibit the same color and the third subpixel and the fourth subpixel detect light of the same color. The display device includes one light-emitting device or one light-receiving device for one subpixel, and light-emitting devices and light-receiving devices can be driven independently of each other.

In the display device of one embodiment of the present invention, when the first direction is the row direction, one row has a portion where a subpixel emitting light of a first color, a subpixel emitting light of a first color, a subpixel detecting light, and a subpixel detecting light are arranged to be adjacent to one another in this order. In addition, one column has a portion where the subpixel emitting light of the first color, the subpixel emitting light of the first color, a subpixel emitting light of a second color, and a subpixel emitting light of a second color are arranged to be adjacent to one another in this order, and another column has a portion where the subpixel detecting light, the subpixel detecting light, a subpixel emitting light of a third color, and a subpixel emitting light of a third color are arranged to be adjacent to one another in this order. In other words, the display device of one embodiment of the present invention has such portions that the subpixels emitting light of the same color are adjacent to each other not only in the one direction but also in both the row direction and the column direction. The display device of one embodiment of the present invention has such portions that the subpixels detecting light are adjacent to each other not only in the one direction but also in both the row direction and the column direction. Note that the first color, the second color, and the third color are colors different from each other.

Specifically, the display device of one embodiment of the present invention includes the first subpixel, the second subpixel, the third subpixel, and the fourth subpixel, which are arranged to be adjacent to one another in this order in the first direction, and the first subpixel, a fifth subpixel, a sixth subpixel, and a seventh subpixel, which are arranged to be adjacent to one another in this order in a second direction. The first direction and the second direction intersect with each other. For example, one of the first direction and the second direction can be a row direction and the other can be a column direction. The first subpixel, the second subpixel, and the fifth subpixel emit light of the first color, the third subpixel and the fourth subpixel detect light of the same color, and the sixth subpixel and the seventh subpixel emit light of the second color. The first color and the second color are colors different from each other. The display device includes one light-emitting device or one light-receiving device for one subpixel, and light-emitting devices and light-receiving devices can be driven independently of each other.

In this specification and the like, subpixels adjacent in a row direction denote subpixels having the following coordinates: coordinates (also referred to as X-coordinates) each representing a position in the row direction (also referred to as an X direction) are the same as the X-coordinate of a reference subpixel; and coordinates (also referred to as Y-coordinates) each representing a position in a column direction (also referred to as a Y direction) are shifted one column from the Y-coordinate of the reference subpixel. For example, a subpixel in the first row and the second column is adjacent, in the row direction, to a subpixel in the first row and the first column. Alternatively, subpixels adjacent in the column direction denote subpixels whose Y-coordinates are the same as that of the reference subpixel and whose X-coordinates are shifted one column from that of the reference subpixel. For example, a subpixel in the second row and the first column is adjacent, in the column direction, to the subpixel in the first row and the first column. The same expression is sometimes also applied to components other than subpixels as long as they are arranged in matrix.

In the display device of one embodiment of the present invention, each subpixel having a light-emitting function includes a light-emitting device emitting light of the same color and a coloring layer overlapping with the light-emitting device. As the light-emitting device, a light-emitting device emitting white light is preferably used, for example. Coloring layers that can transmit visible light of different colors are provided for subpixels, whereby full-color display can be performed.

In the display device of one embodiment of the present invention, each subpixel having a light detection function includes a light-receiving device.

For separately forming a light-emitting device and a light-receiving device for subpixels, at least a light-emitting layer of the light-emitting device and an active layer (also referred to as a photoelectric conversion layer) of the light-receiving device are preferably formed to have an island shape.

For example, an island-shaped light-emitting layer and an island-shaped active layer can be formed by a vacuum evaporation method using a metal mask. However, this method causes a deviation from the designed shape and position of the island-shaped light-emitting layer and the island-shaped active layer due to various influences such as the accuracy of the metal mask, the positional deviation between the metal mask and a substrate, a warp of the metal mask, and the vapor-scattering-induced expansion of outline of the formed film; accordingly, it is difficult to achieve high resolution and high aperture ratio of the display device. In addition, the outline of the layer may blur during vapor deposition, whereby the thickness of an end portion may be reduced. That is, the thickness of the island-shaped light-emitting layer and the island-shaped active layer may vary from area to area. In the case of manufacturing a display device with a large size, high definition, or high resolution, the manufacturing yield might be reduced because of low dimensional accuracy of the metal mask and deformation due to heat or the like.

In view of the above, in manufacturing the display device of one embodiment of the present invention, a pixel electrode is formed for each subpixel, and then, a light-emitting layer and an active layer are formed by a vacuum evaporation method using a metal mask. Specifically, a light-emitting layer is formed across a plurality of pixel electrodes positioned in a region corresponding to the subpixel having a light-emitting function. An active layer is also formed across a plurality of pixel electrodes positioned in a region corresponding to the subpixel having a light detection function. After that, the light-emitting layer and the active layer are processed by a photolithography method, for example, so that one island-shaped light-emitting layer or one island-shaped active layer is formed per pixel electrode. Thus, the light-emitting layer and the active layer can be divided into island-shaped light-emitting layer or island-shaped active layer for respective subpixels. For example, in the case where a plurality of subpixels emitting light of the same color are divided into four, the row direction is divided into two and the column direction is divided into two.

Thus, the island-shaped light-emitting layer and the island-shaped active layer manufactured in the manufacturing method of the display device of one embodiment of the present invention are not only formed using a metal mask having a fine pattern but also processed. Specifically, the island-shaped light-emitting layer and the island-shaped active layer are divided and processed into layers with a smaller size by a photolithography method or the like. Thus, the size of the island-shaped light-emitting layer and the island-shaped active layer can each be made smaller than the size of the layers formed with use of a metal mask. Accordingly, a high-resolution display device or a display device with a high aperture ratio, which has been difficult to achieve, can be manufactured.

The small number of times of processing of the light-emitting layer and the active layer with a photolithography method is preferable because a reduction in manufacturing cost and an improvement of manufacturing yield become possible. In the method for manufacturing the display device of one embodiment of the present invention, both of the light-emitting layer and the active layer can be processed at a time with a photolithography method; thus, the display device can be manufactured with high yield.

In addition, as described above, in a vacuum evaporation method using a metal mask, for example, the thicknesses of the end portions of the light-emitting layer and the active layer are reduced in some cases. In contrast, in the method for manufacturing the display device, the end portions of the light-emitting layer and the active layer, which are formed by a vacuum evaporation method using a metal mask, can be removed by processing using a photolithography method. Accordingly, the display device of one embodiment of the present invention can be a display device in which the light-emitting layer and the active layer each have a uniform thickness, specifically, a display device whose difference between the thickness of the center portion and the thickness of the end portion is small in the light-emitting layer and the active layer.

It is difficult to set the distance between adjacent light-emitting devices, the distance between adjacent light-receiving devices, and the distance between adjacent light-emitting device and the light-receiving device to be less than 10 μm with a formation method using a metal mask, for example. However, with the above method, the distance can be decreased to be less than 10 μm, less than or equal to 5 μm, less than or equal to 3 μm, less than or equal to 2 μm, or less than or equal to 1 μm. For example, with use of an exposure tool for LSI, the distance can be decreased to be less than or equal to 500 nm, less than or equal to 200 nm, less than or equal to 100 nm, or less than or equal to 50 nm. Accordingly, the area of a non-light-emitting region that could exist between two light-emitting devices can be significantly reduced, for example, and the aperture ratio can be close to 100%. For example, the aperture ratio is higher than or equal to 50%, higher than or equal to 60%, higher than or equal to 70%, higher than or equal to 80%, or higher than or equal to 90%; that is, an aperture ratio lower than 100% can be achieved.

Furthermore, a pattern of the light-emitting layer itself and the active layer itself (also referred to as processing size) can be made much smaller than that in the case of using a metal mask. For example, in the case of using a metal mask for forming the light-emitting layer and the active layer separately, a variation in the thickness occurs between the center and the edge of the light-emitting layer or the active layer. This causes a reduction in an effective area that can be used as a light-emitting region or a light-receiving region with respect to the area of the light-emitting layer or the active layer. In contrast, in the above manufacturing method, the film formed to have a uniform thickness is processed, so that island-shaped light-emitting layer and island-shaped active layer can be formed to have a uniform thickness. Accordingly, even with a fine pattern, almost the all area can be used as a light-emitting region or a light-receiving region. Thus, a display device having both a high resolution and a high aperture ratio can be manufactured.

It is not necessary to form separate light-emitting layers for a plurality of subpixels having a light-receiving function when light-emitting devices in the subpixels emit light of the same color. Thus, a layer other than a pixel electrode included in the light-emitting device (e.g., a light-emitting layer) can be common between (can be shared by) a plurality of subpixels. However, some layers included in the light-emitting device have relatively high conductivity; when such a layer having high conductivity is shared by a plurality of subpixels, leakage current might be generated between the subpixels. Particularly when the increase in resolution or aperture ratio of a display device reduces the distance between subpixels, the leakage current might become too large to ignore and cause a decrease in display quality of the display device or the like. In view of the above, in the display device of one embodiment of the present invention, at least part of the light-emitting device is formed to have an island shape in each subpixel having a light-receiving function. This enables the display device to achieve both high resolution and high display quality.

Furthermore, in the method for manufacturing the display device of one embodiment of the present invention, it is preferable to form a sacrificial layer (which may be called a mask layer) over a layer including a light-emitting layer (which can also be referred to as an EL layer or part of an EL layer). Then, a resist mask is formed over the sacrificial layer, and the EL layer and the sacrificial layer are processed using the resist mask, whereby an island-shaped EL layer is preferably formed.

Provision of a sacrificial layer over an EL layer can reduce damage to the EL layer during a manufacturing step of the display device and increase the reliability of the light-emitting device.

In the same manner, provision of a sacrificial layer over a layer constituting a light-receiving device which includes an active layer can reduce damage to the active layer during a manufacturing step of the display device and increase the reliability of the light-receiving device.

The island-shaped EL layer includes at least the light-emitting layer and preferably includes a plurality of layers. Specifically, one or more layers are preferably formed over the light-emitting layer. A layer between the light-emitting layer and the sacrificial layer can inhibit the light-emitting layer from being exposed on the outermost surface during the manufacturing step of the display device and can reduce damage to the light-emitting layer. Thus, the reliability of the light-emitting device can be increased. Thus, the island-shaped EL layer preferably includes the light-emitting layer and a carrier-transport layer (an electron-transport layer or a hole-transport layer) over the light-emitting layer.

In the similar manner, in the light-receiving device, a layer between the active layer and the sacrificial layer can inhibit the active layer from being exposed on the outermost surface during the manufacturing step of the display device and can reduce damage to the active layer. Thus, the reliability of the light-receiving device can be increased.

Note that in the light-emitting device, all layers included in the EL layer are not necessarily formed into island shapes, and some layers can be shared by (are common between) a plurality of light-emitting devices. Examples of layers in the EL layer include a light-emitting layer, carrier-injection layers (a hole-injection layer and an electron-injection layer), carrier-transport layers (a hole-transport layer and an electron-transport layer), carrier-blocking layers (a hole-blocking layer and an electron-blocking layer), and the like. In the method for manufacturing the display device of one embodiment of the present invention, some of the layers included in the EL layer are formed to have an island shape for each subpixel, and then, at least part of the sacrificial layer is removed and the other layer(s) included in the EL layer (e.g., a carrier-injection layer) and a common electrode (also referred to as an upper electrode) can be formed as shared layers by the plurality of light-emitting devices.

In contrast, the carrier-injection layer is often a layer having relatively high conductivity in the EL layer. Therefore, when the carrier-injection layer is in contact with the side surface of the island-shaped EL layer or the side surface of the pixel electrode, the light-emitting device might be short-circuited. Note that also in the case where the carrier-injection layer is formed in an island shape and the common electrode is formed to be shared by the plurality of light-emitting devices, the light-emitting device might be short-circuited when the common electrode is in contact with the side surface of the EL layer or the side surface of the pixel electrode.

Thus, the display device of one embodiment of the present invention includes an insulating layer covering at least the side surface of the island-shaped light-emitting layer. Thus, at least some layers in the island-shaped EL layer and the pixel electrode can be inhibited from being in contact with the carrier-injection layer or the common electrode. Hence, a short circuit of the light-emitting device is inhibited, and the reliability of the light-emitting device can be increased.

The insulating layer is preferably provided to cover the side surface of the island-shaped active layer. Accordingly, a short circuit in a light-receiving device can also be inhibited, leading to an improvement in the reliability of the light-receiving device.

Moreover, providing the insulating layer can fill the space between the adjacent island-shaped EL layers; hence, the formation surface of a layer (e.g., the carrier-injection layer or the common electrode) provided over the island-shaped EL layer has less unevenness and can be flatter. Consequently, the coverage of the carrier-injection layer or the common electrode can be increased. As a result, disconnection of the common electrode can be prevented.

Note that in this specification and the like, disconnection refers to a phenomenon in which a layer, a film, or an electrode is split because of the shape of the formation surface (e.g., a level difference).

The insulating layer can be provided in contact with the island-shaped EL layer. Thus, the EL layer can be prevented from being peeled off. When the insulating layer and the island-shaped EL layer are in close contact with each other, an effect of fixing the adjacent island-shaped EL layers by or attaching the adjacent island-shaped EL layers to the insulating layer can be attained. Furthermore, the insulating layer inhibits moisture from entering the interface between the pixel electrode and the EL layer, so that peeling off the EL layer can be prevented. Thus, the reliability of the light-emitting device can be increased. The manufacturing yield of the light-emitting device can be increased.

The insulating layer preferably has a function of a barrier insulating layer against at least one of water and oxygen. Alternatively, the insulating layer preferably has a function of inhibiting the diffusion of at least one of water and oxygen. Alternatively, the insulating layer preferably has a function of capturing or fixing (also referred to as gettering) at least one of water and oxygen.

Note that in this specification and the like, a barrier insulating layer refers to an insulating layer having a barrier property. A barrier property in this specification and the like means a function of inhibiting diffusion of a targeted substance (also referred to as having low permeability). Alternatively, a barrier property refers to a function of capturing or fixing (also referred to as gettering) a targeted substance.

When the insulating layer has a function of the barrier insulating layer or a gettering function, entry of impurities (typically, at least one of water and oxygen) that would diffuse into the light-emitting devices and the light-receiving devices from the outside can be inhibited. With this structure, a highly reliable light-emitting device, a highly reliable light-receiving device, and a highly reliable display device can be provided.

The display device of one embodiment of the present invention includes a pixel electrode functioning as an anode; an island-shaped hole-injection layer, an island-shaped hole-transport layer, an island-shaped light-emitting layer, and an island-shaped electron-transport layer that are provided in this order over the pixel electrode; an insulating layer provided to cover side surfaces of the hole-injection layer, the hole-transport layer, the light-emitting layer, and the electron-transport layer; an electron-injection layer provided over the electron-transport layer; and a common electrode that is provided over the electron-injection layer and functions as a cathode.

Alternatively, the display device of one embodiment of the present invention includes a pixel electrode functioning as a cathode; an island-shaped electron-injection layer, an island-shaped electron-transport layer, an island-shaped light-emitting layer, and an island-shaped hole-transport layer that are provided in this order over the pixel electrode; an insulating layer provided to cover side surfaces of the electron-injection layer, the electron-transport layer, the light-emitting layer, and the hole-transport layer; a hole-injection layer provided over the hole-transport layer; and a common electrode that is provided over the hole-injection layer and functions as an anode.

Alternatively, the display device of one embodiment of the present invention includes a pixel electrode, a first light-emitting unit over the pixel electrode, a charge-generation layer (also referred to as an intermediate layer) over the first light-emitting unit, a second light-emitting unit over the charge-generation layer, an insulating layer provided to cover side surfaces of the first light-emitting unit, the charge-generation layer, and the second light-emitting unit, and a common electrode provided over the second light-emitting unit. Note that a layer common to light-emitting devices of different colors may be provided between the second light-emitting unit and the common electrode.

The hole-injection layer, the electron-injection layer, and the charge-generation layer, for example, often have relatively high conductivity in the EL layer. Since the side surfaces of these layers are covered with the insulating layer in the display device of one embodiment of the present invention, these layers can be inhibited from being in contact with the common electrode or the like. Hence, a short circuit of the light-emitting device is inhibited, and the reliability of the light-emitting device can be increased.

The insulating layer that covers the side surface of the island-shaped EL layer may have a single-layer structure or a stacked-layer structure.

For example, an insulating layer having a single-layer structure using an inorganic material can be used as a protective insulating layer for the EL layer. In this way, the reliability of the display device can be increased.

When the insulating layer has a stacked-layer structure, the first layer of the insulating layer is preferably formed using an inorganic insulating material because it is formed in contact with the EL layer. In particular, the first layer of the insulating layer is preferably formed by an atomic layer deposition (ALD) method, by which damage due to deposition is small.

Alternatively, an inorganic insulating layer is preferably formed by a sputtering method, a chemical vapor deposition (CVD) method, or a plasma-enhanced chemical vapor deposition (PECVD) method, which have higher deposition speed than an ALD method. In that case, a highly reliable display device can be manufactured with high productivity. The second layer of the insulating layer is preferably formed using an organic material to fill a depressed portion formed by the first layer of the insulating layer.

For example, an aluminum oxide film formed by an ALD method can be used as the first layer of the insulating layer, and an organic resin film can be used as the second layer of the insulating layer.

In the case where the side surface of the EL layer and the organic resin film are in direct contact with each other, the EL layer might be damaged by an organic solvent or the like that might be contained in the organic resin film. When the first layer of the insulating layer is formed using an inorganic insulating film such as an aluminum oxide film by an ALD method, a structure in which the organic resin film and the side surface of the EL layer are not in direct contact with each other can be obtained. Thus, the EL layer can be inhibited from being dissolved by the organic solvent, for example.

In the display device of one embodiment of the present invention, it is not necessary to provide an insulating layer that covers the end portion of the pixel electrode between the pixel electrode and the EL layer; thus, the distance between adjacent light-emitting devices can be made extremely small. Thus, a display device with higher resolution or higher definition can be achieved. In addition, a mask for forming the insulating layer is not needed, which leads to a reduction in manufacturing cost of the display device.

Furthermore, light emitted by the EL layer can be extracted efficiently with a structure where an insulating layer covering the end portion of the pixel electrode is not provided between the pixel electrode and the EL layer, i.e., a structure where an insulating layer is not provided between the pixel electrode and the EL layer. Therefore, the display device of one embodiment of the present invention can significantly reduce the viewing angle dependence. A reduction in the viewing angle dependence leads to an increase in visibility of an image on the display device. For example, in the display device of one embodiment of the present invention, the viewing angle (the maximum angle with a certain contrast ratio maintained when the screen is seen from an oblique direction) can be more than or equal to 100° and less than 180°, preferably more than or equal to 150° and less than or equal to 170°. Note that the viewing angle refers to that in both the vertical direction and the horizontal direction.

### Structure Example 1 of Display Device

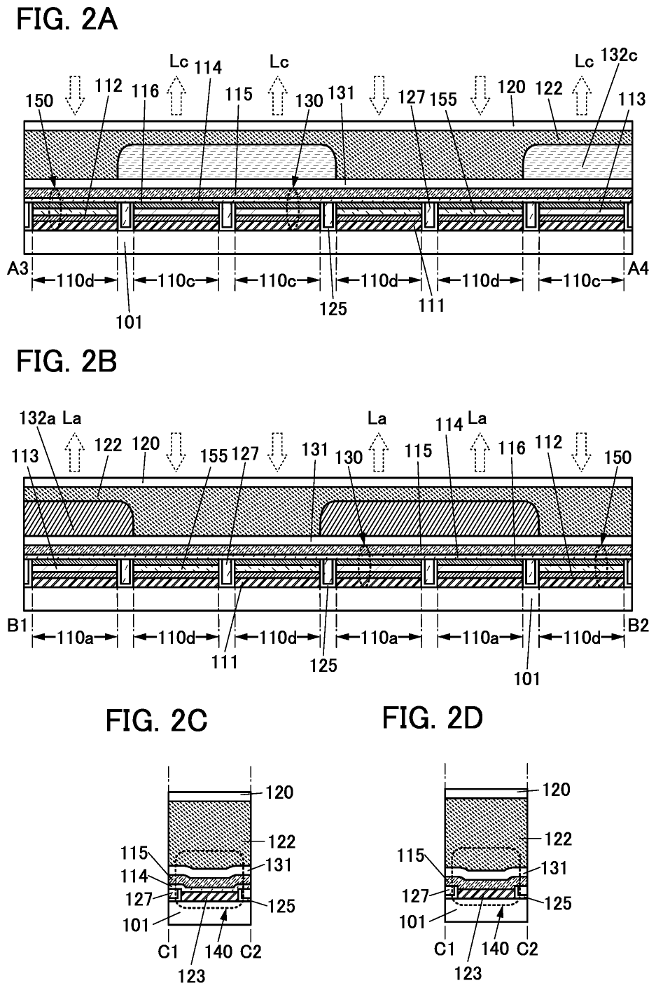

FIG. 1A, FIG. 1B, and FIG. 2A to FIG. 2D illustrate a display device of one embodiment of the present invention.

FIG. 1A is a top view of a display device 100. The display device 100 includes a display portion in which a plurality of pixels 103 are arranged, and a connection portion 140 outside the display portion. A plurality of subpixels are arranged in matrix in the display portion. FIG. 1A illustrates subpixels arranged in six rows and six columns, which form pixels in three rows and three columns. The connection portion 140 can also be referred to as a cathode contact portion.

The pixel 103 illustrated in FIG. 1A includes four subpixels, a subpixel 110a, a subpixel 110b, a subpixel 110c, and a subpixel 110d.

Three of the subpixel 110a, the subpixel 110b, the subpixel 110c, and the subpixel 110d are subpixels having a light-emitting function, and remaining one of them is a subpixel having a light detection function. This embodiment describes an example when the subpixel 110a emits light La of the first color, the subpixel 110b emits light Lb of the second color, the subpixel 110c emits light Lc of the third color, and the subpixel 110d has a light detection function.

The subpixels 110a, 110b, and 110c emit light of different colors from one another. As the subpixels 110a, 110b, and 110c, subpixels of three colors of red (R), green (G), and blue (B) or subpixels of three colors of yellow (Y), cyan (C), and magenta (M) can be given, for example. The number of types of subpixels having a light-emitting function is not limited to three, and four or more types of subpixels may be used. As the four subpixels, subpixels of four colors of R, G, B, and white (W), subpixels of four colors of R, G, B, and Y, or four subpixels of R, G, B, and infrared light (IR) can be given, for example.

The top surface shapes of the subpixels illustrated in FIG. 1A correspond to the top surface shapes of light-emitting regions.

The range of the circuit layout for forming the subpixels is not limited to the range of the subpixels illustrated in FIG. 1A and may be placed outside the subpixels. For example, part or all of transistors included in the subpixel 110a in the pixel 103[2,2] may be positioned out of the range of the subpixel 110a illustrated in FIG. 1A. For example, the transistor included in the subpixel 110a in the pixel 103[2,2] may have a portion positioned within the range of the subpixel 110a in the pixel 103[2,3], may have a portion positioned within the range of one or both of the subpixel 110b and the subpixel 110d in the pixel 103[2,2], or may have a portion positioned within the range of the subpixel 110a in the pixel 103[3,2].

The subpixel 110d has a light detection function. The subpixel 110d has a function of detecting one or both of visible light and infrared light.

Provision of the subpixel 110d in the display portion of the display device 100 allows the display device 100 to have one or both of an image capturing function and a sensing function in addition to an image display function. The display portion included in the display device 100 can be used for an image sensor or a touch sensor.

For example, image capturing for personal authentication with the use of a fingerprint, a palm print, the iris, the shape of a blood vessel (including the shape of a vein and the shape of an artery), a face, or the like is possible by using the subpixel 110d.

The subpixel 110d can be used in a touch sensor (also referred to as a direct touch sensor), a near touch sensor (also referred to as a hover sensor, a hover touch sensor, a contactless sensor, or a touchless sensor), or the like.

Here, a touch sensor or a near touch sensor can detect an approach or touch of an object (e.g., a finger, a hand, or a pen).

A touch sensor can detect an object when a display device or an electronic device including the display device and the object come in direct contact with each other. A near touch sensor can detect an object even when the object does not touch a display device or an electronic device. For example, a display device is preferably capable of detecting an object positioned in the range of 0.1 mm to 300 mm inclusive, further preferably 3 mm to 50 mm inclusive from the display device. This structure enables the display device to be operated without direct contact of an object, that is, enables the display device to be operated in a contactless (touchless) manner. With the above-described structure, the display device can have a reduced risk of being dirty or damaged, or can be operated without the object directly touching a dirt (e.g., dust or a virus) attached to the display device.

The subpixels 110a, 110b, and 110c having a light-emitting function can be used as a light source of a sensor in the display device 100. Note that another light source may be prepared aside from the display device 100.

By mounting the display device 100 of this embodiment on an electronic device, a light-receiving portion and a light source do not need to be provided separately, and the number of components of the electronic device including the display device 100 can be reduced. For example, a fingerprint authentication device provided in the electronic device or a capacitive touch panel for scroll operation or the like is not necessarily provided separately. Thus, with the use of the display device 100, the electronic device can be provided at lower manufacturing costs.

In this specification and the like, in some cases, [a,b] (a and b are each an integer greater than or equal to 1) is used as the reference numeral in order to distinguish a plurality of pixels from each other. For the other elements, similar usage may be performed. For example, a position of an element denoted by [a,b] is referred to as coordinates in some cases. Furthermore, in the case of describing parts common to a plurality of pixels or a plurality of subpixels, the term “pixel 103” or “subpixel 110” is used for the description in some cases. In the case where parts common to components which are distinguished with use of one or both of the alphabet or coordinates are described, reference numerals without the alphabet or coordinates are used for the description in some cases.

In this specification and the like, the row direction is referred to as X direction and the column direction is referred to as Y direction. The X direction and the Y direction intersect with each other and are, for example, orthogonal to each other (see FIG. 1A).

As illustrated in FIG. 1A, the subpixels 110 in the fourth row and the fourth column, the fourth row and the fifth column, the fifth row and the fourth column, and the fifth row and the fifth column are the subpixels 110a; the subpixels 110 in the fourth row and the second column, the fourth row and the third column, the fifth row and the second column, and the fifth row and the third column are the subpixels 110b; the subpixels 110 in the second row and the second column, the second row and the third column, the third row and the second column, and the third row and the third column are the subpixels 110c; and the subpixels 110 in the second row and the fourth column, the second row and the fifth column, the third row and the fourth column, and the third row and the fifth column are the subpixels 110d. In other words, the display device 100 has portions where subpixels emitting light of the same color are adjacent to each other in both the row direction and the column direction. In addition, the display device 100 has portions where subpixels having a light detection function are adjacent to each other in both the row direction and the column direction. Specifically, the subpixels 110 emitting light of the same color are arranged to be adjacent to each other at least in two rows and two columns. Furthermore, the subpixels having a light detection function are arranged to be adjacent to each other at least in two rows and two columns. In other words, a subpixel emitting light of the same color is divided into at least two in the row direction and divided into at least two in the column direction. Furthermore, a subpixel having a light detection function is divided into at least two in the row direction and divided into at least two in the column direction. Note that the subpixels 110 emitting light of the same color or the subpixels 110 having a light detection function may be arranged in three or more columns. The subpixels 110 emitting light of the same color or the subpixels 110 having a light detection function may be arranged in three or more rows.

The display device illustrated in FIG. 1A has a portion where a first arrangement pattern with two rows and a second arrangement pattern with two rows are repeatedly placed in the column direction (Y direction). In the first arrangement pattern, two subpixels 110a and two subpixels 110b are repeatedly placed in the row direction (X direction). In the second arrangement pattern, the two subpixels 110c and two subpixels 110d are repeatedly placed in the row direction (X direction).

Furthermore, the display device illustrated in FIG. 1A has a portion where a third arrangement pattern with two columns and a fourth arrangement pattern with two columns are repeatedly placed in the row direction (X direction). In the third arrangement pattern, two subpixels 110a and two subpixels 110d are repeatedly placed in the column direction (Y direction). In the fourth arrangement pattern, two subpixels 110b and two subpixels 110c are repeatedly placed in the column direction (the Y direction).

Although the top view of FIG. 1A illustrates an example in which the connection portion 140 is positioned in the lower side of the display portion, one embodiment of the present invention is not limited thereto. The connection portion 140 may be provided in at least one of the upper side, the right side, the left side, and the lower side of the display portion in the top view, and may be provided so as to surround the four sides of the display portion. The top surface shape of the connection portion 140 can be a belt-like shape, an L shape, a U shape, a frame-like shape, or the like. The number of the connection portions 140 can be one or more.

FIG. 1B is a cross-sectional view taken along the dashed-dotted line A1-A2 in FIG. 1A. FIG. 2A is a cross-sectional view taken along the dashed-dotted line A3-A4 in FIG. 1A. FIG. 2B is a cross-sectional view taken along the dashed-dotted line B1-B2 in FIG. 1A. FIG. 2C and FIG. 2D are cross-sectional views taken along the dashed-dotted line C1-C2 in FIG. 1A.

As illustrated in FIG. 1B, FIG. 2A and FIG. 2B, the display device 100 includes a light-emitting device 130 and a light-receiving device 150 over a layer 101 including a transistor and a protective layer 131 to cover the light-emitting device 130 and the light-receiving device 150. Coloring layers 132a, 132b, and 132c are provided over the protective layer 131, and a substrate 120 is bonded onto the protective layer 131 with a resin layer 122. In a region between the adjacent light-emitting devices 130, a region between the adjacent light-receiving devices 150, and a region between the adjacent light-emitting device 130 and the light-receiving device 150, an insulating layer 125 and an insulating layer 127 over the insulating layer 125 are provided.

Although FIG. 1B, FIG. 2A, FIG. 2B, and the like illustrate in such a manner that a plurality of insulating layers 125 and a plurality of insulating layers 127 are provided, the display device 100 can have a structure, when seen from above, such that the insulating layers 125 are connected to each other and the insulating layers 127 are connected to each other. In other words, the display device 100 can have a structure such that one insulating layer 125 and one insulating layer 127 are provided, for example. Note that the display device 100 may include a plurality of insulating layers 125 which are separated from each other and a plurality of insulating layers 127 which are separated from each other.

The display device of one embodiment of the present invention can have any of the following structures: a top-emission structure in which light is emitted in a direction opposite to the substrate where the light-emitting device 130 is formed, a bottom-emission structure where light is emitted toward the substrate where the light-emitting device 130 is formed, and a dual-emission structure where light is emitted toward both surfaces.

The layer 101 including a transistor can employ a stacked-layer structure in which a plurality of transistors are provided over a substrate and an insulating layer is provided to cover these transistors, for example. The layer 101 including a transistor may have depressed portions between the adjacent light-emitting devices 130, between the adjacent light-receiving devices 150, and between the light-emitting device and the light-receiving device that are adjacent to each other. For example, an insulating layer positioned on the outermost surface of the layer 101 including a transistor may have a depressed portion. Structure examples of the layer 101 including a transistor will be described in Embodiment 2 and Embodiment 3.

The light-emitting device 130 included in each subpixel can exhibit the same color. The light-emitting device 130 emits white (W) light, for example.

As the light-emitting device 130, an OLED (Organic Light Emitting Diode) and a QLED (Quantum-dot Light Emitting Diode) are preferably used, for example. Examples of a light-emitting substance (also referred to as a light-emitting material) included in the light-emitting device include a substance that emits fluorescent light (a fluorescent material), a substance that emits phosphorescent light (a phosphorescent material), and a substance exhibiting thermally activated delayed fluorescence (a thermally activated delayed fluorescent (TADF) material). As the TADF material, a material in which the singlet and triplet excited states are in thermal equilibrium may be used. Since such a TADF material has a short emission lifetime (excitation lifetime), it inhibits a reduction in the efficiency of a light-emitting device in a high-luminance region. An inorganic compound (e.g., a quantum dot material) may also be used as the light-emitting substance included in the light-emitting device.

The light-emitting device 130 includes an EL layer between a pair of electrodes. The EL layer includes at least a light-emitting layer. In this specification and the like, one of the pair of electrodes may be referred to as a pixel electrode and the other may be referred to as a common electrode.

The light-emitting device 130 includes a pixel electrode 111 over the layer 101 including a transistor, an island-shaped first layer 112 over the pixel electrode 111, an island-shaped light-emitting layer 113 over the first layer 112, a second layer 116 over the light-emitting layer 113, a common layer 114 over the second layer 116, and a common electrode 115 over the common layer 114. The light-emitting layer 113 contains at least a light-emitting material. The first layer 112 and the second layer 116 may each include one or more of a hole-injection layer, a hole-transport layer, a hole-blocking layer, an electron-blocking layer, an electron-transport layer, and an electron-injection layer. The first layer 112, the light-emitting layer 113, and the second layer 116 can be collectively referred to as an island-shaped EL layer. For example, the first layer 112 can include a hole-injection layer and a hole-transport layer, and the second layer 116 can include an electron-transport layer. In this case, the pixel electrode 111 can function as an anode and the common electrode 115 can function as a cathode. The first layer 112 can include an electron-injection layer and an electron-transport layer, and the second layer 116 can include a hole-transport layer. In this case, the pixel electrode 111 can function as a cathode and the common electrode 115 can function as an anode.

The common layer 114 includes, for example, an electron-injection layer or a hole-injection layer. Alternatively, the common layer 114 may be a stack of an electron-transport layer and an electron-injection layer, and may be a stack of a hole-transport layer and a hole-injection layer. The common layer 114 is shared by the plurality of light-emitting devices 130 and the plurality of light-receiving devices 150 and for example, is shared by all of the light-emitting devices 130 and the light-receiving devices 150.

There is no particular limitation on the structure of the light-emitting device in this embodiment, and the light-emitting device can have a single structure or a tandem structure. In the case of having a tandem structure, the island-shaped EL layer is not limited to a stacked-layer structure of the first layer 112, the light-emitting layer 113, and the second layer 116. For example, the island-shaped EL layer can have a stacked-layer structure of the first layer 112, a first light-emitting layer, a third layer (a layer including at least one of a carrier-transport layer, a carrier-injection layer, a carrier-blocking layer, and a charge-generation layer), a second light-emitting layer, and the second layer 116, and may include another layer. Note that structure examples of the light-emitting device will be described later in Embodiment 4.

The light-receiving device 150 includes an active layer 155 between a pair of electrodes. In this specification and the like, one of the pair of electrodes may be referred to as a pixel electrode and the other may be referred to as a common electrode.

The light-receiving device 150 can detect one or both of infrared light and visible light. As the structure in which visible light is detected, a structure can be given in which one or more of blue light, violet light, bluish violet light, green light, yellowish green light, yellow light, orange light, red light, and the like are detected.

One of the pair of electrodes of the light-receiving device 150 functions as an anode, and the other electrode functions as a cathode. The case where the pixel electrode 111 functions as an anode and the common electrode 115 functions as a cathode is described below as an example. Alternatively, the pixel electrode 111 may function as a cathode and the common electrode 115 may function as an anode. When the light-receiving device is driven by application of reverse bias between the pixel electrode and the common electrode, light entering the light-receiving device can be detected and electric charge can be generated and extracted as current.

The light-receiving device 150 includes the pixel electrode 111 over the layer 101 including a transistor, the island-shaped first layer 112 over the pixel electrode 111, the island-shaped active layer 155 over the first layer 112, the second layer 116 over the active layer 155, the common layer 114 over the second layer 116, and the common electrode 115 over the common layer 114.

For example, a pn or pin photodiode can be used as the light-receiving device. The light-receiving device functions as a photoelectric conversion device (also referred to as a photoelectric conversion element) that detects light entering the light-receiving device and generates electric charge. The amount of electric charge generated from the light-receiving device depends on the amount of light entering the light-receiving device.

It is particularly preferable to use an organic photodiode including a layer containing an organic compound, as the light-receiving device. An organic photodiode, which is easily made thin, lightweight, and large in area and has a high degree of freedom for shape and design, can be used in a variety of display devices.

In one embodiment of the present invention, an organic EL device is used as the light-emitting device, and an organic photodiode is used as the light-receiving device. The organic EL device and the organic photodiode can be formed over the same substrate. Thus, the organic photodiode can be incorporated in the display device using the organic EL device.

Since a large number of layers in the organic photodiodes can have structures in common with the layers in the organic EL devices, forming the layers having common structures concurrently can inhibit an increase in the number of film formation steps.

For example, one of a pair of electrodes (a common electrode) can be a layer shared by the light-receiving device and the light-emitting device. For another example, at least one of a hole-injection layer, a hole-transport layer, a hole-blocking layer, an electron-blocking layer, an electron-transport layer, and an electron-injection layer is preferably shared by the light-receiving device and the light-emitting device. Note that in the display device of this embodiment, the following two kinds of layers can be given as a layer shared by the light-receiving device and the light-emitting device: a layer like the first layer 112 and the second layer 116 that is formed concurrently and then divided into the island shape by processing and one layer like the common layer 114 that is shared by the light-receiving device and the light-emitting device.

Note that a layer shared by the light-receiving device and the light-emitting device may have different functions in the light-emitting device and the light-receiving device. In this specification, the name of a component is based on its function in the light-emitting device. For example, a hole-injection layer functions as a hole-injection layer in the light-emitting device and functions as a hole-transport layer in the light-receiving device. Similarly, an electron-injection layer functions as an electron-injection layer in the light-emitting device and functions as an electron-transport layer in the light-receiving device. A layer shared by the light-receiving device and the light-emitting device may have the same function in both the light-emitting device and the light-receiving device. The hole-transport layer functions as a hole-transport layer in both the light-emitting device and the light-receiving device, and the electron-transport layer functions as an electron-transport layer in both the light-emitting device and the light-receiving device.

The common electrode 115 is shared by the plurality of light-emitting devices 130 and the plurality of light-receiving devices 150 and for example, is shared by all the light-emitting devices 130 and the light-receiving devices 150. The common electrode 115 shared by the plurality of light-emitting devices 130 and the plurality of light-receiving devices 150 is electrically connected to a conductive layer 123 provided in the connection portion 140 (see FIG. 2C and FIG. 2D). The conductive layer 123 can be formed using a conductive layer formed using the same material and through the same steps as the pixel electrode 111.

Note that FIG. 2C illustrates an example in which the common layer 114 is provided over the conductive layer 123 and the conductive layer 123 and the common electrode 115 are electrically connected to each other through the common layer 114. The common layer 114 is not necessarily provided in the connection portion 140. For example, FIG. 2D illustrates an example in which the common layer 114 is not provided over the conductive layer 123 and the conductive layer 123 and the common electrode 115 are directly connected to each other. For example, by using a mask for specifying a film formation area (also referred to as an area mask or a rough metal mask), the common layer 114 can be formed in a region different from a region where the common electrode 115 is formed.

The relationship in size between the pixel electrode 111 and the light-emitting layer 113 are not particularly limited. The relationship in size between the pixel electrode 111 and the active layer 155 are not particularly limited. Note that the same applies to the first layer 112 and the second layer 116. FIG. 1B, FIG. 2A, and FIG. 2B each illustrate an example in which the end portion of the pixel electrode 111 is aligned or substantially aligned with the end portion of the light-emitting layer 113. FIG. 1B, FIG. 2A, and FIG. 2B each illustrate an example in which the end portion of the pixel electrode 111 is aligned or substantially aligned with the end portion of the active layer 155.

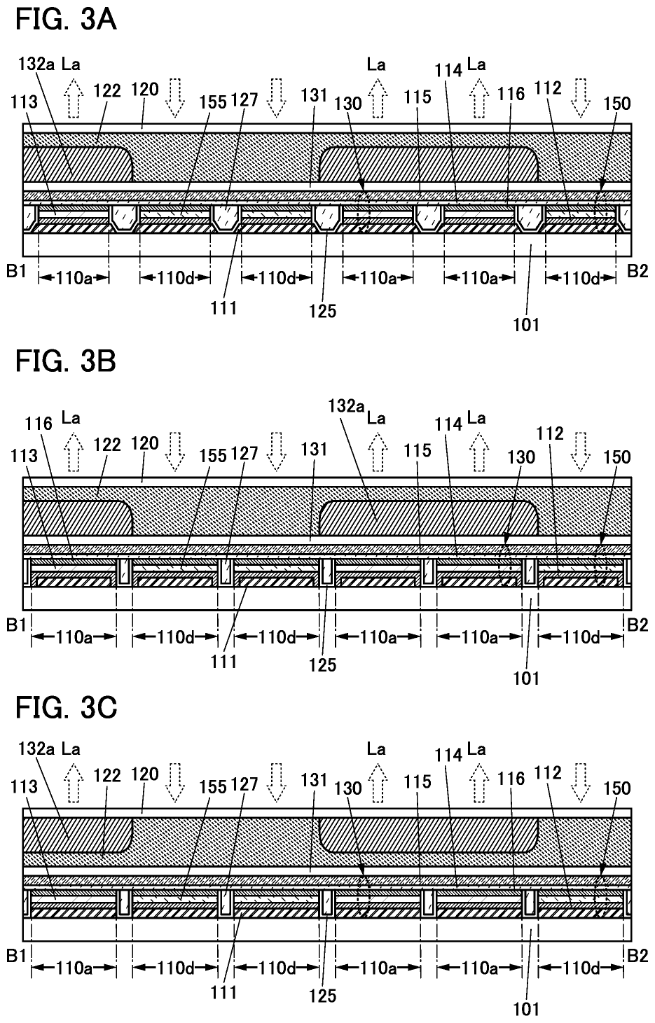

FIG. 3A illustrates an example in which the end portion of the light-emitting layer 113 and the end portion of the active layer 155 are positioned inside compared to the end portion of the pixel electrode 111. In FIG. 3A, the end portion of the light-emitting layer 113 is positioned over the pixel electrode 111. In FIG. 3A, the end portion of the active layer 155 is positioned over the pixel electrode 111. FIG. 3B illustrates an example in which the end portion of the light-emitting layer 113 and the end portion of the active layer 155 are positioned outside compared to the end portion of the pixel electrode 111. In FIG. 3B, the first layer 112 is provided to cover the end portion of the pixel electrode 111. The end portion of the light-emitting layer 113 and the end portion of the active layer 155 may each have both a part positioned outside compared to the end portion of the pixel electrode 111 and a part positioned inside compared to the end portion of the pixel electrode 111.

As illustrated in FIG. 3A, the end portion of the pixel electrode 111 may have a tapered shape. When the side surface of the pixel electrode 111 has a tapered shape, coverage with the insulating layer 125 provided along the side surface of the pixel electrode 111 can be improved. Furthermore, when the side surface of the pixel electrode 111 has a tapered shape, a material (also referred to as dust or particles) in the manufacturing step is easily removed by processing such as cleaning, which is preferable. Note that in this specification and the like, a tapered shape refers to a shape such that at least part of a side surface of a component is inclined with respect to the substrate surface or the surface where the component is formed. For example, a tapered shape preferably includes a region where the angle between the inclined side surface and the substrate surface or the surface where a component is formed (such an angle is also referred to as a taper angle) is less than 90°.

In the case where end portions are aligned or substantially aligned with each other and the case where top surface shapes are the same or substantially the same, it can be said that outlines of stacked layers at least partly overlap with each other in a top view. For example, the case of patterning or partly patterning an upper layer and a lower layer with use of the same mask pattern is included in the expression. However, in some cases, the outlines are not completely overlapped with each other and the upper layer is positioned on an inner side of the lower layer or the upper layer is positioned on an outer side of the lower layer; such a case is also represented by the expression “end portions are aligned or substantially aligned with each other” or “top surface shapes are substantially aligned with each other”.

The protective layer 131 is preferably provided over the light-emitting device 130 and the light-receiving device 150. Providing the protective layer 131 can improve the reliability of the light-emitting device and the light-receiving device. The protective layer 131 may have a single-layer structure or a stacked-layer structure of two or more layers.

There is no limitation on the conductivity of the protective layer 131. As the protective layer 131, at least one type of an insulating film, a semiconductor film, and a conductive film can be used.

The protective layer 131 including an inorganic film can inhibit deterioration of the light-emitting device and the light-receiving device by preventing oxidation of the common electrode 115 and inhibiting entry of impurities (e.g., moisture and oxygen) into the light-emitting device 130 and the light-receiving device 150, for example; thus, the reliability of the display device can be improved.

As the protective layer 131, an inorganic insulating film such as an oxide insulating film, a nitride insulating film, an oxynitride insulating film, or a nitride oxide insulating film can be used, for example. Examples of the oxide insulating film include a silicon oxide film, an aluminum oxide film, a gallium oxide film, a germanium oxide film, an yttrium oxide film, a zirconium oxide film, a lanthanum oxide film, a neodymium oxide film, a hafnium oxide film, a tantalum oxide film, and the like. Examples of the nitride insulating film include a silicon nitride film, an aluminum nitride film, and the like. Examples of the oxynitride insulating film include a silicon oxynitride film, an aluminum oxynitride film, and the like. Examples of the nitride oxide insulating film include a silicon nitride oxide film, an aluminum nitride oxide film, and the like.

Note that in this specification and the like, oxynitride refers to a material that contains more oxygen than nitrogen, and nitride oxide refers to a material that contains more nitrogen than oxygen. For example, silicon oxynitride refers to a material which contains oxygen at a higher proportion than nitrogen, and silicon nitride oxide refers to a material which contains nitrogen at a higher proportion than oxygen.

The protective layer 131 preferably includes a nitride insulating film or a nitride oxide insulating film, and further preferably includes a nitride insulating film.

As the protective layer 131, an inorganic film containing In—Sn oxide (also referred to as ITO), In—Zn oxide, Ga—Zn oxide, Al—Zn oxide, indium gallium zinc oxide (In—Ga—Zn oxide, also referred to as IGZO), or the like can also be used. The inorganic film preferably has high resistance, specifically, higher resistance than the common electrode 115. The inorganic film may further contain nitrogen.

When light emitted from the light-emitting device is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can be, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (such as water and oxygen) into the EL layer.

Furthermore, the protective layer 131 may include an organic film. For example, the protective layer 131 may include both an organic film and an inorganic film.

The protective layer 131 may have a stacked-layer structure of two layers which are formed by different formation methods. Specifically, the first layer of the protective layer 131 may be formed by an ALD method, and the second layer of the protective layer 131 may be formed by a sputtering method.

In the subpixel 110a, the coloring layer 132a that transmits light of the first color is provided over the protective layer 131. Thus, from the subpixel 110a, light emitted by the light-emitting device 130 is extracted as light of the first color to the outside of the display device 100 through the coloring layer 132a. Note that the coloring layer 132a may be shared by a plurality of subpixels 110a adjacent to each other. For example, one coloring layer 132a may be shared by four subpixels 110a included in the pixels 103[2,2], 103[2,3], 103[3,2], and 103[3,3] in FIG. 1A. Furthermore, the coloring layers 132a may be independently provided one by one for the subpixels 110a.

Similarly, in the subpixel 110b, the coloring layer 132b that transmits light of the second color is provided over the protective layer 131. Thus, from the subpixel 110b, light emitted by the light-emitting device 130 is extracted as light of the second color to the outside of the display device 100 through the coloring layer 132b.

Also in the subpixel 110c, the coloring layer 132c that transmits light of the third color is provided over the protective layer 131. Thus, from the subpixel 110c, light emitted by the light-emitting device 130 is extracted as light of the third color to the outside of the display device 100 through the coloring layer 132c.

FIG. 1B, FIG. 2A, and FIG. 2B each illustrate an example in which the coloring layers 132a, 132b, and 132c are directly provided over the light-emitting device 130 with the protective layer 131 provided therebetween. With such a structure, the alignment accuracy of the light-emitting device 130 and the coloring layer can be improved. It is preferable that the distance between the light-emitting device 130 and the coloring layer be decreased, in which case color mixing can be inhibited and the viewing angle characteristics can be improved.

Alternatively, as illustrated in FIG. 3C, the substrate 120 provided with the coloring layers 132a, 132b, and 132c may be attached to the protective layer 131 with the resin layer 122. The coloring layers 132a, 132b, and 132c are provided on the substrate 120, whereby the heat treatment temperature in the forming step of them can be increased.

In FIG. 1B, FIG. 2A, and FIG. 2B, the end portion of the top surface of the pixel electrode 111 is not covered with an insulating layer. Thus, the distance between adjacent light-emitting devices can be extremely shortened. Accordingly, the display device can have high resolution or high definition.

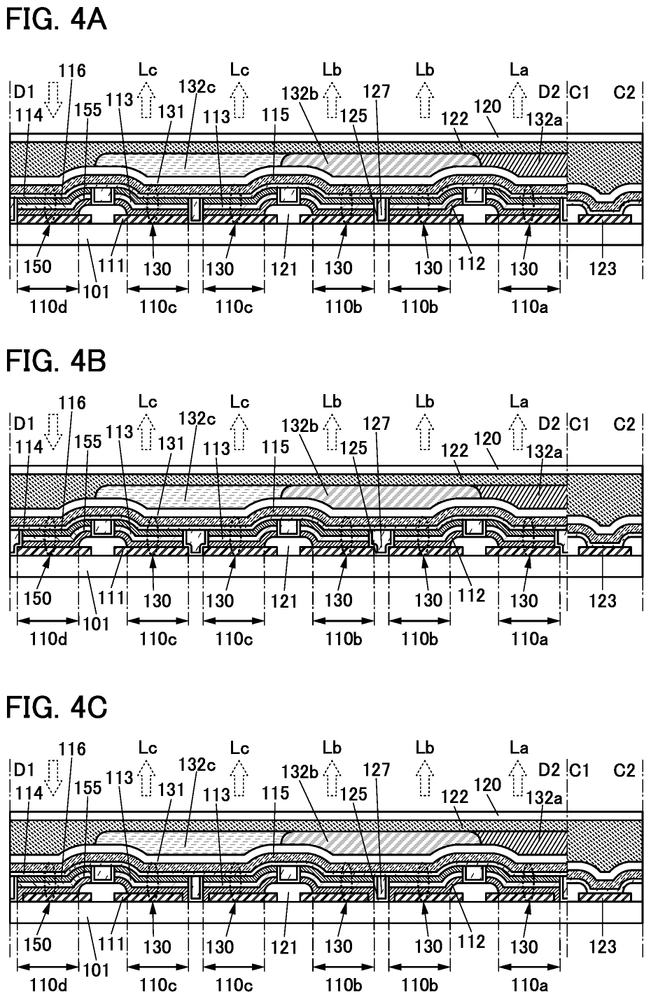

Note that as illustrated in FIG. 4A to FIG. 4C, an insulating layer 121 covering the end portion of the top surface of the pixel electrode 111 may be provided.

FIG. 4A to FIG. 4C each illustrate an example where the insulating layer 121 is provided between subpixels exhibiting different colors and between the subpixel having a light-emitting function and the subpixel having a light detection function. Specifically, in the subpixel 110c on the left side illustrated in FIG. 4A to FIG. 4C, the end portion of the pixel electrode 111 on the subpixel 110d side is covered with the insulating layer 121, and the end portion of the adjacent subpixel 110c side is not covered with the insulating layer 121. In the subpixel 110c on the right side illustrated in FIG. 4A to FIG. 4C, the end portion of the pixel electrode 111 on the subpixel 110b side is covered with the insulating layer 121, and the end portion of the adjacent subpixel 110c side is not covered with the insulating layer 121. Note that the layout of the insulating layer 121 is not limited to the above. For example, the insulating layer 121 may cover an end portion of one side of the pixel electrode 111, end portions of two or more sides thereof, or end portions of four sides thereof. That is, the insulating layer 121 may be provided between the subpixels exhibiting the same color.

FIG. 4A is an example where the end portions of the pixel electrode 111 and the light-emitting layer 113 are aligned or substantially aligned with each other on the adjacent subpixel 110c side in the subpixel 110c. Note that the end portions of the pixel electrode 111 and the light-emitting layer 113 are aligned or substantially aligned with each other on the adjacent subpixel 110b side in the subpixel 110b. FIG. 4B illustrates an example where the end portion of the light-emitting layer 113 is positioned inside compared to the end portion of the pixel electrode 111 on the adjacent subpixel 110c side in the subpixel 110c. FIG. 4C illustrates an example where the end portion of the light-emitting layer 113 is positioned outside compared to the end portion of the pixel electrode 111 on the adjacent subpixel 110c side in the subpixel 110c. Note that the same applies not only to the light-emitting layer 113 but also to the first layer 112 and the second layer 116.

The insulating layer 121 can have a single-layer structure or a stacked-layer structure using one or both of an inorganic insulating film and an organic insulating film.

Examples of an organic insulating material that can be used for the insulating layer 121 include an acrylic resin, an epoxy resin, a polyimide resin, a polyamide resin, a polyimide-amide resin, a polysiloxane resin, a benzocyclobutene-based resin, and a phenol resin. As an inorganic insulating film that can be used as the insulating layer 121, an inorganic insulating film that can be used as the protective layer 131 can be used.

When an inorganic insulating film is used as the insulating layer 121 covering the end portion of the pixel electrode 111, impurities are less likely to enter the light-emitting device 130 and the light-receiving device 150 as compared with the case where an organic insulating film is used; therefore, the reliability of the light-emitting device 130 and the light-receiving device 150 can be improved. When an organic insulating film is used as the insulating layer 121 covering the end portion of the pixel electrode 111, a short circuit in the light-emitting device 130 and the light-receiving device 150 can be prevented because the organic insulating film has higher step coverage and is less likely to be influenced by the shape of the pixel electrode than the inorganic insulating film. Specifically, when an organic insulating film is used as the insulating layer 121, the insulating layer 121 can be processed into a tapered shape or the like.

The insulating layer 121 has a function of preventing a metal mask from being in contact with the pixel electrode 111 and the like when the light-emitting layer 113 or the active layer 155 is formed using the metal mask. Note that an insulating layer having a function of a spacer may be additionally provided over the insulating layer 121, so that the metal mask is prevented from being in contact with the pixel electrode 111 and the like.

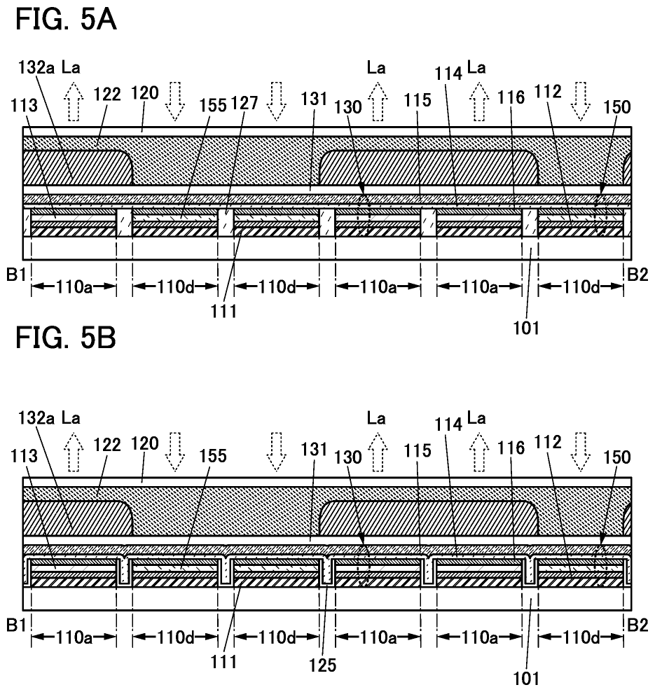

In FIG. 1B, FIG. 2A, FIG. 2B, and FIG. 3A to FIG. 3C, the side surfaces of the pixel electrode 111, the first layer 112, the light-emitting layer 113, the second layer 116, and the active layer 155 are covered with the insulating layer 125 and the insulating layer 127. In FIG. 4A to FIG. 4C, the side surface of the pixel electrode 111 is covered with the insulating layer 121, and the side surfaces of the first layer 112, the light-emitting layer 113, the second layer 116, and the active layer 155 are covered with the insulating layer 125 and the insulating layer 127. In FIG. 5A, the side surfaces of the pixel electrode 111, the first layer 112, the light-emitting layer 113, the second layer 116, and the active layer 155 are covered with the insulating layer 127. In FIG. 5B, the side surfaces of the pixel electrode 111, the first layer 112, the light-emitting layer 113, the second layer 116, and the active layer 155 are covered with the insulating layer 125. Thus, the common layer 114 (or the common electrode 115) can be inhibited from being in contact with the side surfaces of these layers, so that a short circuit of the light-emitting device and the light-receiving device can be inhibited. Thus, the reliability of the light-emitting device and light-receiving device can be increased.

The insulating layer 125 preferably covers at least one of the side surface of the pixel electrode 111 and the side surface of the light-emitting layer 113, and further preferably covers both the side surface of the pixel electrode 111 and the side surface of the light-emitting layer 113. The insulating layer 125 can be in contact with the side surface of the pixel electrode 111 and the side surface of the light-emitting layer 113. In addition, it is preferable that the insulating layer 125 cover the side surface of the active layer 155 and the insulating layer 125 be in contact with the side surface of the active layer 155.

The insulating layer 127 is provided over the insulating layer 125 to fill a depressed portion in the insulating layer 125. The insulating layer 127 can have a structure overlapping with the side surfaces of the pixel electrode 111, the first layer 112, the light-emitting layer 113, the second layer 116, and the active layer 155 with the insulating layer 125 provided therebetween (also referred to as a structure covering the side surfaces thereof).

The insulating layer 125 and the insulating layer 127 can fill a gap between the adjacent island-shaped layers, whereby the formation surface of a layer (e.g., the common electrode) provided over the island-shaped layers can be less uneven and can be flatter. Thus, the coverage with the common electrode can be increased and disconnection of the common electrode can be prevented.

The common layer 114 and the common electrode 115 are provided over the second layer 116, the insulating layer 125, and the insulating layer 127. Before the insulating layer 125 and the insulating layer 127 are provided, a level difference due to a region where the pixel electrode 111 and the second layer 116 are provided and a region where neither the pixel electrode 111 nor the second layer 116 is provided (a region between the light-emitting devices, a region between the light-emitting device and the light-receiving device, and a region between the light-receiving devices) is caused. In the display device of one embodiment of the present invention, the level difference can be planarized with the insulating layer 125 and the insulating layer 127, and the coverage with the common layer 114 and the common electrode 115 can be improved.

Consequently, it is possible to inhibit a connection defect due to disconnection of the common electrode 115. Alternatively, an increase in electrical resistance, which is caused by a reduction in thickness locally of the common electrode 115 due to level difference, can be inhibited.

To improve the planarity of a surface over which the common layer 114 and the common electrode 115 are formed, the levels of the top surface of the insulating layer 125 and the top surface of the insulating layer 127 are aligned or substantially aligned with the level of the top surface of the second layer 116 at its end portion (also referred to as the level of the end portion of the top surface of the EL layer 113). The top surface of the insulating layer 127 preferably has a flat surface; however, it may include a projecting portion, a convex curved surface, a concave curved surface, or a depressed portion.

The insulating layer 125 or the insulating layer 127 can be provided to be in contact with the first layer 112, the light-emitting layer 113, the second layer 116, and the active layer 155. When the insulating layer is in close contact with the first layer 112, the light-emitting layer 113, the second layer 116, and the active layer 155, an effect of fixing or attaching these layers to the insulating layer can be attained. Thus, film separation of the first layer 112, the light-emitting layer 113, the second layer 116, and the active layer 155 can be prevented and the reliability of the light-emitting device and the light-receiving device can be increased. The manufacturing yield of the light-emitting device and the light-receiving device can be increased.

Note that one of the insulating layer 125 and the insulating layer 127 is not necessarily provided. For example, a single-layer insulating layer 125 using an inorganic material can be used as a protective insulating layer of the first layer 112, the light-emitting layer 113, the second layer 116, and the active layer 155. In this way, the reliability of the display device can be increased. For another example, a single-layer insulating layer 127 using an organic material can fill a gap between the adjacent second layers 116 and planarization can be performed. In this way, the coverage with the common electrode 115 (the upper electrode) formed over the second layer 116 and the insulating layer 127 can be increased.

FIG. 5A illustrates an example in which the insulating layer 125 is not provided. In the case where the insulating layer 125 is not provided, the insulating layer 127 can be in contact with the side surfaces of the pixel electrode 111, the first layer 112, the light-emitting layer 113, the second layer 116, and the active layer 155. The insulating layer 127 can be provided to fill gaps between the adjacent second layers 116.

In this case, an organic material which causes less damage to the first layer 112, the light-emitting layer 113, the second layer 116, and the active layer 155 is preferably used for the insulating layer 127. For example, it is preferable to use, for the insulating layer 127, an organic material such as polyvinyl alcohol (PVA), polyvinyl butyral, polyvinyl pyrrolidone, polyethylene glycol, polyglycerin, pullulan, water-soluble cellulose, or alcohol-soluble polyamide resin.

FIG. 5B illustrates an example in which the insulating layer 127 is not provided.

Note that although FIG. 5B illustrates an example in which the common layer 114 is provided in the depressed portion of the insulating layer 125, spaces may be formed in the regions.

The insulating layer 125 has a region in contact with the side surfaces of the first layer 112, the light-emitting layer 113, the second layer 116, and the active layer 155 and functions as a protective insulating layer of the first layer 112, the light-emitting layer 113, the second layer 116, and the active layer 155. With the insulating layer 125, entry of impurities (such as oxygen and moisture) from the side surfaces of the first layer 112, the light-emitting layer 113, the second layer 116, and the active layer 155 into its inside can be inhibited, and thus a highly reliable display device can be obtained.

The insulating layer 125 can be formed using an inorganic material. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium-gallium-zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, aluminum oxide is preferably used because it has high selectivity with respect to the EL layer in etching and has a function of protecting the EL layer when the insulating layer 127 to be described later is formed. An inorganic insulating film such as an aluminum oxide film, a hafnium oxide film, or a silicon oxide film is formed by an ALD method as the insulating layer 125, whereby the insulating layer 125 can have few pinholes and an excellent function of protecting the EL layer. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. Alternatively, the insulating layer 125 preferably has a function of inhibiting the diffusion of at least one of water and oxygen. Alternatively, the insulating layer 125 preferably has a function of capturing or fixing (also referred to as gettering) at least one of water and oxygen.

When the insulating layer 125 has a function of the barrier insulating layer or a gettering function, entry of impurities (typically, at least one of water and oxygen) that would diffuse into the light-emitting device and the light-receiving device from the outside can be inhibited. In this structure, a highly reliable light-emitting device and a highly reliable light-receiving device, furthermore, a highly reliable display device can be provided.

The insulating layer 125 preferably has a low impurity concentration. Accordingly, degradation of the first layer 112, the light-emitting layer 113, the second layer 116, and the active layer 155, which is caused by entry of impurities into these layers from the insulating layer 125, can be inhibited. In addition, when the impurity concentration is reduced in the insulating layer 125, a barrier property against at least one of water and oxygen can be increased. For example, the insulating layer 125 preferably has one of a sufficiently low hydrogen concentration and a sufficiently low carbon concentration, desirably has both of them.

The insulating layer 125 can be formed by a sputtering method, a CVD method, a pulsed laser deposition (PLD) method, an ALD method, or the like. The insulating layer 125 is preferably formed by an ALD method achieving good coverage.

When the substrate temperature at the time when the insulating layer 125 is formed is increased, the formed insulating layer 125, even with a small thickness, can have a low impurity concentration and a high barrier property against at least one of water and oxygen. Therefore, the substrate temperature is preferably higher than or equal to 60° C., further preferably higher than or equal to 80° C., still further preferably higher than or equal to 100° C., yet still further preferably higher than or equal to 120° C. Meanwhile, the insulating layer 125 is formed after formation of an island-shaped EL layer, it is preferable that the insulating layer 125 be formed at a temperature lower than the upper temperature limit of the EL layer. Therefore, the substrate temperature is preferably lower than or equal to 200° C., further preferably lower than or equal to 180° C., still further preferably lower than or equal to 160° C., still further preferably lower than or equal to 150° C., yet still further preferably lower than or equal to 140° C.

Examples of indicators of the upper temperature limit are the glass transition point, the softening point, the melting point, the thermal decomposition temperature, and the 5% weight loss temperature. The upper temperature limit of the EL layer can be, for example, any of the above temperatures, preferably the lowest temperature thereof.

The insulating layer 127 provided over the insulating layer 125 has a function of filling the depressed portion of the insulating layer 125 formed between adjacent light-emitting devices, between the light-receiving devices, and between the light-emitting device and the light-receiving device for planarization. In other words, the insulating layer 127 brings an effect of improving the planarity of a surface where the common electrode 115 is formed. As the insulating layer 127, an insulating layer containing an organic material can be suitably used. For the insulating layer 127, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like can be used, for example. Examples of organic materials used for the insulating layer 127 include polyvinyl alcohol (PVA), polyvinyl butyral, polyvinyl pyrrolidone, polyethylene glycol, polyglycerin, pullulan, water-soluble cellulose, and an alcohol-soluble polyamide resin. Alternatively, a photosensitive resin can be used for the insulating layer 127. A photoresist may be used for the photosensitive resin. As the photosensitive resin, a positive photosensitive material or a negative photosensitive material can be used.

The insulating layer 127 may be formed using a material absorbing visible light. When the insulating layer 127 absorbs light emitted by the light-emitting device, leakage of light (stray light) from the light-emitting device to the adjacent light-emitting device through the insulating layer 127 can be inhibited. Thus, the display quality of the display device can be improved. In addition, entry of light from the light-emitting device into the adjacent light-receiving device through the insulating layer 127 can be inhibited; thus, noise can be reduced and the accuracy of light detection in the display device can be increased.

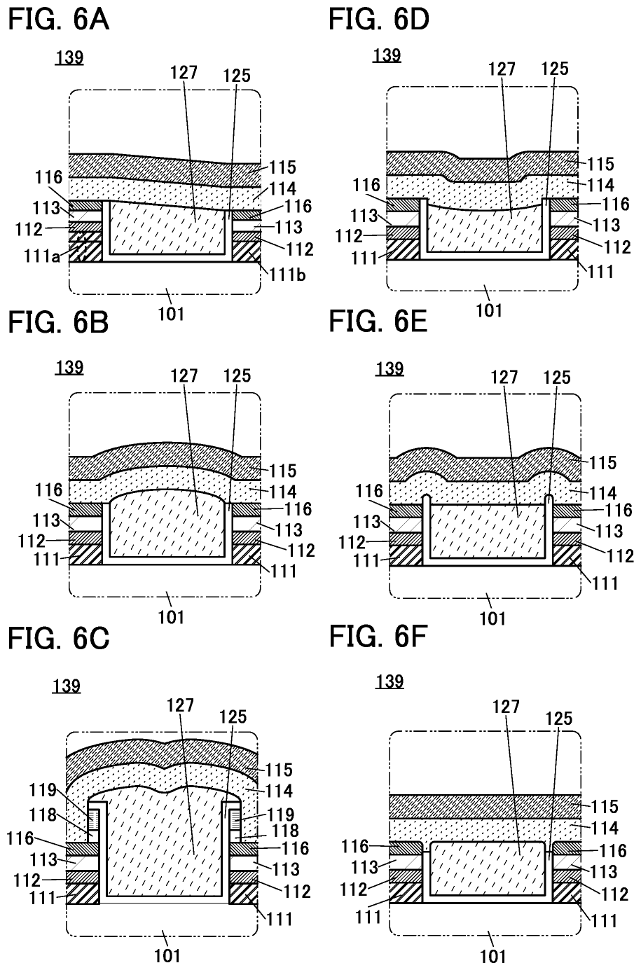

FIG. 6A to FIG. 6F each illustrate a cross-sectional structure of a region 139 including the insulating layer 127 and its surroundings.

FIG. 6A illustrates an example in which the thickness of the pixel electrode differs between subpixels of different colors. Specifically, the thickness of a pixel electrode 111a and the thickness of a pixel electrode 111b are different from each other. FIG. 6A illustrates an example where the pixel electrode 111a has a two-layer structure and the pixel electrode 111b has a single-layer structure. Since the first layer 112, the light-emitting layer 113, and the second layer 116 are formed in common between the subpixels of different colors, the thickness of the first layer 112, the light-emitting layer 113, and the second layer 116 over the pixel electrode 111a and the thickness of the first layer 112, the light-emitting layer 113, and the second layer 116 over the pixel electrode 111b are the same or substantially the same as each other. Therefore, the level of the top surface of the second layer 116 over the pixel electrode 111a is different from that over the pixel electrode 111b. On both the pixel electrode 111a side and the pixel electrode 111b side, the top surface of the insulating layer 125 is at the same level or substantially the same level as that of the second layer 116. The top surface of the insulating layer 127 has a gentle slope such that the side closer to the pixel electrode 111a is higher and the side closer to the pixel electrode 111b is lower. In this manner, the levels of the insulating layer 125 and the insulating layer 127 are preferably equal to the levels of the top surfaces of the adjacent EL layers. Alternatively, the top surface of the insulating layer 125 or the top surface of the insulating layer 127 may include a flat portion that is level with the top surface of any of adjacent EL layers.

In FIG. 6B, the top surface of the insulating layer 127 has a region whose level is higher than that of top surface of the second layer 116. As illustrated in FIG. 6B, it can be said that the top surface of the insulating layer 127 has a shape in which its center and vicinity thereof rise, i.e., a shape including a convex curved surface, in the cross-sectional view.

In the cross-sectional view of FIG. 6C, the top surface of the insulating layer 127 gently rises from its end portions toward the center, i.e., has convex curved surfaces, and has a depressed portion in the center and its vicinity, i.e., has a concave curved surface. The insulating layer 127 has a region whose level is higher than that of the top surface of the second layer 116. In the region 139, the display device includes at least one of a sacrificial layer 118 and a sacrificial layer 119. The end portion of the insulating layer 125 and the end portion of the insulating layer 127 overlap with the top surface of the second layer 116 and are positioned over at least one of the sacrificial layer 118 and the sacrificial layer 119.

In FIG. 6D, the top surface of the insulating layer 127 includes a region whose level is lower than that of the top surface of the second layer 116. In the cross-sectional view, the top surface of the insulating layer 127 has a depressed portion in the center and its vicinity, i.e., has a concave curved surface.

In FIG. 6E, the top surface of the insulating layer 125 includes a region whose level is higher than that of the top surface of the second layer 116. That is, the insulating layer 125 protrudes from the formation surface of the common layer 114 and forms a projecting portion.

For example, when the insulating layer 125 is formed so that its level is equal to or substantially equal to the level of the sacrificial layer, the insulating layer 125 may protrude as illustrated in FIG. 6E.

In FIG. 6F, the top surface of the insulating layer 125 includes a region whose level is lower than that of the top surface of the second layer 116. That is, the insulating layer 125 forms a depressed portion on the formation surface of the common layer 114.

As described above, the insulating layer 125 and the insulating layer 127 can have a variety of shapes.

As the sacrificial layer, one or more kinds of inorganic films such as a metal film, an alloy film, a metal oxide film, a semiconductor film, and an inorganic insulating film can be used, for example.

For example, a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials can be used for the sacrificial layer.

For the sacrificial layer, a metal oxide such as In—Ga—Zn oxide can be used. As the sacrificial layer, an In—Ga—Zn oxide film can be formed by a sputtering method, for example. Furthermore, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or the like can be used. Indium tin oxide containing silicon, or the like can also be used.

In addition, in place of gallium described above, an element M (M is one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, magnesium, and the like) may be used.

As the sacrificial layer, a variety of inorganic insulating films that can be used as the protective layer 131 can be used. In particular, an oxide insulating film is preferable because its adhesion to the EL layer is higher than that of a nitride insulating film. For example, an inorganic insulating material such as aluminum oxide, hafnium oxide, or silicon oxide can be used for the sacrificial layer. As the sacrificial layer, an aluminum oxide film can be formed by an ALD method, for example. The use of an ALD method is preferable, in which case damage to a base (in particular, the EL layer or the like) can be reduced. For example, a silicon nitride film can be formed by a sputtering method.

For example, the sacrificial layer can employ a stacked-layer structure of an inorganic insulating film (e.g., an aluminum oxide film) formed by an ALD method and an In—Ga—Zn oxide film formed by a sputtering method. Alternatively, the sacrificial layer can employ a stacked-layer structure of an inorganic insulating film (e.g., an aluminum oxide film) formed by an ALD method and an aluminum film, a tungsten film, or an inorganic insulating film (e.g., a silicon nitride film) formed by a sputtering method.

In the display device of this embodiment, the distance between the light-emitting devices can be narrowed. Specifically, the distance between the light-emitting devices, the distance between the EL layers, or the distance between the pixel electrodes can be less than 10 μm, 5 μm or less, 3 μm or less, 2 μm or less, 1 μm or less, 500 nm or less, 200 nm or less, 100 nm or less, 90 nm or less, 70 nm or less, 50 nm or less, 30 nm or less, 20 nm or less, 15 nm or less, or 10 nm or less. In other words, the display device of this embodiment includes a region where a distance between two light-emitting layers 113 adjacent to each other is less than or equal to 1 μm, preferably less than or equal to 0.5 μm (500 nm), further preferably less than or equal to 100 nm.

Note that the distance between the light-emitting device and the light-receiving device can be set within the above range. In order to inhibit leakage between the light-emitting device and the light-receiving device, the distance between the light-emitting device and the light-receiving device is preferably larger than the distance between the light-emitting devices. For example, the distance between the light-emitting device and the light-receiving device can be set to 8 μm or less, 5 μm or less, or 3 μm or less.

A light-blocking layer may be provided on the surface of the substrate 120 on the resin layer 122 side. Moreover, a variety of optical members can be provided on the outer side of the substrate 120. Examples of optical members include a polarizing plate, a retardation plate, a light diffusion layer (e.g., a diffusion film), an anti-reflective layer, and a light-condensing film. Furthermore, an antistatic film inhibiting the attachment of dust, a water repellent film suppressing the attachment of stain, a hard coat film inhibiting generation of a scratch caused by the use, an impact-absorbing layer, or the like may be provided as a surface protective layer on the outer surface of the substrate 120. For example, it is preferable to provide, as the surface protective layer, a glass layer or a silica layer (SiOₓ layer) because the surface contamination or damage can be inhibited from being generated. The surface protective layer may be formed using DLC (diamond like carbon), alumina (AlOₓ), a polyester-based material, a polycarbonate-based material, or the like. For the surface protective layer, a material having a high transmitting property with respect to visible light is preferably used. The surface protective layer is preferably formed using a material with high hardness.

For the substrate 120, glass, quartz, ceramic, sapphire, a resin, a metal, an alloy, a semiconductor, or the like can be used. The substrate on the side from which light from the light-emitting device is extracted is formed using a material which transmits the light. When a flexible material is used for the substrate 120, the display devices can have increased flexibility and a flexible display can be obtained. Furthermore, a polarizing plate may be used as the substrate 120.

For the substrate 120, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used as the substrate 120.

In the case where a circularly polarizing plate overlaps with the display devices, a highly optically isotropic substrate is preferably used as the substrate included in the display devices. A highly optically isotropic substrate has a low birefringence (i.e., a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of films having high optical isotropy include a triacetyl cellulose (TAC, also referred to as cellulose triacetate) film, a cycloolefin polymer (COP) film, a cycloolefin copolymer (COC) film, and an acrylic film.

When a film used as the substrate absorbs water, the shape of the display panel might be changed, e.g., creases might be caused. Thus, as the substrate, a film with a low water absorption rate is preferably used. For example, the water absorption rate of the film is preferably 1% or lower, further preferably 0.1% or lower, still further preferably 0.01% or lower.

For the resin layer 122, a variety of curable adhesives such as a photocurable adhesive like an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferred. A two-component-mixture-type resin may be used. An adhesive sheet or the like may be used.

Next, materials that can be used for the light-emitting device and the light-receiving device will be described.

A conductive film that transmits visible light is used as the electrode through which light is extracted, which is either the pixel electrode or the common electrode. A conductive film that reflects visible light is preferably used as the electrode through which light is not extracted. In the case where a display device includes at least one of a light-emitting device emitting infrared light and a light-receiving device detecting infrared light, a conductive film which transmits visible light and infrared light is used as the electrode through which light is extracted, and a conductive film that reflects visible light and infrared light is preferably used as the electrode through which light is not extracted.

As a material that forms the pair of electrodes (the pixel electrode and the common electrode) of the light-emitting device and the light-receiving device, a metal, an alloy, an electrically conductive compound, a mixture thereof, and the like can be used as appropriate. Specific examples include indium tin oxide (In—Sn oxide, also referred to as ITO), In—Si—Sn oxide (also referred to as ITSO), indium zinc oxide (In—Zn oxide), In—W—Zn oxide, an alloy containing aluminum (an aluminum alloy) such as an alloy of aluminum, nickel, and lanthanum (Al—Ni—La), and an alloy of silver, palladium, and copper (Ag—Pd—Cu, also referred to as APC). In addition, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals. It is also possible to use a Group 1 element or a Group 2 element in the periodic table, which is not described above (e.g., lithium (Li), cesium (Cs), calcium (Ca), or strontium (Sr)), a rare earth metal such as europium (Eu) or ytterbium (Yb), an alloy containing an appropriate combination of any of these elements, graphene, or the like.

The light-emitting device and the light-receiving device preferably employs a microcavity structure. Therefore, one of the pair of electrodes of the light-emitting device and the light-receiving device is preferably an electrode having properties of transmitting and reflecting visible light (a transflective electrode), and the other is preferably an electrode having a property of reflecting visible light (a reflective electrode). When the light-emitting device has a microcavity structure, light obtained from the light-emitting layer can be resonated between the electrodes, whereby light emitted from the light-emitting device can be intensified. When the light-receiving device has a microcavity structure, light received by the active layer can be resonated between the electrodes, whereby the light can be intensified and the detecting accuracy of the light-receiving device can be increased.

The transflective electrode can have a stacked-layer structure of a reflective electrode and an electrode having a property of transmitting visible light (also referred to as a transparent electrode).

The transparent electrode has a light transmittance higher than or equal to 40%. For example, an electrode having a visible light (light at wavelengths greater than or equal to 400 nm and less than 750 nm) transmittance higher than or equal to 40% is preferably used in the light-emitting device. The visible light reflectivity of the transflective electrode is higher than or equal to 10% and lower than or equal to 95%, preferably higher than or equal to 30% and lower than or equal to 80%. The visible light reflectivity of the reflective electrode is higher than or equal to 40% and lower than or equal to 100%, preferably higher than or equal to 70% and lower than or equal to 100%. These electrodes preferably have a resistivity of 1×10⁻² Ωcm or lower. The infrared light (light at wavelengths greater than or equal to 750 nm and less than or equal to 1300 nm) transmittance and reflectivity of these electrodes preferably satisfy the above-described numerical ranges of the visible light transmittance and reflectivity.

The plurality of light-emitting layers 113 are each provided into an island shape. The plurality of light-emitting layers 113 can have the same structure. Each of the plurality of light-emitting layers 113 preferably emits white light. For example, when the light-emitting layer 113 includes a plurality of light-emitting layers whose emission colors are complementary to each other, the light-emitting device 130 can emit white light.

The light-emitting layer 113 contains a light-emitting substance. The light-emitting layer 113 can contain one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer 113 may contain one or more kinds of organic compounds (e.g., a host material or an assist material) in addition to the light-emitting substance (guest material). As one or more kinds of organic compounds, one or both of a hole-transport material and an electron-transport material can be used. Alternatively, as one or more kinds of organic compounds, a bipolar material or a TADF material may be used.

The light-emitting layer 113 preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from the exciplex to the light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With the above structure, high efficiency, low-voltage driving, and a long lifetime of a light-emitting device can be achieved at the same time.

The first layer 112, the second layer 116, and the common layer 114 each include a layer containing any of a substance with a high hole-injection property, a substance with a high hole-transport property (also referred to as a hole-transport material), a hole-blocking material, a substance with a high electron-transport property (also referred to as an electron-transport material), a substance with a high electron-injection property, an electron-blocking material, a substance with a bipolar property (also referred to as a substance with a high electron- and hole-transport property or a bipolar material), and the like. The first layer 112, the second layer 116, and the common layer 114 may each have a single-layer structure or a stacked-layer structure.

Either a low molecular compound or a high molecular compound can be used in the light-emitting device, and an inorganic compound may also be included. Each layer included in the light-emitting device can be formed by any of the following methods: an evaporation method (including a vacuum evaporation method), a transfer method, a printing method, an inkjet method, a coating method, and the like.

For example, the first layer 112, the second layer 116, and the common layer 114 each include one or more of a hole-injection layer, a hole-transport layer, a hole-blocking layer, an electron-blocking layer, an electron-transport layer, and an electron-injection layer.

The plurality of first layers 112 are each provided into an island shape. The plurality of first layers 112 can have the same structure. In the case where the pixel electrode 111 functions as an anode, the first layer 112 preferably includes at least one of a hole-injection layer, a hole-transport layer, and an electron-blocking layer. In the case where the pixel electrode 111 functions as a cathode, the first layer 112 preferably includes at least one of an electron-injection layer, an electron-transport layer, and a hole-blocking layer.

The plurality of second layers 116 are each provided into an island shape. The plurality of second layers 116 can have the same structure. In the case where the pixel electrode 111 functions as an anode, the second layer 116 preferably includes at least one of an electron-injection layer, an electron-transport layer, and a hole-blocking layer. In the case where the pixel electrode 111 functions as a cathode, the second layer 116 preferably includes at least one of a hole-injection layer, a hole-transport layer, and an electron-blocking layer.

The common layer 114 is provided to be shared by a plurality of light-emitting devices and a plurality of light-receiving devices. In the case where the pixel electrode 111 functions as an anode, the common layer 114 preferably includes an electron-injection layer. In the case where the pixel electrode 111 functions as a cathode, the second layer 116 preferably includes a hole-injection layer. Note that at least one of the light-emitting device 130 and the light-receiving device 150 does not necessarily include the common layer 114.

It is preferable that a carrier-transport layer be included as the second layer 116 over the light-emitting layer 113. Accordingly, the light-emitting layer 113 is inhibited from being exposed on the outermost surface in the step of manufacturing the display device 100, so that damage to the light-emitting layer 113 can be reduced. Thus, the reliability of the light-emitting device can be increased.

The hole-injection layer injects holes from the anode to the hole-transport layer and contains a substance with a high hole-injection property. Examples of a substance with a high hole-injection property include an aromatic amine compound and a composite material containing a hole-transport material and an acceptor material (electron-accepting material).

In the light-emitting device, the hole-transport layer transports holes injected from the anode by the hole-injection layer, to the light-emitting layer. In the light-receiving device, the hole-transport layer transports holes generated in the active layer on the basis of incident light, to the anode. The hole-transport layer is a layer containing a hole-transport material. The hole-transport material preferably has a hole mobility of 1×10⁻⁶ cm²/Vs or higher. Note that other substances can also be used as long as the substances have a hole-transport property higher than an electron-transport property. As the hole-transport material, substances with a high hole-transport property, such as a x-electron rich heteroaromatic compound (e.g., a carbazole derivative, a thiophene derivative, and a furan derivative) and an aromatic amine (a compound having an aromatic amine skeleton), are preferred.

In the light-emitting device, the electron-transport layer transports electrons injected from the cathode by the electron-injection layer, to the light-emitting layer. In the light-receiving device, the electron-transport layer transports electrons generated in the active layer on the basis of incident light, to the cathode. The electron-transport layer contains an electron-transport material. The electron-transport material preferably has an electron mobility of 1×10⁻⁶ cm²/Vs or higher. Note that other substances can also be used as long as the substances have an electron-transport property higher than a hole-transport property. As the electron-transport material, any of the following substances with a high electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a x-electron deficient heteroaromatic compound such as a nitrogen-containing heteroaromatic compound.

The electron-injection layer injects electrons from the cathode to the electron-transport layer and contains a substance with a high electron-injection property. As the substance with a high electron-injection property, an alkali metal, an alkaline earth metal, or a compound thereof can be used. As the substance with a high electron-injection property, a composite material containing an electron-transport material and a donor material (electron-donating material) can also be used.

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFr, where X is a given number), 8-(quinolinolato)lithium (abbreviation: Liq), 2-(2-pyridyl)phenolatolithium (abbreviation: LiPP), 2-(2-pyridyl)-3-pyridinolato lithium (abbreviation: LiPPy), 4-phenyl-2-(2-pyridyl)phenolatolithium (abbreviation: LiPPP), lithium oxide (LiOₓ), or cesium carbonate, for example. The electron-injection layer may have a stacked-layer structure of two or more layers. In the stacked-layer structure, for example, lithium fluoride can be used for the first layer and ytterbium can be used for the second layer.

Alternatively, the electron-injection layer may be formed using an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, and a pyridazine ring), and a triazine ring.

Note that the lowest unoccupied molecular orbital (LUMO) of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-bis(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used as the organic compound having an unshared electron pair. Note that NBPhen has a higher glass transition temperature (Tg) than BPhen and thus has high heat resistance.

In the case of manufacturing a tandem light-emitting device, a charge-generation layer (also referred to as an intermediate layer) is provided between two light-emitting units. The intermediate layer has a function of injecting electrons into one of the two light-emitting units and injecting holes to the other when voltage is applied between the pair of electrodes.

For example, the charge-generation layer can be suitably formed using a material that can be used for the electron-injection layer, such as lithium. As another example, the charge-generation layer can be suitably formed using a material that can be used for the hole-injection layer. Moreover, the charge-generation layer can be a layer containing a hole-transport material and an acceptor material (electron-accepting material). The charge-generation layer can be a layer containing an electron-transport material and a donor material. Forming the charge-generation layer including such a layer can inhibit an increase in the driving voltage that would be caused when the light-emitting units are stacked.

The plurality of active layers 155 are each provided into an island shape. The plurality of active layers 155 can have the same structure. The plurality of active layers 155 are each preferably detect one or both of visible light and infrared light. The active layers 155 may have a single-layer structure or a stacked-layer structure.

The active layer 155 contains a semiconductor. Examples of the semiconductor include an inorganic semiconductor such as silicon and an organic semiconductor including an organic compound. This embodiment describes an example in which an organic semiconductor is used as the semiconductor included in the active layer 155. The use of an organic semiconductor is preferable because the light-emitting layer 113 and the active layer 155 can be formed by the same method (e.g., a vacuum evaporation method) and thus the same manufacturing apparatus can be used.

Examples of an n-type semiconductor material contained in the active layer 155 include electron-accepting organic semiconductor materials such as fullerene (e.g., C₆₀ and C₇₀) and fullerene derivatives. Fullerene has a soccer ball-like shape, which is energetically stable. Both the HOMO level and the LUMO level of fullerene are deep (low). Having a deep LUMO level, fullerene has an extremely high electron-accepting property (acceptor property). When T-electron conjugation (resonance) spreads in a plane as in benzene, the electron-donating property (donor property) usually increases; however, fullerene has a spherical shape, and thus has a high electron-accepting property although x-electron conjugation widely spread therein. The high electron-accepting property efficiently causes rapid charge separation and is useful for the light-receiving device. Both C₆₀ and C₇₀ have a wide absorption band in the visible light region, and C₇₀ is especially preferable because of having a larger x-electron conjugation system and a wider absorption band in the long wavelength region than C₆₀. Other examples of fullerene derivatives include [6,6]-Phenyl-C₇₁-butyric acid methyl ester (abbreviation: PC₇₀BM), [6,6]-Phenyl-C₆₁-(abbreviation: PC₆₀BM), and 1′,1″,4′,4″-Tetrahydro-butyric acid methyl ester di[1,4]methanonaphthaleno[1,2:2′,3′,56,60:2″,3″][5,6]fullerene-C₆₀ (abbreviation: ICBA).

Other examples of an n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material contained in the active layer 155 include electron-donating organic semiconductor materials such as copper(II) phthalocyanine (CuPc), tetraphenyldibenzoperiflanthene (DBP), zinc phthalocyanine (ZnPc), tin (II) phthalocyanine (SnPc), and quinacridone.

Examples of a p-type semiconductor material include a carbazole derivative, a thiophene derivative, a furan derivative, and a compound having an aromatic amine skeleton. Other examples of the p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of similar kinds, which have molecular orbital energy levels close to each other, can increase the carrier-transport property.

For example, the active layer 155 is preferably formed by co-evaporation of an n-type semiconductor and a p-type semiconductor. Alternatively, the active layer 155 may be formed by stacking an n-type semiconductor and a p-type semiconductor.

Either a low molecular compound or a high molecular compound can be used in the light-receiving device, and an inorganic compound may also be contained. Each layer included in the light-receiving device can be formed by an evaporation method (including a vacuum evaporation method), a transfer method, a printing method, an inkjet method, a coating method, or the like.

As the hole-transport material, a high molecular compound such as poly(3,4-ethylenedioxythiophene)/poly(styrenesulfonic acid) (PEDOT/PSS), or an inorganic compound such as molybdenum oxide or copper iodide (Cul) can be used, for example. As the electron-transport material, an inorganic compound such as zinc oxide (ZnO) can be used.

For the active layer 155, a high molecular compound such as Poly[[4,8-bis[5-(2-ethylhexyl)-2-thienyl]benzo[1,2-b:4,5-b′]dithiophene-2,6-diyl]-2,5-thiophenediyl[5,7-bis(2-ethylhexyl)-4,8-dioxo-4H,8H-benzo[1,2-c:4,5-c′]dithiophene-1,3-diyl]] polymer (abbreviation: PBDB-T) or a PBDB-T derivative, which functions as a donor, can be used. For example, a method in which an acceptor material is dispersed to PBDB-T or a PBDB-T derivative can be used.

The active layer 155 may contain a mixture of three or more kinds of materials. For example, a third material may be mixed with an n-type semiconductor material and a p-type semiconductor material in order to extend the absorption wavelength range. The third material may be a low molecular compound or a high molecular compound.

In this embodiment, an example is described in which the light-emitting layer 113 of the light-emitting device 130 and the active layer 155 of the light-receiving device 150 are separately formed and other layers (the first layer 112, the second layer 116, and the common layer 114) are the same between the light-emitting device 130 and the light-receiving device 150; however, one embodiment of the present invention is not limited thereto. For example, a layer containing a substance with a high hole-transport property, a substance with a high electron-transport property, or a substance with a bipolar property (a substance with a high electron-transport property and a high hole-transport property) may further be included in only the light-emitting device 130 or the light-receiving device 150.

### Manufacturing Method Example 1 of display device

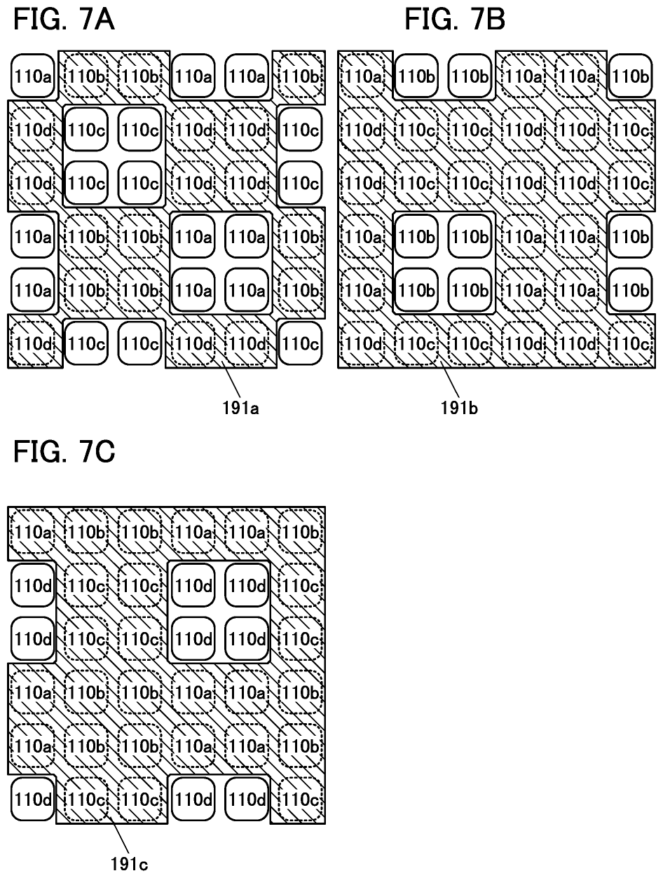

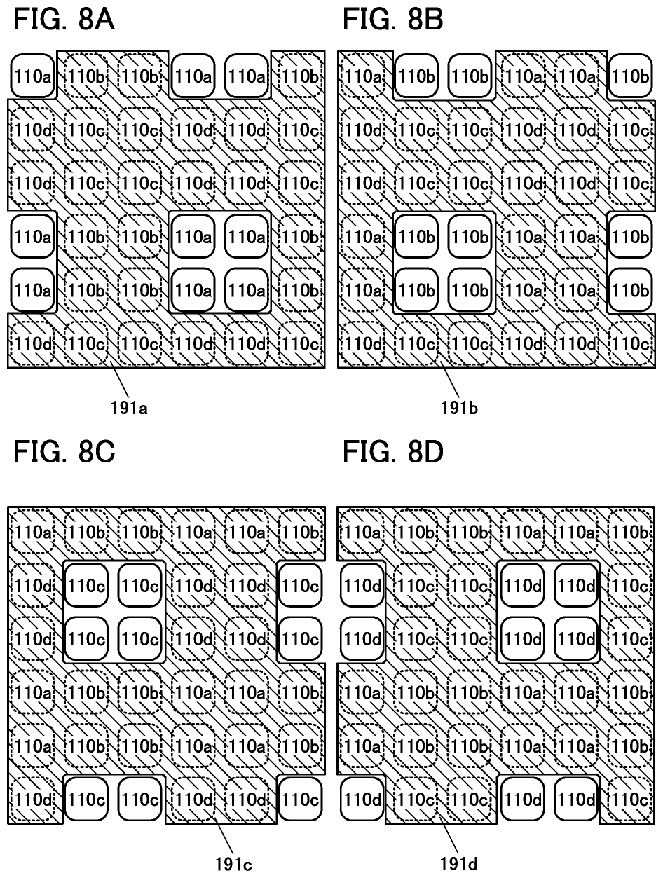

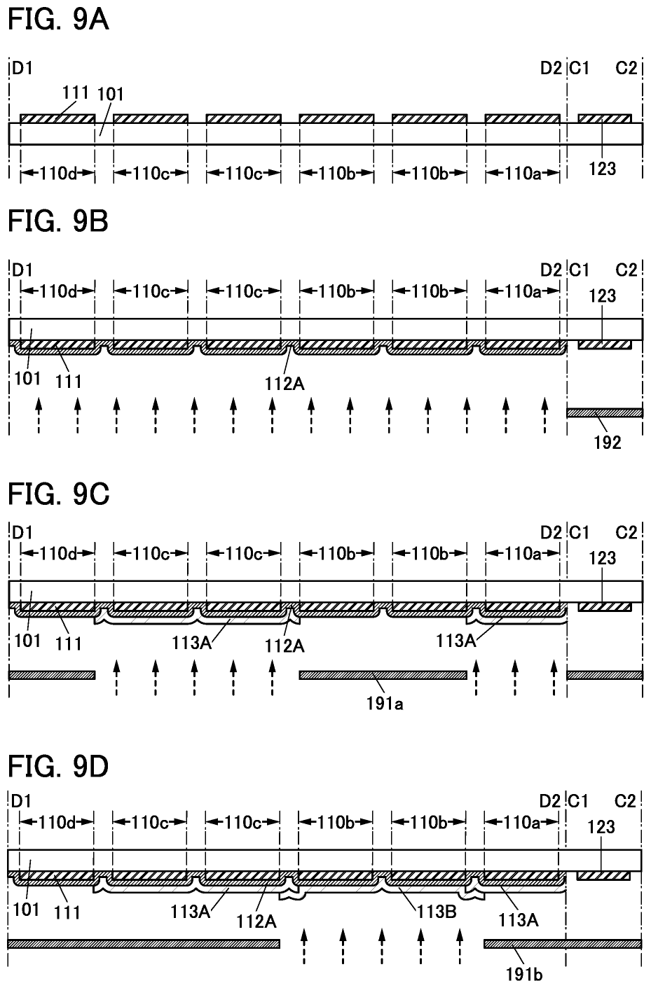

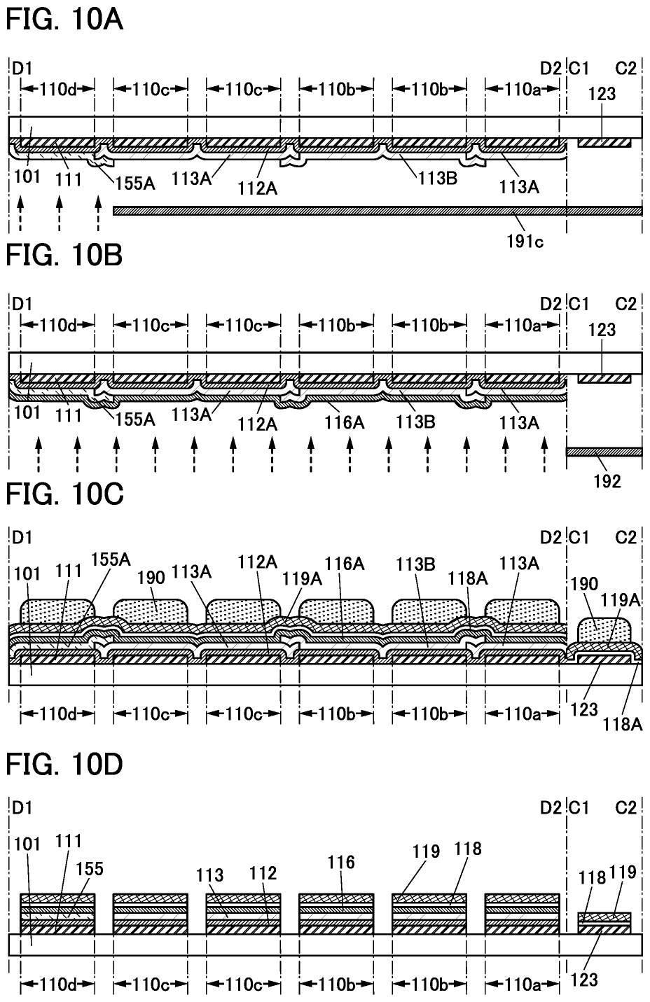

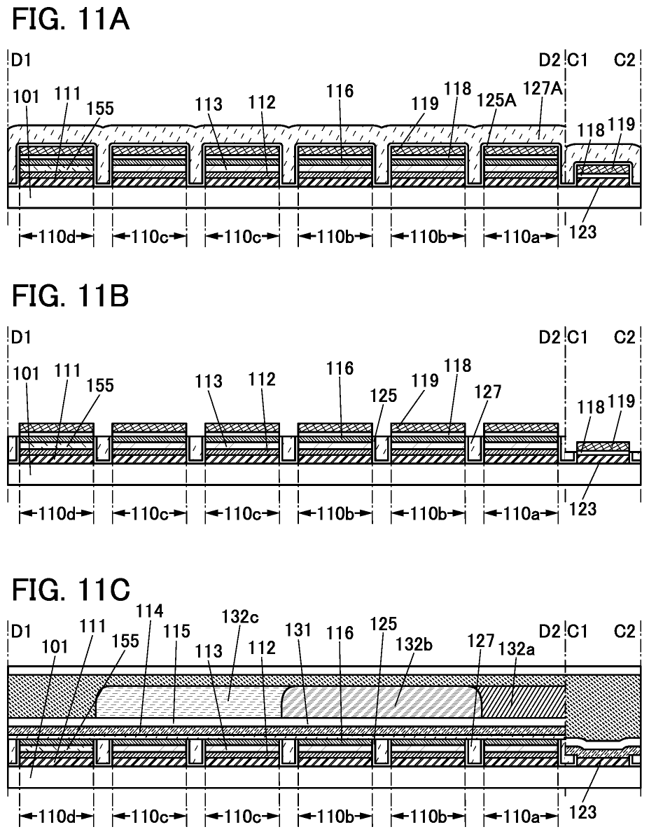

Next, an example of a method for manufacturing the display device will be described with reference to FIG. 7 to FIG. 11. FIG. 7A to FIG. 7C and FIG. 8A to FIG. 8D each illustrate a top view of a fine metal mask used for the method for manufacturing the display device. FIG. 9A to FIG. 9D, FIG. 10A to FIG. 10D, and FIG. 11A to FIG. 11C each illustrate a cross-sectional view along the dashed-dotted line D1-D2 and a cross-sectional view along the dashed-dotted line C1-C2 in FIG. 1A side by side.

Thin films included in the display device (e.g., insulating films, semiconductor films, and conductive films) can be formed by a sputtering method, a CVD method, a vacuum evaporation method, a PLD method, an ALD method, or the like. Examples of a CVD method include a PECVD method and a thermal CVD method. An example of a thermal CVD method is a metal organic chemical vapor deposition (MOCVD: Metal Organic CVD) method.

Alternatively, thin films included in the display device (e.g., insulating films, semiconductor films, and conductive films) can be formed by a method such as spin coating, dipping, spray coating, ink-jetting, dispensing, screen printing, or offset printing or with a doctor knife, a slit coater, a roll coater, a curtain coater, or a knife coater.

Specifically, for manufacture of the light-emitting device, a vacuum process such as an evaporation method and a solution process such as a spin coating method or an inkjet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a light-emitting layer, an electron-transport layer, and an electron-injection layer) included in the EL layer can be formed by an evaporation method (e.g., a vacuum evaporation method), a coating method (e.g., a dip coating method, a die coating method, a bar coating method, a spin coating method, or a spray coating method), a printing method (e.g., an inkjet method, a screen printing (stencil) method, an offset printing (planography) method, a flexography (relief printing) method, a gravure printing method, or a micro-contact printing method), or the like.

Thin films included in the display device can be processed by a photolithography method or the like. Alternatively, thin films may be processed by a nanoimprinting method, a sandblasting method, a lift-off method, or the like. Alternatively, island-shaped thin films may be directly formed by a film formation method using a shielding mask such as a metal mask.

There are two typical methods in a photolithography method. In one of the methods, a resist mask is formed over a thin film that is to be processed, the thin film is processed by etching or the like, and then the resist mask is removed. In the other method, a photosensitive thin film is formed and then processed into a desired shape by light exposure and development.

As light for exposure in a photolithography method, it is possible to use light with the i-line (wavelength: 365 nm), light with the g-line (wavelength: 436 nm), light with the h-line (wavelength: 405 nm), or light in which the i-line, the g-line, and the h-line are mixed. Alternatively, ultraviolet light, KrF laser light, ArF laser light, or the like can be used. Exposure may be performed by liquid immersion exposure technique. As the light for exposure, extreme ultraviolet (EUV) light or X-rays may also be used. Furthermore, instead of the light used for the exposure, an electron beam can also be used. It is preferable to use EUV, X-rays, or an electron beam because extremely minute processing can be performed. Note that a photomask is not needed when exposure is performed by scanning with a beam such as an electron beam.

For etching of thin films, a dry etching method, a wet etching method, a sandblast method, or the like can be used.

First, the pixel electrode 111 and the conductive layer 123 are formed over the layer 101 including a transistor (FIG. 9A). The pixel electrode 111 can be formed by a sputtering method or a vacuum evaporation method, for example.

Next, a first layer 112A that is to be the first layer 112 later is formed over the pixel electrode 111 and the layer 101 including a transistor (FIG. 9B).

The first layer 112A can be formed by an evaporation method, specifically a vacuum evaporation method, for example. FIG. 9B illustrates a state where film formation is performed under a condition that the substrate is inverted so that a film formation surface faces downward, i.e., film formation is performed with a face-down system. In the other drawings, a state where film formation is performed with a face-down system is illustrated when film formation is performed by an evaporation method

The first layer 112A may be formed by a transfer method, a printing method, an inkjet method, a coating method, or the like.

As illustrated in FIG. 9B, the first layer 112A is not formed over the conductive layer 123 in the cross sectional view along the dashed-dotted line C1-C2. For example, a mask 192 for specifying a film formation area (also referred to as an area mask or a rough metal mask to distinguish from a fine metal mask) is used, so that the first layer 112A can be formed only in a desired region.

Next, a light-emitting layer 113A that is to be the light-emitting layer 113 later is formed over the first layer 112A (FIG. 9C). The light-emitting layer 113A can have a single-layer structure or a stacked-layer structure, and the structure emitting white light can be used.

The light-emitting layer 113A can be formed by an evaporation method, specifically, a vacuum evaporation method, using a fine metal mask 191a.

As illustrated in FIG. 7A, the fine metal mask 191a includes openings in a region to be the subpixel 110a and a region to be the subpixel 110c. Thus, as illustrated in FIG. 9C, the light-emitting layer 113A can be selectively formed over the first layer 112A in the region to be the subpixel 110a and the region to be the subpixel 110c.

Next, a light-emitting layer 113B to be the light-emitting layer 113 later is formed over the first layer 112A (FIG. 9D). The light-emitting layer 113B can be formed using a material similar to that of the light-emitting layer 113A.

The light-emitting layer 113B can be formed by an evaporation method, specifically, a vacuum evaporation method, using a fine metal mask 191b.

As illustrated in FIG. 7B, the fine metal mask 191b has an opening in a region to be the subpixel 110b. Thus, as illustrated in FIG. 9D, the light-emitting layer 113B can be selectively formed over the first layer 112A in the region to be the subpixel 110b. Note that FIG. 9D illustrates an example where the end portion of the light-emitting layer 113B overlaps with the light-emitting layer 113A. The light-emitting layer 113A and the light-emitting layer 113B may overlap with each other or may be separated from each other without overlapping with each other.

Subsequently, an active layer 155A that is to be the active layer 155 later is formed over the first layer 112A (FIG. 10A). The active layer 155A can have a single-layer structure or a stacked-layer structure.

The active layer 155A can be formed by an evaporation method, specifically, a vacuum evaporation method, using a fine metal mask 191c.

As illustrated in FIG. 7C, the fine metal mask 191c has an opening in a region to be the subpixel 110d. Thus, as illustrated in FIG. 10A, the active layer 155A can be selectively formed over the first layer 112A in the region to be the subpixel 110d. Note that FIG. 10A illustrates an example where the end portion of the active layer 155A overlaps with the light-emitting layer 113A. The light-emitting layer 113A and the active layer 155A may overlap with each other or may be separated from each other without overlapping with each other.

As described above, an evaporation step is performed three times using the three fine metal masks illustrated in FIG. 7A to FIG. 7C, whereby the light-emitting layer and the active layer can be separately formed for the subpixels. Alternatively, an evaporation step is performed four times using four fine metal masks illustrated in FIG. 8A to FIG. 8D, whereby the light-emitting layer and the active layer can be separately formed for the subpixels. The fine metal mask 191a illustrated in FIG. 8A has an opening in the region to be the subpixel 110a. The fine metal mask 191b illustrated in FIG. 8B has an opening in the region to be the subpixel 110b. The fine metal mask 191c illustrated in FIG. 8C has an opening in the region to be the subpixel 110c. A fine metal mask 191d illustrated in FIG. 8D has an opening in the region to be the subpixel 110d.

The formation order of the light-emitting layers and the active layer is not particularly limited, and the light-emitting layer 113A and the light-emitting layer 113B may be formed after the active layer 155A is formed.

Next, a second layer 116A that is to be the second layer 116 later is formed over the light-emitting layer 113A, the light-emitting layer 113B, and the active layer 155A (FIG. 10B).

As illustrated in FIG. 10B, the second layer 116A is not formed over the conductive layer 123 in the cross sectional view along the dashed-dotted line C1-C2. For example, the use of the mask 192 for specifying a film formation area enables the second layer 116A to be formed only in a desired region.

Next, over the second layer 116A and the conductive layer 123, a sacrificial layer 118A that is to be the sacrificial layer 118 and a sacrificial layer 119A that is to be the sacrificial layer 119 are sequentially formed (FIG. 10C). For the sacrificial layer 118A and the sacrificial layer 119A, a film that is highly resistant to the process conditions for the first layer 112A, the light-emitting layers 113A and 113B, the active layer 155A, and the second layer 116A, specifically, a film having high etching selectivity with these films is used.

The sacrificial layer 118A and the sacrificial layer 119A can be formed by a sputtering method, an ALD method (including a thermal ALD method or a PEALD method), a CVD method, or a vacuum evaporation method, for example. The sacrificial layer 118A is preferably formed by a formation method that causes less damage to the second layer 116A than a formation method for the sacrificial layer 119A. For example, the sacrificial layer 118A is preferably formed by an ALD method or a vacuum evaporation method rather than a sputtering method. The sacrificial layer 118A and the sacrificial layer 119A are formed at a temperature lower than the upper temperature limit of the first layer 112A, the light-emitting layers 113A and 113B, the active layer 155A, and the second layer 116A. The typical substrate temperatures in formation of the sacrificial layer 118A and the sacrificial layer 119A are each lower than or equal to 200° C., preferably lower than or equal to 150° C., further preferably lower than or equal to 120° C., still further preferably lower than or equal to 100° C., yet still further preferably lower than or equal to 80° C.

The sacrificial layer 118A and the sacrificial layer 119A are preferably films that can be removed by a wet etching method. The use of a wet etching method can reduce damage to the light-emitting layers 113A and 113B and the active layer 155A in processing of the sacrificial layer 118A and the sacrificial layer 119A, compared to the case of using a dry etching method.

The sacrificial layer 118A is preferably a film having high etching selectivity with the sacrificial layer 119A.

In the method for manufacturing the display device of this embodiment, it is preferred that the first layer 112A, the second layer 116A, the light-emitting layers 113A and 113B, and the active layer 155A not be easily processed in the step of processing the sacrificial layers, and that the sacrificial layers not be easily processed in the steps of processing the first layer 112A, the second layer 116A, the light-emitting layers 113A and 113B, and the active layer 155A. In consideration of the above, the materials and a processing method for the sacrificial layers and processing methods for the first layer 112A, the second layer 116A, the light-emitting layers 113A and 113B, and the active layer 155A are preferably selected.

Although this embodiment describes an example in which the sacrificial layer is formed with a two-layer structure of the sacrificial layer 118A and the sacrificial layer 119A, the sacrificial layer may have a single-layer structure or a stacked-layer structure of three or more layers.

As the sacrificial layer 118A and the sacrificial layer 119A, it is preferable to use an inorganic film such as a metal film, an alloy film, a metal oxide film, a semiconductor film, or an inorganic insulating film, for example.

For the sacrificial layer 118A and the sacrificial layer 119A, it is preferable to use a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials, for example. It is particularly preferable to use a low-melting-point material such as aluminum or silver. The use of a metal material capable of blocking ultraviolet light for one or both of the sacrificial layer 118A and the sacrificial layer 119A is preferable, in which case the EL layer can be inhibited from being irradiated with ultraviolet light and deteriorating.

For the sacrificial layer 118A and the sacrificial layer 119A, a metal oxide such as In—Ga—Zn oxide can be used. As the sacrificial layer 118A or the sacrificial layer 119A, an In—Ga—Zn oxide film can be formed by a sputtering method, for example. Furthermore, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or the like can be used. Indium tin oxide containing silicon, or the like can also be used.

In addition, in place of gallium described above, an element M (M is one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, magnesium, and the like) may be used.

As the sacrificial layer 118A and the sacrificial layer 119A, a variety of inorganic insulating films that can be used as the protective layer 131 can be used. In particular, an oxide insulating film is preferable because its adhesion to the EL layer is higher than that of a nitride insulating film. For example, an inorganic insulating material such as aluminum oxide, hafnium oxide, or silicon oxide can be used for the sacrificial layer 118A and the sacrificial layer 119A. As the sacrificial layer 118A or the sacrificial layer 119A, an aluminum oxide film can be formed by an ALD method, for example. The use of an ALD method is preferable, in which case damage to a base (in particular, the EL layer or the like) can be reduced.

For example, an inorganic insulating film (e.g., an aluminum oxide film) formed by an ALD method can be used as the sacrificial layer 118A, and an inorganic film (e.g., an In—Ga—Zn oxide film, an aluminum film, or a tungsten film) formed by a sputtering method can be used as the sacrificial layer 119A.

Note that the same inorganic insulating film can be used for both the sacrificial layer 118A and the insulating layer 125 that is to be formed later. For example, an aluminum oxide film formed by an ALD method can be used for both the sacrificial layer 118A and the insulating layer 125. Here, for the sacrificial layer 118A and the insulating layer 125, the same film-formation condition may be used or different film-formation conditions may be used. For example, when the sacrificial layer 118A is formed under conditions similar to those of the insulating layer 125, the sacrificial layer 118A can be an insulating layer having a high barrier property against at least one of water and oxygen. Meanwhile, since the sacrificial layer 118A is a layer almost or all of which is to be removed in a later step, it is preferable that the processing of the sacrificial layer 118A be easy. Therefore, the sacrificial layer 118A is preferably formed with a substrate temperature lower than that for formation of the insulating layer 125.

A material dissolvable in a solvent that is chemically stable with respect to at least a film on the outermost side of the light-emitting layer 113A may be used for one or both of the sacrificial layer 118A and the sacrificial layer 119A. Specifically, a material that will be dissolved in water or alcohol can be suitably used. In forming a film of such a material, it is preferable to apply the material dissolved in a solvent such as water or alcohol by a wet film formation method and then perform heat treatment for evaporating the solvent. At this time, the heat treatment is preferably performed in a reduced-pressure atmosphere, in which case the solvent can be removed at a low temperature in a short time and thermal damage to the EL layer can be reduced accordingly.

The sacrificial layer 118A and the sacrificial layer 119A may be formed by a wet film formation method such as spin coating, dipping, spray coating, ink-jetting, dispensing, screen printing, offset printing, doctor blade coating, slit coating, roll coating, curtain coating, or knife coating.

The sacrificial layer 118A and the sacrificial layer 119A may be formed using an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin.

Next, a resist mask 190 is formed over the sacrificial layer 119A (FIG. 10C). The resist mask 190 can be formed by application of a photosensitive resin (photoresist), exposure, and development.

The resist mask may be formed using either a positive resist material or a negative resist material.

The resist mask 190 is provided at a position overlapping with the pixel electrode 111. As the resist mask 190, one island-shaped pattern is preferably provided for one subpixel 110.

Note that the resist mask 190 is preferably provided also at a position overlapping with the conductive layer 123. This can inhibit the conductive layer 123 from being damaged during the step of manufacturing the display device. Note that the resist mask 190 is not necessarily provided over the conductive layer 123.

Next, part of the sacrificial layer 119A is removed with use of the resist mask 190, so that the sacrificial layer 119 is formed (FIG. 10D). The sacrificial layer 119 partly remains over the pixel electrode 111 and the conductive layer 123.

In the etching of the sacrificial layer 119A, an etching condition with high selectivity is preferably employed so that the sacrificial layer 118A is not removed by the etching. Since the light-emitting layers 113A and 113B and the active layer 155A are not exposed in processing the sacrificial layer 119A, the range of choices of the processing method is wider than that for processing the sacrificial layer 118A. Specifically, deterioration of the light-emitting layers 113A and 113B and the active layer 155A can be further inhibited even when a gas containing oxygen is used as an etching gas for processing the sacrificial layer 119A.

After that, the resist mask 190 is removed. The resist mask 190 can be removed by ashing using oxygen plasma or the like, for example. Alternatively, an oxygen gas and any of CF₄, C₄F₈, SF₆, CHF₃, Cl₂, H₂O, BCl₃, or a noble gas (also referred to as a rare gas) such as He. Alternatively, the resist mask 190 may be removed by wet etching. At this time, the sacrificial layer 118A is positioned on the outermost surface, and the light-emitting layers 113A and 113B and the active layer 155A are not exposed; thus, the light-emitting layers 113A and 113B and the active layer 155A can be inhibited from being damaged in the step of removing the resist mask 190. In addition, the range of choices of the method for removing the resist mask 190 can be widened.

Next, part of the sacrificial layer 118A is removed with use of the sacrificial layer 119 as a mask (also referred to as hard mask) to form the sacrificial layer 118 (FIG. 10D).

The sacrificial layer 118A and the sacrificial layer 119A can be processed by a wet etching method or a dry etching method. The sacrificial layer 118A and the sacrificial layer 119A are preferably processed by anisotropic etching.

The use of a wet etching method can reduce damage to the light-emitting layers 113A and 113B and the active layer 155A in processing of the sacrificial layer 118A and the sacrificial layer 119A, compared to the case of using a dry etching method. In the case of using a wet etching method, it is preferable to use a chemical solution of a developer, an aqueous solution of tetramethylammonium hydroxide (TMAH), dilute hydrofluoric acid, oxalic acid, phosphoric acid, acetic acid, nitric acid, a mixed solution thereof, or the like, for example.

In the case of using a dry etching method, deterioration of the light-emitting layers 113A and 113B and the active layer 155A can be inhibited by not using a gas containing oxygen as the etching gas. In the case of using a dry etching method, it is preferable to use a gas containing CF₄, C₄F₈, SF₆, CHF₃, Cl₂, H₂O, or BCl₃ or a noble gas (also referred to as a rare gas) such as He as the etching gas, for example.

For example, when an aluminum oxide film formed by an ALD method is used as the sacrificial layer 118A, the sacrificial layer 118A can be processed by a dry etching method using CHF₃ and He. In the case where an In—Ga—Zn oxide film formed by a sputtering method is used as the sacrificial layer 119A, the sacrificial layer 119A can be processed by a wet etching method using a diluted phosphoric acid. Alternatively, the sacrificial layer 119A may be processed by a dry etching method using CH₄ and Ar. Alternatively, the sacrificial layer 119A can be processed by a wet etching method using a diluted phosphoric acid. When a tungsten film formed by a sputtering method is used as the sacrificial layer 119A, the sacrificial layer 119A can be processed by a dry etching method using a combination of SF₆, CF₄, and O₂ or a combination of CF₄, Cl₂, and O₂.

Next, the first layer 112A, the light-emitting layers 113A and 113B, the active layer 155A, and the second layer 116A are processed, so that one first layer 112, one light-emitting layer 113, and one second layer 116 are formed into island shapes for one pixel electrode 111 in the subpixel 110a to the subpixel 110c, and one first layer 112, one active layer 155, and one second layer 116 are formed into island shapes for one pixel electrode 111 in the subpixel 110d. For example, the first layer 112A, the light-emitting layers 113A and 113B, the active layer 155A, and the second layer 116A are removed using the sacrificial layer 119 and the sacrificial layer 118 as hard masks, whereby the first layer 112, the light-emitting layer 113, the active layer 155, and the second layer 116 are formed (FIG. 10D).

As illustrated in FIG. 10D, the first layer 112A, the light-emitting layers 113A and 113B, the active layer 155A, and the second layer 116A are processed, whereby the plurality of first layers 112, the plurality of light-emitting layers 113, the plurality of active layers 155, and the plurality of second layers 116 can be formed. That is, the first layer 112A, the light-emitting layers 113A and 113B, the active layer 155A, and the second layer 116A can be divided into the plurality of first layers 112, the plurality of light-emitting layers 113, the plurality of active layers 155, and the plurality of second layers 116, respectively. Note that the light-emitting layers 113A and 113B are not necessarily divided in either the row direction or the column direction. In that case, the light-emitting layer 113 can have a belt-like shape.

The first layer 112A, the light-emitting layers 113A and 113B, the active layer 155A, and the second layer 116A are preferably processed by anisotropic etching. In particular, an anisotropic dry etching is preferably used. Alternatively, a wet etching may be used.

In the case of using a dry etching method, deterioration of the light-emitting layer 113A can be inhibited by not using a gas containing oxygen as the etching gas.

A gas containing oxygen may be used as the etching gas. When the etching gas contains oxygen, the etching rate can be increased. Therefore, the etching can be performed under a low-power condition while an adequately high etching rate is maintained. Thus, damage to the first layer 112A, the light-emitting layers 113A and 113B, the active layer 155A, and the second layer 116A can be inhibited. Furthermore, a defect such as attachment of a reaction product generated at the etching can be inhibited.

In the case of using a dry etching method, it is preferable to use a gas containing at least one of H₂, CF₄, C₄F₈, SF₆, CHF₃, Cl₂, H₂O, BCl₃, and a noble gas (also referred to as a rare gas) such as He and Ar as the etching gas, for example. Alternatively, a gas containing oxygen and at least one of the above is preferably used as the etching gas. Alternatively, an oxygen gas may be used as the etching gas. Specifically, for example, a gas containing H₂ and Ar or a gas containing CF₄ and He can be used as the etching gas. As another example, a gas containing CF₄, He, and oxygen can be used as the etching gas.

As described above, in one embodiment of the present invention, the sacrificial layer 119 is formed in the following manner: the resist mask 190 is formed over the sacrificial layer 119A; and part of the sacrificial layer 119A is removed with use of the resist mask 190. After that, part of the first layer 112A, the light-emitting layers 113A and 113B, the active layer 155A, and the second layer 116A are removed with use of the sacrificial layer 119 as a hard mask, so that the first layer 112, the light-emitting layer 113, the active layer 155, and the second layer 116 are formed. Thus, the first layer 112, the light-emitting layer 113, the active layer 155, and the second layer 116 can be formed by processing the first layer 112A, the light-emitting layers 113A and 113B, the active layer 155A, and the second layer 116A with a photolithography method. Note that part of the first layer 112A, the light-emitting layers 113A and 113B, the active layer 155A, and the second layer 116A may be removed using the resist mask 190. Then, the resist mask 190 may be removed.

As described above, in the method for manufacturing the display device of one embodiment of the present invention, the first layer 112A, the light-emitting layers 113A and 113B, the active layer 155A, and the second layer 116A are formed by a vacuum evaporation method using a metal mask or the like, and then these layers are divided by a photolithography method, so that the first layer 112, the light-emitting layer 113, the active layer 155, and the second layer 116 are formed. Thus, the shapes of these layers can be reduced in size. Accordingly, a high-resolution display device or a display device having a high aperture ratio, which has been difficult to achieve, can be manufactured.

Each subpixel includes the island-shaped first layer 112, the island-shaped light-emitting layer 113, and the island-shaped second layer 116, which can inhibit generation of leakage current between the subpixels. Accordingly, degradation of the display quality of the display device can be inhibited. In addition, both the higher resolution and higher display quality of the display device can be achieved. Similarly, island-shaped layers included in the light-receiving device are provided for subpixels, which can inhibit generation of leakage current between the subpixels. Accordingly, a reduction in the accuracy of light detection in the display device can be inhibited.

Next, an insulating film 125A that is to be the insulating layer 125 later is formed to over the pixel electrode 111, the first layer 112, the light-emitting layer 113, the active layer 155, the second layer 116, the sacrificial layer 118, and the sacrificial layer 119 (FIG. 11A).

As the insulating film 125A, an insulating film is preferably formed at a substrate temperature higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C. to have a thickness greater than or equal to 3 nm, greater than or equal to 5 nm, or greater than or equal to 10 nm and less than or equal to 200 nm, less than or equal to 150 nm, less than or equal to 100 nm, or less than or equal to 50 nm, for example.

As the insulating film 125A, an aluminum oxide film is preferably formed by an ALD method, for example.

Then, an insulating film 127A is formed over the insulating film 125A (FIG. 11A). A photosensitive material, for example, a photosensitive resin, can be used for the insulating film 127A. For example, the insulating film 127A can be formed by a wet film formation method such as spin coating, dipping, spray coating, ink-jetting, dispensing, screen printing, offset printing, doctor blade coating, slit coating, roll coating, curtain coating, or knife coating. Specifically, an organic insulating film that is to be the insulating film 127 is preferably formed by spin coating.

The insulating film 125A and the insulating film 127A are preferably formed by a formation method by which the first layer 112, the light-emitting layer 113, the active layer 155, and the second layer 116 are less damaged. In particular, the insulating film 125A, which is formed in contact with the side surfaces of the first layer 112, the light-emitting layer 113, the active layer 155, and the second layer 116, are preferably formed by a formation method that causes less damage to the first layer 112, the light-emitting layer 113, the active layer 155, and the second layer 116 than the method of forming the insulating film 127A. The insulating film 125A and the insulating film 127A are each formed at a temperature lower than the upper temperature limit of the first layer 112, the light-emitting layer 113, the active layer 155, and the second layer 116. The typical substrate temperatures in formation of the insulating film 125A and the insulating film 127A are each lower than or equal to 200° C., preferably lower than or equal to 180° C., further preferably lower than or equal to 160° C., still further preferably lower than or equal to 150° C., yet still further preferably lower than or equal to 140° C. As the insulating film 125A, an aluminum oxide film can be formed by an ALD method, for example. The use of an ALD method is preferable, in which case damage by the film formation is reduced and a film with good coverage can be formed.

Next, the insulating film 127A is processed to form the insulating layer 127 (FIG. 11B). For example, in the case where a photosensitive material is used for the insulating film 127A, exposure and development are performed on the insulating film 127A, whereby the insulating layer 127 can be formed. Etching may be performed so that the surface level of the insulating layer 127 is adjusted. The insulating layer 127 may be processed by ashing using oxygen plasma, for example.

Next, at least part of the insulating film 125A is removed, so that the insulating layer 125 is formed (FIG. 11B).

The insulating film 125A is preferably processed by a dry etching method. The insulating film 125A is preferably processed by anisotropic etching. The insulating film 125A can be processed using an etching gas that can be used for processing the sacrificial layer.

After that, the sacrificial layer 119 and the sacrificial layer 118 are removed. Accordingly, at least part of the top surface of the second layer 116 and the top surface of the conductive layer 123 are exposed.

For the removal of the sacrificial layer, a wet etching method is preferably used. With this method, damage given to the light-emitting layer 113 and the active layer 155 in removal of the sacrificial layer can be reduced as compared to the case where the sacrificial layer is removed by a dry etching method, for example.

The sacrificial layer may be removed by being dissolved in a solvent such as water or alcohol. Examples of alcohol include ethyl alcohol, methyl alcohol, isopropyl alcohol (IPA), and glycerin.

After the sacrificial layer is removed, drying treatment may be performed to remove water included in the EL layer or the like and water adsorbed on the surface of the EL layer or the like. For example, heat treatment in an inert gas atmosphere or a reduced-pressure atmosphere can be performed. The heat treatment can be performed with a substrate temperature higher than or equal to 50° C. and lower than or equal to 200° C., preferably higher than or equal to 60° C. and lower than or equal to 150° C., further preferably higher than or equal to 70° C. and lower than or equal to 120° C. Employing a reduced-pressure atmosphere is preferable, in which case drying at a lower temperature is possible.

Next, the common layer 114 is formed over the insulating layer 125, the insulating layer 127, and the second layer 116. Then, the common electrode 115 is formed over the common layer 114 (FIG. 11C).

The common layer 114 can be formed by an evaporation method (including a vacuum evaporation method), a transfer method, a printing method, an inkjet method, a coating method, or the like. As described above, the common layer 114 can include an electron-injection layer or a hole-injection layer, for example.

The common electrode 115 can be formed by a sputtering method or a vacuum evaporation method, for example. Alternatively, the common electrode 115 may be a stack of a film formed by an evaporation method and a film formed by a sputtering method.

Next, the protective layer 131 is formed over the common electrode 115, and the coloring layers 132a, 132b and 132c are formed over the protective layer 131 (FIG. 11C). In addition, the substrate 120 is bonded onto the protective layer 131 and the coloring layers 132a, 132b, and 132c with the resin layer 122, whereby the display device 100 can be manufactured.

Examples of methods for forming the protective layer 131 include a vacuum evaporation method, a sputtering method, a CVD method, and an ALD method. The protective layer 131 may have a single-layer structure or a stacked-layer structure. [Manufacturing Method Example 2 of display device]

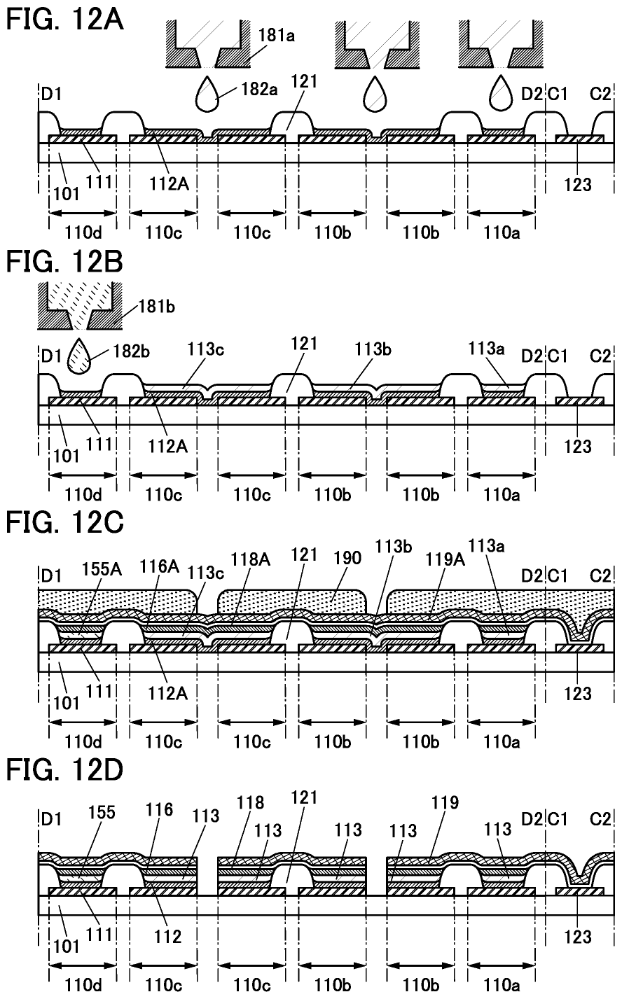

Although an example in which the light-emitting layer of the light-emitting device and the active layer of the light-receiving layer are formed by an evaporation method is described in the above Manufacturing Method Example 1, one embodiment of the present invention is not limited thereto. In Manufacturing Method Example 2, an example of forming light-emitting layers 113a, 113b, and 113c, the active layer 155A, and the like using a wet process, specifically, an inkjet method is described with reference to FIG. 12A and FIG. 12B.

For example, a light-receiving device that detects infrared light can achieve favorable characteristics with the use of a high molecular material. Therefore, this Manufacturing Method Example 2 is preferable in manufacturing a light-receiving device that detects infrared light.

FIG. 12A illustrates a state where droplets 182a that are to be the light-emitting layers 113a, 113b, and 113c are dropped by an inkjet method. Note that FIG. 12A illustrates an example in which the first layer 112A has already been provided over the pixel electrode 111 by an inkjet method. A nozzle 181a of an inkjet apparatus is placed to face the layer 101 including a transistor, and the droplets 182a are dropped from the nozzle 181a onto the first layer 112A. Specifically, the droplets 182a are dropped to regions corresponding to the subpixel 110a to the subpixel 110c.

The droplet 182a contains an organic compound for forming a light-emitting layer and a solvent. The droplet 182a may contain at least a light-emitting material as the organic compound and may further contain at least one of a hole-injection material, a hole-transport material, a hole-blocking material, an electron-blocking material, an electron-transport material, and the like.

As illustrated in FIG. 12B, the light-emitting layers 113a, 113b, and 113c are formed over the first layer 112A. Here, in the light-emitting layers 113a, 113b, and 113c, the solvents included in the droplets may be vaporized through a drying step or the like. Heat may be added in the drying step.

At least surfaces of the light-emitting layers 113a, 113b, and 113c may be cured through a light irradiation step or the like. As the light, ultraviolet light or infrared light can be used.

FIG. 12B illustrates a state where droplet 182b that is to be the active layer 155A is dropped by an inkjet method. A nozzle 181b of an inkjet apparatus is placed to face the layer 101 including a transistor, and the droplet 182b are dropped from the nozzle 181b onto the first layer 112A. Specifically, the droplet 182b are dropped to a region corresponding to the subpixel 110d.

The droplet 182b contains an organic compound and a solvent. The droplet 182b may contain at least a semiconductor material (e.g., at least one of a p-type semiconductor material and an n-type semiconductor material) as the organic compound and may further contain at least one of a hole-transport material, a hole-blocking material, an electron-blocking material, an electron-transport material, and the like.

The dropping of the droplets 182a and the droplet 182b at the same time is preferable because the productivity is high. Alternatively, one of the droplet 182a and the droplet 182b may be dropped first, and then the other of the droplets may be dropped. For example, a curing step may be provided between the dropping of the droplets 182a and the dropping of the droplet 182b. Thus, it might be possible to prevent mixing of the droplets dropped first and the droplets dropped later.

Next, over the light-emitting layers 113a, 113b, and 113c and the active layer 155A, the second layer 116A, the sacrificial layer 118A, the sacrificial layer 119A, and the resist mask 190 are sequentially formed as in Manufacturing Method Example 1 (FIG. 12C). Then, as illustrated in FIG. 12D, the first layer 112A, the light-emitting layers 113a, 113b, and 113c, the active layer 155A, and the second layer 116A are processed, so that one first layer 112, one light-emitting layer 113, and one second layer 116 are formed into island shapes for one pixel electrode 111 in the subpixel 110a to the subpixel 110c, and one first layer 112, one active layer 155, and one second layer 116 are formed into island shapes for one pixel electrode 111 in the subpixel 110d.

Each subpixel includes an island-shaped EL layer, which can inhibit generation of leakage current between the subpixels. Accordingly, degradation of the display quality of the display device can be inhibited. In addition, both the higher resolution and higher display quality of the display device can be achieved. Similarly, island-shaped layers included in the light-receiving device are provided for subpixels, which can inhibit generation of leakage current between the subpixels. Accordingly, a reduction in the accuracy of light detection in the display device can be inhibited.

### Structure Example 2 of Display Device

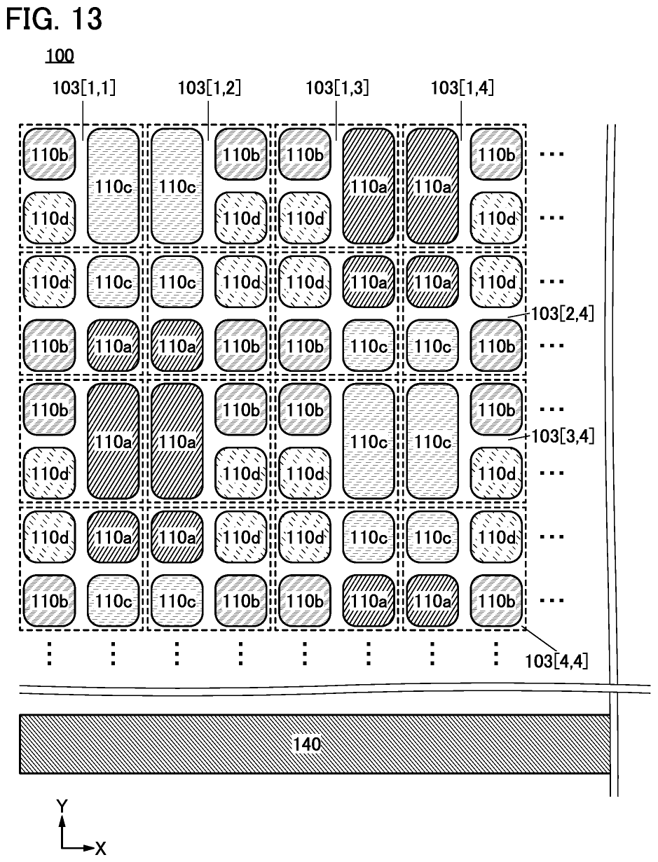

Although pixel arrangement of the display device 100 in FIG. 1 is a Bayer arrangement, one embodiment of the present invention is not limited thereto. FIG. 13 is a top view illustrating a structure example of the display device 100 whose part of the pixel arrangement is an S-stripe arrangement.

FIG. 13 illustrates the pixels 103 in four rows and four columns. Eight pixels 103 in two rows and two columns have different subpixel arrangements.

The pixel 103[1,1] and the pixel 103[1,2] each include three types of subpixels 110b, 110c, and 110d. The pixel 103[1,3] and the pixel 103[1,4] each include three types of subpixels 110a, 110b, and 110d. The pixel 103[2,1] to the pixel 103[2,4] each include four types of subpixels 110a, 110b, 110c, and 110d. Three out of the subpixels 110a, 110b, 110c, and 110d each include a light-emitting device and emit light of different colors. As the three subpixels, subpixels of three colors of red (R), green (G), and blue (B), subpixels of three colors of yellow (Y), cyan (C), and magenta (M), and the like can be given. The other subpixel has a light-receiving device and has a function of detecting light.

As illustrated in FIG. 13, for example, the subpixels 110 in the fourth row and the second column to the seventh row and the third column are the subpixels 110a. In addition, the subpixels 110 in the fourth row and the fourth column, in the fourth row and the fifth column, in the fifth row and the fourth column, and in the fifth row and the fifth column are the subpixels 110b. For example, the subpixels 110 in the fourth row and the sixth column to the seventh row and the seventh column are the subpixels 110c. Furthermore, the subpixels 110 in the sixth row and the fourth column, in the sixth row and the fifth column, in the seventh row and the fourth column, and in the seventh row and the fifth column are the subpixels 110d. That is, the subpixels 110a and the subpixels 110c are each arranged in four rows and two columns to be adjacent to each other, for example. The subpixels 110b and the subpixels 110d are each arranged in two rows and two columns to be adjacent to each other, for example. Note that the subpixels 110a and the subpixels 110c may each be arranged in five or more rows to be adjacent to each other, and the subpixels 110b and the subpixels 110d may each be arranged in two or more rows to be adjacent to each other. Furthermore, the subpixels 110a, the subpixels 110b, the subpixels 110c, and the subpixels 110d may each be arranged in three or more columns to be adjacent to each other.

### Structure Example 3 of Display Device

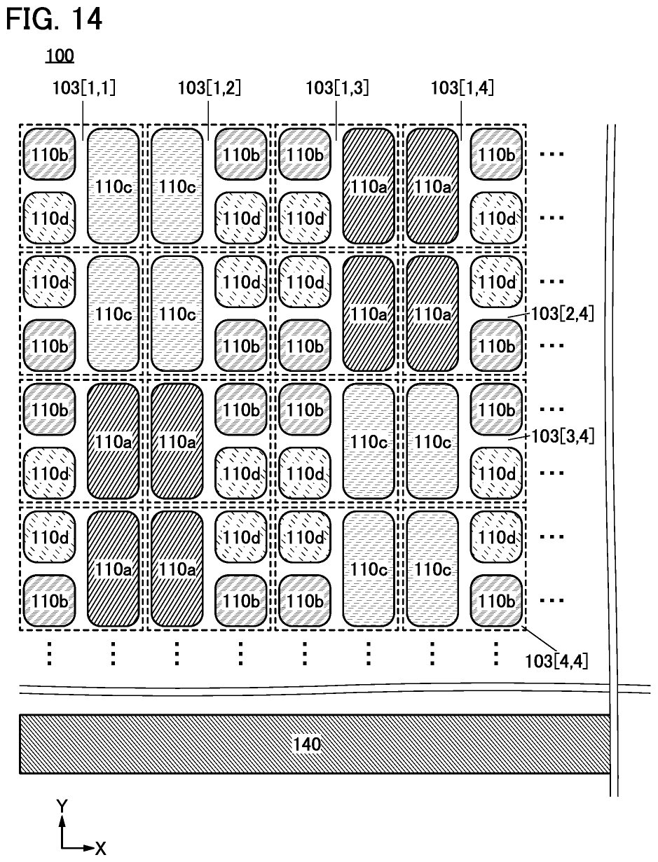

FIG. 14 is a top view illustrating a structure example of the display device 100 and is a variation example of the display device 100 illustrated in FIG. 13. The display device 100 illustrated in FIG. 13 includes the pixels 103 including three subpixels 110 and the pixels 103 including four subpixels 110. Meanwhile, in the display device 100 illustrated in FIG. 14, all the pixels 103 each include three subpixels 110.

FIG. 14 illustrates the pixels 103 in four rows and four columns. Eight pixels 103 in two rows and two columns have different subpixel arrangements.

The pixel 103[1,1], the pixel 103[1,2], the pixel 103[2,1], and the pixel 103[2,2] each include three types of subpixels 110b, 110c, and 110d. The pixel 103[1,3], the pixel 103[1,4], the pixel 103[2,3], and the pixel 103[2,4] each include three types of subpixels 110a, 110b, and 110d.

The display device in FIG. 14 has a portion where a first arrangement pattern with two columns and a second arrangement pattern with two columns are repeated in the row direction (X direction). In the first arrangement pattern, two subpixels 110a and two subpixels 110c are repeated in the column direction (Y direction). In the second arrangement pattern, two subpixels 110b and two subpixels 110d are repeated in the column direction (Y direction).

In the case where image data is written to the pixels 103 in the display device 100 of this embodiment so that an image is displayed, the display device 100 may be driven with a progressive method in which image data is written to the pixels 103 in the second row immediately after image data is written to the pixels 103 in the first row, and image data is written to the pixels 103 in rows sequentially up to the last row (m-th row). Alternatively, the display device 100 may be driven with an interlaced method in which image data is not written to alternate rows of the pixels 103. In the interlaced method, for example, after writing image data to the pixels 103 in the first row, writing image data to the pixels 103 in the second row is skipped, and image data is written to the pixels 103 in the third row. In this manner, the image data is written sequentially up to the pixels 103 in the (m−1)-th row. Then, after writing image data to the pixels 103 in the second row, image data is written to the pixels 103 in the fourth row. In this manner, the image data is written sequentially up to the pixels 103 in the m-th row. In other words, after image data is written to the pixels 103 in all odd-numbered rows, image data is written to the pixels 103 in all even-numbered rows, for example. Note that when the display device 100 is driven with an interlaced method, this method is not limited to the above example where image data is written to the pixels 103 in every other row, image data may be written to the pixels 103 in every third row.

When the display device 100 is driven with a progressive method, the display device 100 can display an image with few flickers. On the other hand, the display device 100 is driven with an interlaced method, which enables a pseudo increase in frame frequency and results in displaying a smooth moving image.

Note that the driving system may be set so that a user of the display device 100 can switch the driving method optionally between the progressive method and the interlaced method. With such a structure, an image according to the user's preference can be displayed.

As described above, in the method for manufacturing the display device of this embodiment, the island-shaped light-emitting layer and the island-shaped active layer are formed not only using a metal mask having a fine pattern but also by processing. Specifically, the island-shaped light-emitting layer and the island-shaped active layer are divided and processed into layers with a smaller size by a photolithography method or the like. Thus, the size of the island-shaped light-emitting layer and the island-shaped active layer can each be made smaller than the size of the layers formed with use of a metal mask. Accordingly, a high-resolution display device or a display device with a high aperture ratio, which has been difficult to achieve, can be manufactured.

Each subpixel includes an island-shaped EL layer, which can inhibit generation of leakage current between the subpixels. Accordingly, degradation of the display quality of the display device can be inhibited. In addition, both the higher resolution and higher display quality of the display device can be achieved. Similarly, island-shaped layers included in the light-receiving device are provided for subpixels, which can inhibit generation of leakage current between the subpixels. Accordingly, a reduction in the accuracy of light detection in the display device can be inhibited.

This embodiment can be combined with any of the other embodiments as appropriate. In this specification, in the case where a plurality of structure examples are described in one embodiment, the structure examples can be combined as appropriate.

### Embodiment 2

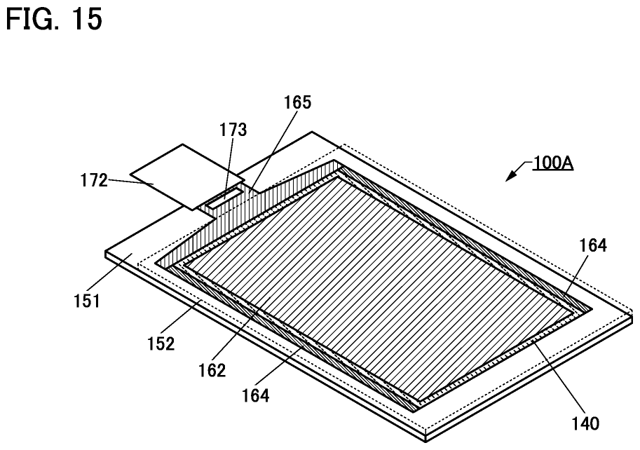

In this embodiment, a display device of one embodiment of the present invention will be described with reference to FIG. 15 to FIG. 18.

The display device in this embodiment can be a high-definition display device or a large-sized display device. Accordingly, the display device in this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer or the like, digital signage, and a large game machine such as a pachinko machine.

### [Display Device 100A]

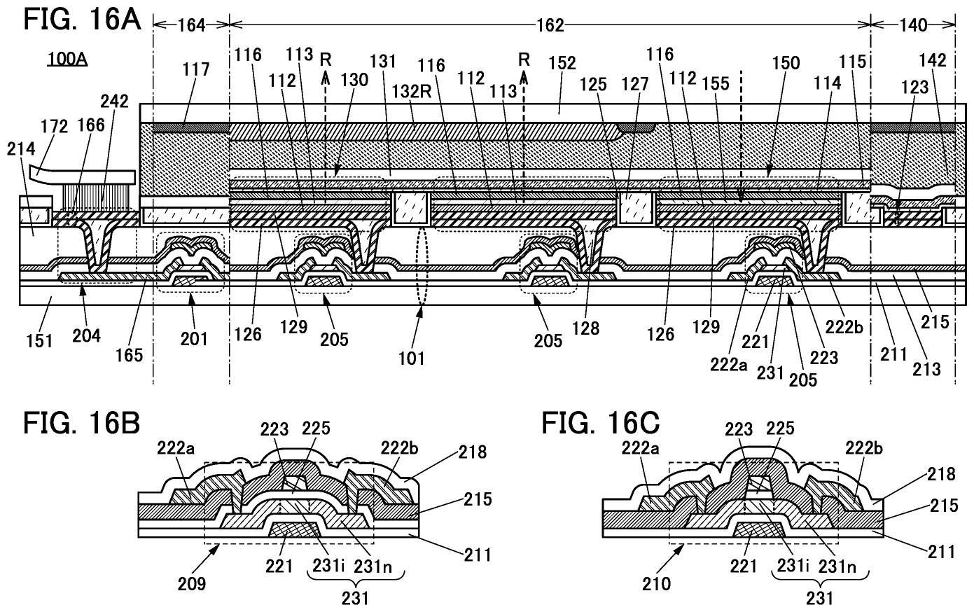

FIG. 15 is a perspective view of a display device 100A, and FIG. 16A is a cross-sectional view of the display device 100A.

In the display device 100A, a substrate 152 and a substrate 151 are attached to each other. In FIG. 15, the substrate 152 is denoted by a dashed line.

The display device 100A includes a display portion 162, the connection portion 140, a circuit 164, a wiring 165, and the like. FIG. 15 illustrates an example in which an IC 173 and an FPC 172 are implemented onto the display device 100A. Thus, the structure illustrated in FIG. 15 can be regarded as a display module including the display device 100A, the IC (integrated circuit), and the FPC.

The connection portion 140 is provided outside the display portion 162. The connection portion 140 can be provided along one or more sides of the display portion 162. The number of the connection portions 140 may be one or more. FIG. 15 illustrates an example in which the connection portion 140 is provided to surround the four sides of the display portion. The common electrode of the light-emitting device and the light-receiving device is electrically connected to a conductive layer in the connection portion 140, and thus a potential can be supplied to the common electrode.

As the circuit 164, a scan line driver circuit can be used, for example.

The wiring 165 has a function of supplying a signal and power to the display portion 162 and the circuit 164. The signal and power are input to the wiring 165 from the outside through the FPC 172 or from the IC 173.

FIG. 15 illustrates an example in which the IC 173 is provided over the substrate 151 by a COG (Chip On Glass) method, a COF (Chip On Film) method, or the like. An IC including a scan line driver circuit, a signal line driver circuit, or the like can be used as the IC 173, for example. Note that the display device 100A and the display module are not necessarily provided with an IC. The IC may be mounted on the FPC by a COF method or the like.

FIG. 16A illustrates an example of cross sections of part of a region including the FPC 172, part of the circuit 164, part of the display portion 162, part of the connection portion 140, and part of a region including an end portion of the display device 100A.

The display device 100A illustrated in FIG. 16A includes a transistor 201, a transistor 205, the light-emitting device 130, a coloring layer 132R that transmits red light, the light-receiving device 150, and the like between the substrate 151 and the substrate 152.

The light-emitting device 130 emits white light. Light emitted by the light-emitting device 130 is extracted as red light to the outside of the display device 100A through the coloring layer 132R.

The light-receiving device 150 detects visible light. Alternatively, the light-receiving device 150 may detect infrared light or both visible light and infrared light.

For the display device 100A, the pixel layout shown in Embodiment 1 can be employed. Thus, the display portion 162 includes a portion where subpixels emitting light of the same color are provided to be adjacent to each other. FIG. 16A illustrates a portion where two subpixels emitting red light are adjacent to each other.

The two subpixels share one coloring layer 132R. The light-emitting devices 130 in the two subpixels include separate first layers 112, separate light-emitting layers 113, and separate second layers 116. The light-emitting devices in the two subpixels can be driven independently of each other.

The light-emitting devices in the subpixels emitting light of different colors can have the same structure in which white light can be emitted, for example. Specifically, the first layer 112, the light-emitting layer 113, and the second layer 116 included in the light-emitting device can have the same structure. Meanwhile, the first layer 112, the light-emitting layer 113, and the second layer 116 in the light-emitting devices are separated from each other, which can inhibit generation of leakage current between the light-emitting devices. Thus, the display quality of the display device can be improved.

The first layer 112 included in the light-emitting device 130 and the first layer 112 included in the light-receiving device 150 can have the same structure. The first layers 112 are separated from each other in each subpixel. Similarly, the second layer 116 included in the light-emitting device 130 and the second layer 116 included in the light-receiving device 150 can have the same structure. The second layers 116 are separated from each other in each subpixel. Since the first layers 112 and the second layers 116 that are included in each subpixel are separated from one another, generation of leakage current between the light-emitting device and the light-receiving device, between the light-emitting devices, and between the light-receiving devices can be inhibited. Accordingly, the display quality and the light detection accuracy of the display device can be improved.

Other than a difference in the structure of pixel electrode, the light-emitting device 130 and the light-receiving device 150 each have a structure similar to the stacked-layer structure illustrated in FIG. 2B. Embodiment 1 can be referred to for the details of the light-emitting devices and the light-receiving device.

The light-emitting device 130 and the light-receiving device 150 each include a conductive layer 126 and a conductive layer 129 over the conductive layer 126. One or both of the conductive layer 126 and the conductive layer 129 can be referred to as a pixel electrode.

The conductive layer 126 is connected to a conductive layer 222b included in the transistor 205 through an opening provided in an insulating layer 214. In the display device 100A, the end portion of the conductive layer 126 and the end portion of the conductive layer 129 are aligned or substantially aligned with each other; however, one embodiment of the present invention is not limited thereto. For example, the conductive layer 129 may be provided so as to cover the end portion of the conductive layer 126. The conductive layer 126 and the conductive layer 129 each preferably include a conductive layer functioning as a reflective electrode. The one or both of the conductive layer 126 and the conductive layer 129 may include a conductive layer functioning as a transparent electrode.

The conductive layer 126 is formed to cover the opening provided in the insulating layer 214. A layer 128 is embedded in a depressed portion of the conductive layer 126.

The layer 128 has a function of filling the depressed portion of the conductive layer 126 for planarization. The conductive layer 129 electrically connected to the conductive layer 126 is provided over the conductive layer 126 and the layer 128. Thus, a region overlapping with the depressed portion of the conductive layer 126 can also be used as the light-emitting region or the light-receiving region, increasing the aperture ratio of the pixels.

The layer 128 may be an insulating layer or a conductive layer. Any of a variety of inorganic insulating materials, organic insulating materials, and conductive materials can be used for the layer 128 as appropriate. In particular, the layer 128 is preferably formed using an insulating material.

An insulating layer containing an organic material can be suitably used as the layer 128. For example, an acrylic resin, a polyimide resin, an epoxy resin, a polyamide resin, a polyimide-amide resin, a siloxane resin, a benzocyclobutene-based resin, a phenol resin, and precursors of these resins can be used for the layer 128. A photosensitive resin can also be used for the layer 128. As the photosensitive resin, a positive photosensitive material or a negative photosensitive material can be used.

When a photosensitive resin is used, the layer 128 can be formed through only light-exposure and development steps, reducing the influence of dry etching, wet etching, or the like on the surfaces of the conductive layer 126. When the layer 128 is formed using a negative photosensitive resin, the layer 128 can sometimes be formed using the same photomask (light-exposure mask) as the photomask used for forming the opening in the insulating layer 214.

The entire top surface of the conductive layer 129 is covered with the first layer 112, the light-emitting layer 113, and the second layer 116. Accordingly, a region provided with the conductive layer 129 can be entirely used as a light-emitting region of the light-emitting device 130, increasing the aperture ratio of the pixels. Note that the first layer 112, the light-emitting layer 113, and the second layer 116 may cover the side surface of the conductive layer 129. The first layer 112, the light-emitting layer 113, and the second layer 116 may cover only part of the top surface of the conductive layer 129. In other words, part of the top surface of the conductive layer 129 is not necessarily covered with the first layer 112, the light-emitting layer 113, and the second layer 116.

Similarly, the entire top surface of the conductive layer 129 is covered with the first layer 112, the active layer 155, and the second layer 116. Accordingly, a region provided with the conductive layer 129 can be entirely used as a light-receiving region of the light-receiving device 150, increasing the aperture ratio of the pixels. Note that the first layer 112, the active layer 155, and the second layer 116 may cover the side surface of the conductive layer 129. The first layer 112, the active layer 155, and the second layer 116 may cover only part of the top surface of the conductive layer 129. In other words, part of the top surface of the conductive layer 129 is not necessarily covered with the first layer 112, the active layer 155, and the second layer 116.

The side surfaces of the first layer 112, the light-emitting layer 113, the active layer 155, and the second layer 116 are covered with the insulating layer 125 and overlap with the insulating layer 127 with the insulating layer 125 provided therebetween. The common layer 114 is provided over the second layer 116, the insulating layer 125, and the insulating layer 127, and the common electrode 115 is provided over the common layer 114. The common layer 114 and the common electrode 115 are each one continuous film shared by the plurality of light-emitting devices and the plurality of light-receiving device.

The protective layer 131 is provided over the light-emitting device 130 and the light-receiving device 150. Providing the protective layer 131 that covers the light-emitting device and the light-receiving device can inhibit entry of impurities such as water into the light-emitting device and the light-receiving device, thereby increasing the reliability of the light-emitting device and the light-receiving device.

The protective layer 131 and the substrate 152 are bonded to each other with an adhesive layer 142. A solid sealing structure, a hollow sealing structure, or the like can be employed to seal the light-emitting device and the light-receiving device. In FIG. 16A, a solid sealing structure is employed, in which a space between the substrate 152 and the substrate 151 is filled with the adhesive layer 142. Alternatively, a hollow sealing structure may be employed, in which the space is filled with an inert gas (e.g., nitrogen or argon). In this case, the adhesive layer 142 may be provided not to overlap with the light-emitting device and the light-receiving device. Alternatively, the space may be filled with a resin other than the frame-like adhesive layer.

The conductive layer 123 is provided over the insulating layer 214 in the connection portion 140. An example is illustrated in which the conductive layer 123 has a stacked-layer structure of a conductive film obtained by processing the same conductive film as the conductive layer 126 and a conductive film obtained by processing the same conductive film as the conductive layer 129. The side surface of the conductive layer 123 is covered with the insulating layer 125 and overlaps with the insulating layer 127 with the insulating layer 125 provided therebetween. The common layer 114 is provided over the conductive layer 123, and the common electrode 115 is provided over the common layer 114. The conductive layer 123 and the common electrode 115 are electrically connected to each other through common layer 114. Note that the common layer 114 is not necessarily formed in the connection portion 140. In this case, the conductive layer 123 and the common electrode 115 are directly and electrically connected to each other.

The display device 100A has a top-emission structure. Light emitted by the light-emitting device is emitted toward the substrate 152 side. Light enters the light-receiving device from the substrate 152 side. For the substrate 152, a material having a high visible-light-transmitting property is preferably used.

The pixel electrode contains a material that reflects visible light, and the counter electrode (the common electrode 115) contains a material that transmits visible light.

A stacked-layer structure including the substrate 151 and the components thereover up to the insulating layer 214 corresponds to the layer 101 including a transistor in Embodiment 1.

The transistor 201 and the transistor 205 are formed over the substrate 151. These transistors can be formed using the same material in the same step.

An insulating layer 211, an insulating layer 213, an insulating layer 215, and the insulating layer 214 are provided in this order over the substrate 151. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

A material through which impurities such as water and hydrogen do not easily diffuse is preferably used for at least one of the insulating layers covering the transistors. This is because such an insulating layer can function as a barrier layer. Such a structure can effectively inhibit diffusion of impurities into the transistors from the outside and increase the reliability of the display device.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, an aluminum nitride film, or the like can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

An organic insulating layer is suitable as the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. Alternatively, the insulating layer 214 may have a stacked-layer structure of an organic insulating layer and an inorganic insulating film. The outermost layer of the insulating layer 214 preferably has a function of an etching protective film. Thus, the formation of a depressed portion in the insulating layer 214 can be inhibited in processing the conductive layer 126, the conductive layer 129, or the like. Alternatively, a depressed portion may be formed in the insulating layer 214 in processing the conductive layer 126, the conductive layer 129, or the like.

Each of the transistor 201 and the transistor 205 includes a conductive layer 221 functioning as a gate, the insulating layer 211 functioning as a gate insulating layer, a conductive layer 222a and a conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display device of this embodiment. For example, a planar transistor, a staggered transistor, an inverted staggered transistor, or the like can be used. A top-gate transistor or a bottom-gate transistor can be used. Alternatively, gates may be provided above and below a semiconductor layer where a channel is formed.

The structure in which the semiconductor layer where a channel is formed is provided between two gates is used for the transistor 201 and the transistor 205. The two gates may be connected to each other and supplied with the same signal to operate the transistor. Alternatively, the threshold voltage of the transistor may be controlled by applying a potential for controlling the threshold voltage to one of the two gates and a potential for driving to the other of the two gates.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. It is preferable to use a single crystal semiconductor or a semiconductor having crystallinity because degradation of transistor characteristics can be inhibited.

It is preferable that a semiconductor layer of a transistor contain a metal oxide (also referred to as an oxide semiconductor). That is, a transistor including a metal oxide in its channel formation region (hereinafter, also referred to as an OS transistor) is preferably used for the display device of this embodiment.

As the oxide semiconductor having crystallinity, a CAAC (c-axis aligned crystalline)-OS, an nc (nanocrystalline)-OS, and the like can be given.

Alternatively, a transistor using silicon in a channel formation region (a Si transistor) may be used. Examples of silicon include single crystal silicon, polycrystalline silicon, and amorphous silicon. In particular, a transistor containing low-temperature polysilicon (LTPS) in a semiconductor layer (such a transistor is referred to as an LTPS transistor below) can be used.

The LTPS transistor has high field-effect mobility and excellent frequency characteristics. With use of the Si transistor such as the LTPS transistor, a circuit required to drive at a high frequency (e.g., a source driver circuit) can be formed on the same substrate as the display portion. This allows simplification of an external circuit mounted on the display device and a reduction in costs of parts and mounting costs.

The OS transistor has much higher field-effect mobility than a transistor containing amorphous silicon. In addition, the OS transistor has an extremely low leakage current between a source and a drain in an off state (hereinafter, also referred to as an off-state current), and electric charge accumulated in a capacitor that is connected in series to the transistor can be held for a long period. Furthermore, the power consumption of the display device can be reduced with the OS transistor.

The off-state current per micrometer of channel width of the OS transistor at room temperature can be lower than or equal to 1 aA (1×10⁻¹⁸ A), lower than or equal to 1 zA (1×10⁻²¹ A), or lower than or equal to 1 yA (1×10⁻²⁴ A). Note that the off-state current per micrometer of channel width of a Si transistor at room temperature is higher than or equal to 1 fA (1×10⁻¹⁵ A) and lower than or equal to 1 pA (1×10⁻¹² A). That is, the off-state current of the OS transistor is lower than the off-state current of the Si transistor by approximately 10 digits.

To increase the emission luminance of the light-emitting device included in a pixel circuit, it is necessary to increase the amount of current flowing through the light-emitting device. For this, it is necessary to increase the source-drain voltage of a driving transistor included in the pixel circuit. Since the OS transistor has a higher withstand voltage between the source and the drain than a Si transistor, a high voltage can be applied between the source and the drain of the OS transistor. Thus, with use of an OS transistor as a driving transistor included in the pixel circuit, the amount of current flowing through the light-emitting device can be increased, resulting in an increase in emission luminance of the light-emitting device.

When transistors operate in a saturation region, a change in source-drain current relative to a change in gate-source voltage can be smaller in an OS transistor than in a Si transistor. Accordingly, when an OS transistor is used as the driving transistor included in the pixel circuit, the amount of current flowing between the source and the drain can be set minutely by a change in gate-source voltage; hence, the amount of current flowing through the light-emitting device can be controlled. Accordingly, the gray level in the pixel circuit can be increased.

Regarding saturation characteristics of current flowing when transistors operate in a saturation region, even in the case where the source-drain voltage of an OS transistor increases gradually, more stable constant current (saturation current) can be fed through the OS transistor than through a Si transistor. Thus, with use of an OS transistor as a driving transistor, current can be made flow stably through the light-emitting device, for example, even when a variation in current-voltage characteristics of the EL device occurs. In other words, the amount of current between the source and the drain is less changed in the OS transistor operating in the saturation region even when the source-drain voltage is made higher. As a result, the emission luminance of the light-emitting device can be stabilized.

As described above, with use of an OS transistor as a driving transistor included in the pixel circuit, it is possible to achieve “inhibition of black floating”, “increase in emission luminance”, “increase in gray level”, “inhibition of variation in light-emitting devices”, and the like.

The metal oxide used in the semiconductor layer preferably contains indium, M (M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more kinds selected from aluminum, gallium, yttrium, and tin.

It is particularly preferable that an oxide containing indium (In), gallium (Ga), and zinc (Zn) (also referred to as IGZO) be used for the semiconductor layer. Alternatively, it is preferable to use an oxide containing indium, tin, and zinc. Further alternatively, it is preferable to use an oxide containing indium, gallium, tin, and zinc. Further alternatively, it is preferable to use an oxide containing indium (In), aluminum (Al), and zinc (Zn) (also referred to as IAZO). Further alternatively, it is preferable to use an oxide containing indium (In), aluminum (Al), gallium (Ga), and zinc (Zn) (also referred to as IAGZO).

When the semiconductor layer is an In-M-Zn oxide, the atomic ratio of In is preferably greater than or equal to the atomic ratio of M in the In-M-Zn oxide. Examples of the atomic ratio of the metal elements in such an In-M-Zn oxide are In:M:Zn=1:1:1 or a composition in the vicinity thereof, In:M:Zn=1:1:1.2 or a composition in the vicinity thereof, In:M:Zn=1:3:2 or a composition in the vicinity thereof, In:M:Zn=1:3:4 or a composition in the vicinity thereof, In:M:Zn=2:1:3 or a composition in the vicinity thereof, In:M:Zn=3:1:2 or a composition in the vicinity thereof, In:M:Zn=4:2:3 or a composition in the vicinity thereof, In:M:Zn=4:2:4.1 or a composition in the vicinity thereof, In:M:Zn=5:1:3 or a composition in the vicinity thereof, In:M:Zn=5:1:6 or a composition in the vicinity thereof, In:M:Zn=5:1:7 or a composition in the vicinity thereof, In:M:Zn=5:1:8 or a composition in the vicinity thereof, In:M:Zn=6:1:6 or a composition in the vicinity thereof, and In:M:Zn=5:2:5 or a composition in the vicinity thereof. Note that the vicinity of the atomic ratio includes ±30% of an intended atomic ratio.

For example, when the atomic ratio is described as In:Ga:Zn=4:2:3 or a composition in the vicinity thereof, the case is included where the atomic ratio of Ga is greater than or equal to 1 and less than or equal to 3 and the atomic ratio of Zn is greater than or equal to 2 and less than or equal to 4 with the atomic ratio of In being 4. In addition, when the atomic ratio is described as In:Ga:Zn=5:1:6 or a composition in the vicinity thereof, the case is included where the atomic ratio of Ga is greater than 0.1 and less than or equal to 2 and the atomic ratio of Zn is greater than or equal to 5 and less than or equal to 7 with the atomic ratio of In being 5. Furthermore, when the atomic ratio is described as In:Ga:Zn=1:1:1 or a composition in the vicinity thereof, the case is included where the atomic ratio of Ga is greater than 0.1 and less than or equal to 2 and the atomic ratio of Zn is greater than 0.1 and less than or equal to 2 with the atomic ratio of In being 1.

The transistors included in the circuit 164 and the transistors included in the display portion 162 may have the same structure or different structures. One structure or two or more kinds of structures may be employed for a plurality of transistors included in the circuit 164. Similarly, one structure or two or more kinds of structures may be employed for a plurality of transistors included in the display portion 162.

All of the transistors included in the display portion 162 may be OS transistors or Si transistors. Alternatively, some of the transistors included in the display portion 162 may be OS transistors and the others may be Si transistors.

For example, when both the LTPS transistor and the OS transistor are used in the display portion 162, the display device can have low power consumption and high drive capability. Note that a structure in which the LTPS transistor and the OS transistor are combined is referred to as LTPO in some cases. As a more suitable example, a structure in which the OS transistor is used as a transistor or the like functioning as a switch for controlling conduction or non-conduction between wirings, and the LTPS transistor is used as a transistor or the like for controlling current, can be given.

For example, one transistor included in the display portion 162 may function as a transistor for controlling current flowing through the light-emitting device and be also referred to as a driving transistor. One of a source and a drain of the driving transistor is electrically connected to the pixel electrode of the light-emitting device. The LTPS transistor is preferably used as the driving transistor. Thus, current flowing through the light-emitting device in the pixel circuit can be increased.

In contrast, another transistor included in the display portion 162 may function as a switch for controlling selection or non-selection of a pixel and can also be referred to as a selection transistor. A gate of the selection transistor is electrically connected to a gate line, and one of a source and a drain thereof is electrically connected to a source line (signal line). The OS transistor is preferably used as the selection transistor. Thus, the gray level of the pixel can be maintained even when the frame frequency is extremely reduced (e.g., 1 fps or lower), whereby power consumption can be reduced by stopping the driver in displaying a still image.

As described above, the display device of one embodiment of the present invention can have all of a high aperture ratio, high resolution, high display quality, and low power consumption.

Note that the display device of one embodiment of the present invention has a structure including the OS transistor and the light-emitting device having an MML (metal maskless) structure. This structure can extremely reduce the leakage current that might flow through a transistor, and the leakage current that might flow between adjacent light-emitting devices (also referred to as a lateral leakage current, a side leakage current, or the like). With the structure, a viewer can observe any one or more of the image crispness, the image sharpness, a high chroma, and a high contrast ratio in an image displayed on the display device. Note that when the leakage current that might flow through a transistor and the lateral leakage current between light-emitting devices are extremely low, display with little leakage of light or the like that might occur in black display can be reduced as much as possible.

FIG. 16B and FIG. 16C illustrate other structure examples of transistors.

A transistor 209 and a transistor 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the pair of low-resistance regions 231n, the conductive layer 222b connected to the other of the pair of low-resistance regions 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned between at least the conductive layer 223 and the channel formation region 231i. Furthermore, an insulating layer 218 covering the transistor may be provided.

FIG. 16B illustrates an example of the transistor 209 in which the insulating layer 225 covers the top surface and the side surface of the semiconductor layer 231. The conductive layer 222a and the conductive layer 222b are connected to the corresponding low-resistance regions 231n through openings provided in the insulating layer 225 and the insulating layer 215. One of the conductive layer 222a and the conductive layer 222b functions as a source, and the other functions as a drain.

In the transistor 210 illustrated in FIG. 16C, the insulating layer 225 overlaps with the channel formation region 231i of the semiconductor layer 231 and does not overlap with the low-resistance regions 231n. The structure illustrated in FIG. 16C is obtained by processing the insulating layer 225 with the conductive layer 223 as a mask, for example. In FIG. 16C, the insulating layer 215 is provided to cover the insulating layer 225 and the conductive layer 223, and the conductive layer 222a and the conductive layer 222b are connected to the corresponding low-resistance regions 231n through the openings in the insulating layer 215.

A connection portion 204 is provided in a region of the substrate 151 which does not overlap with the substrate 152. In the connection portion 204, the wiring 165 is electrically connected to the FPC 172 through a conductive layer 166 and a connection layer 242. An example is illustrated in which the conductive layer 166 has a stacked-layer structure of a conductive film obtained by processing the same conductive film as the conductive layer 126 and a conductive film obtained by processing the same conductive film as the conductive layer 129. On the top surface of the connection portion 204, the conductive layer 166 is exposed. Thus, the connection portion 204 and the FPC 172 can be electrically connected to each other through the connection layer 242.

A light-blocking layer 117 is preferably provided on the surface of the substrate 152 on the substrate 151 side. In addition, the coloring layer 132R may be provided on the surface of the substrate 152 that faces the substrate 151. In FIG. 16A, when the substrate 152 is considered as a reference, the coloring layer 132R is provided to cover part of the light-blocking layer 117.

The substrate 151 and the substrate 152 can be each formed using any of the materials given in Embodiment 1 as examples of the material that can be used for the substrate 120. In addition, a variety of members that can be placed outside the substrate 120 can also be used at the outside of the substrate 151 or the substrate 152.

A material that can be used for the resin layer 122 described in Embodiment 1 can be used for the adhesive layer 142.

As the connection layer 242, an anisotropic conductive film (ACF), an anisotropic conductive paste (ACP), or the like can be used.

As materials for a gate, a source, and a drain of a transistor and conductive layers functioning as wirings and electrodes included in the display device, any of metals such as aluminum, titanium, chromium, nickel, copper, yttrium, zirconium, molybdenum, silver, tantalum, and tungsten, or an alloy containing any of these metals as its main component can be used, for example. A single-layer structure or a stacked-layer structure including a film containing any of these materials can be used.

As a light-transmitting conductive material, a conductive oxide such as indium oxide, indium tin oxide, indium zinc oxide, zinc oxide, or zinc oxide containing gallium, or graphene can be used. It is also possible to use a metal material such as gold, silver, platinum, magnesium, nickel, tungsten, chromium, molybdenum, iron, cobalt, copper, palladium, or titanium or an alloy material containing any of these metal materials. Alternatively, a nitride of the metal material (e.g., titanium nitride) or the like may be used. Note that in the case of using the metal material or the alloy material (or the nitride thereof), the thickness is preferably set small enough to transmit light. Alternatively, stacked films of any of the above materials can be used for the conductive layers. For example, stacked films of indium tin oxide and an alloy of silver and magnesium are preferably used, in which case the conductivity can be increased. These materials can also be used for conductive layers such as wirings and electrodes included in the display device, and conductive layers (e.g., a conductive layer functioning as the pixel electrode or the common electrode) included in the light-emitting device and the light-receiving device.

Examples of insulating materials that can be used for insulating layers include resins such as an acrylic resin and an epoxy resin, and inorganic insulating materials such as silicon oxide, silicon oxynitride, silicon nitride oxide, silicon nitride, and aluminum oxide.

### [Display Device 100B]

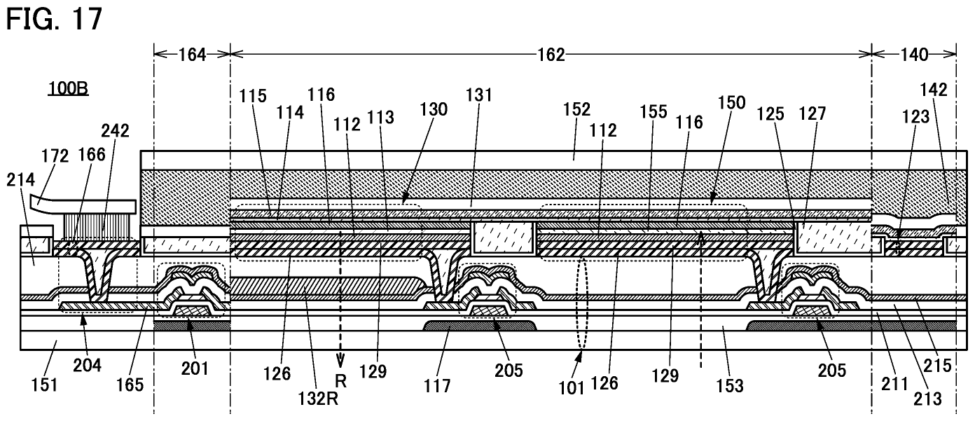

A display device 100B illustrated in FIG. 17 differs from the display device 100A mainly in having a bottom-emission structure. Note that the description of portions similar to those of the display device 100A is omitted.

For the display device 100B, the pixel layout described in Embodiment 1 can be used. Accordingly, subpixels that emit light of the same color are provided to be adjacent to each other. FIG. 17 illustrates a portion where two subpixels emitting red light are adjacent to each other.

Light emitted by the light-emitting device is emitted toward the substrate 151 side. Light enters the light-receiving device from the substrate 151 side. For the substrate 151, a material having a high visible-light-transmitting property is preferably used. In contrast, there is no limitation on the light-transmitting property of a material used for the substrate 152.

In the display device 100B, the conductive layer 126 and the conductive layer 129 each contain a material transmitting visible light, and the common electrode 115 contains a material reflecting visible light.

The light-blocking layer 117 is preferably formed between the substrate 151 and the transistor 201 and between the substrate 151 and the transistor 205. FIG. 17 illustrates an example in which the light-blocking layer 117 is provided over the substrate 151, an insulating layer 153 is provided over the light-blocking layer 117, and the transistors 201 and 205 and the like are provided over the insulating layer 153.

Moreover, in the display device 100B, the coloring layer 132R transmitting red light is provided between the insulating layer 215 and the insulating layer 214. The end portion of the coloring layer 132R preferably overlaps with the light-blocking layer 117. Light emitted by the light-emitting device 130 is extracted as red light to the outside of the display device 100B through the coloring layer 132R.

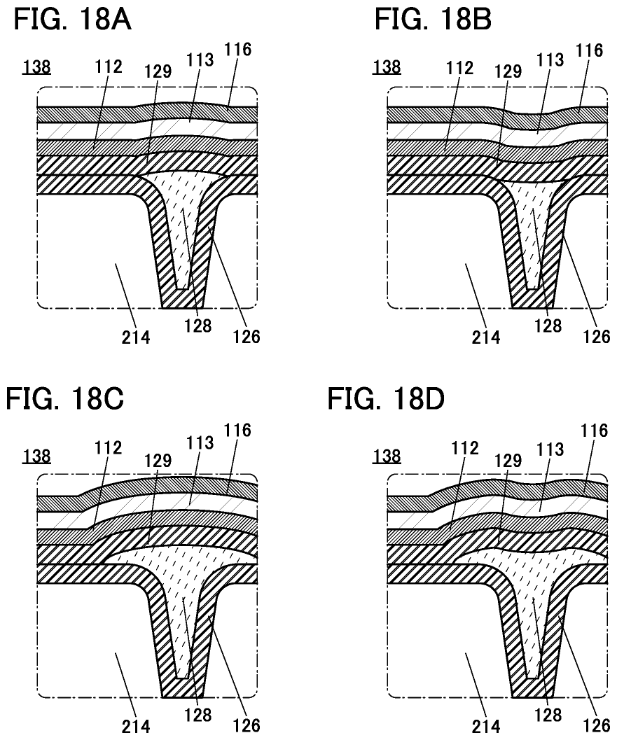

Here, FIG. 18A to FIG. 18D illustrate cross-sectional structures of a region 138 including the conductive layer 126, the layer 128, and the vicinity thereof in the display device 100A and the display device 100B.

FIG. 16A and FIG. 17 each illustrate an example in which the top surface of the layer 128 and the top surface of the conductive layer 126 are substantially at the same level; however, the present invention is not limited to such an example. For example, as illustrated in FIG. 18A, the top surface of the layer 128 may be at a higher level than that of the conductive layer 126. In this case, the top surface of the layer 128 has a convex shape that is gently bulged toward the center.

As illustrated in FIG. 18B, the top surface of the layer 128 may be at a lower level than that of the conductive layer 126. In this case, the top surface of the layer 128 has a concave shape that is gently recessed toward the center.

When the top surface of the layer 128 is at a higher level than that of the conductive layer 126 as illustrated in FIG. 18C, the upper portion of the layer 128 is formed to extend beyond a depressed portion in the conductive layer 126 in some cases. In this case, part of the layer 128 may be formed to cover part of a region of the conductive layer 126 which is substantially flat.

As illustrated in FIG. 18D, part of the top surface of layer 128 has another depressed portion in the structure of FIG. 18C, in some cases. The depressed portion has a shape that is gently recessed toward the center.

This embodiment can be combined with the other embodiments as appropriate.

### Embodiment 3

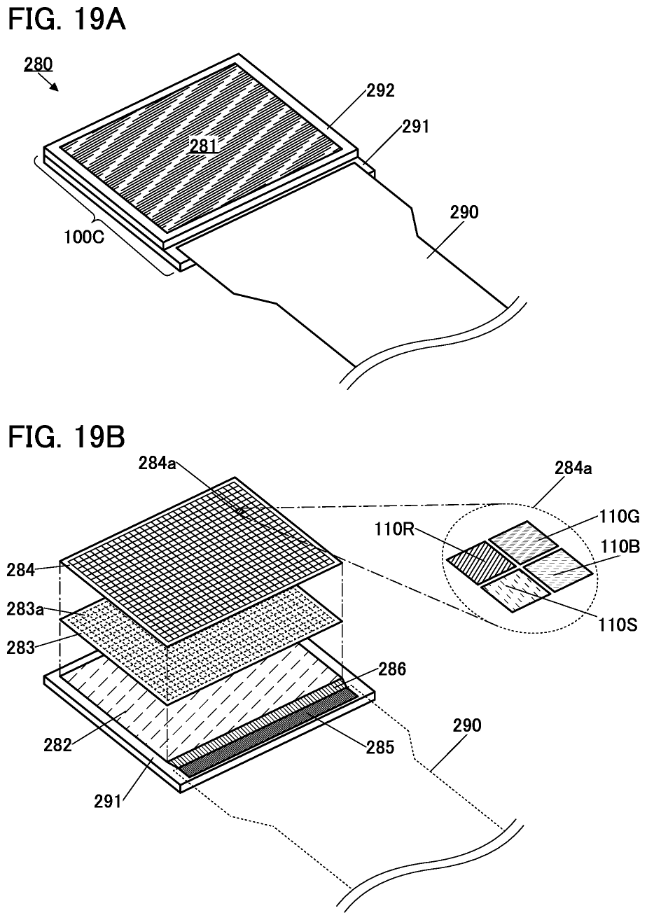

In this embodiment, a display device of one embodiment of the present invention will be described with reference to FIG. 19 to FIG. 24.

The display device in this embodiment can be a high-resolution display device. Accordingly, the display device in this embodiment can be used for display portions of information terminals (wearable devices) such as watch-type and bracelet-type information terminals and display portions of wearable devices capable of being worn on the head, such as a VR device like a head-mounted display and a glasses-type AR device.

### [Display Module]

FIG. 19A is a perspective view of a display module 280. The display module 280 includes a display device 100C and an FPC 290. Note that the display device included in the display module 280 is not limited to the display device 100C and may be any of a display device 100D to a display device 100G described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 19B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. A terminal portion 285 to be connected to the FPC 290 is provided in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. Four subpixels are illustrated on the right side in FIG. 19B as an enlarged view of the pixel 284a. One pixel 284a includes a subpixel 110R emitting red light, a subpixel 110G emitting green light, a subpixel 110B emitting blue light, and a subpixel 110S including a light-receiving device. Embodiment 1 can be referred to as a pixel layout applicable to the pixel portion 284.

The pixel circuit portion 283 includes a plurality of pixel circuits 283a arranged periodically.

One pixel circuit 283a is a circuit that controls driving of a plurality of elements included in one pixel 284a. For example, the pixel circuit 283a can include at least one selection transistor, one current control transistor (driving transistor), and a capacitor for one light-emitting device. In this case, a gate signal is input to a gate of the selection transistor, and a source signal is input to a source of the selection transistor. With such a structure, an active-matrix display device is achieved.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (the effective display area ratio) of the display portion 281 can be significantly high. For example, the aperture ratio of the display portion 281 can be greater than or equal to 40% and less than 100%, preferably greater than or equal to 50% and less than or equal to 95%, further preferably greater than or equal to 60% and less than or equal to 95%. Furthermore, the pixels 284a can be arranged extremely densely and thus the display portion 281 can have extremely high resolution. For example, the pixels 284a are preferably arranged in the display portion 281 with a resolution greater than or equal to 2000 ppi, preferably greater than or equal to 3000 ppi, further preferably greater than or equal to 5000 ppi, still further preferably greater than or equal to 6000 ppi, and less than or equal to 20000 ppi or less than or equal to 30000 ppi.

Such a display module 280 has extremely high resolution, and thus can be suitably used for a VR device such as a head-mounted display or a glasses-type AR device. For example, even with a structure in which the display portion of the display module 280 is seen through a lens, pixels of the extremely-high-resolution display portion 281 included in the display module 280 are prevented from being perceived when the display portion is enlarged by the lens, so that display providing a high sense of immersion can be performed. Without being limited thereto, the display module 280 can be suitably used for electronic devices including a relatively small display portion. For example, the display module 280 can be suitably used in a display portion of a wearable electronic device, such as a wrist watch.

### [Display Device 100C]

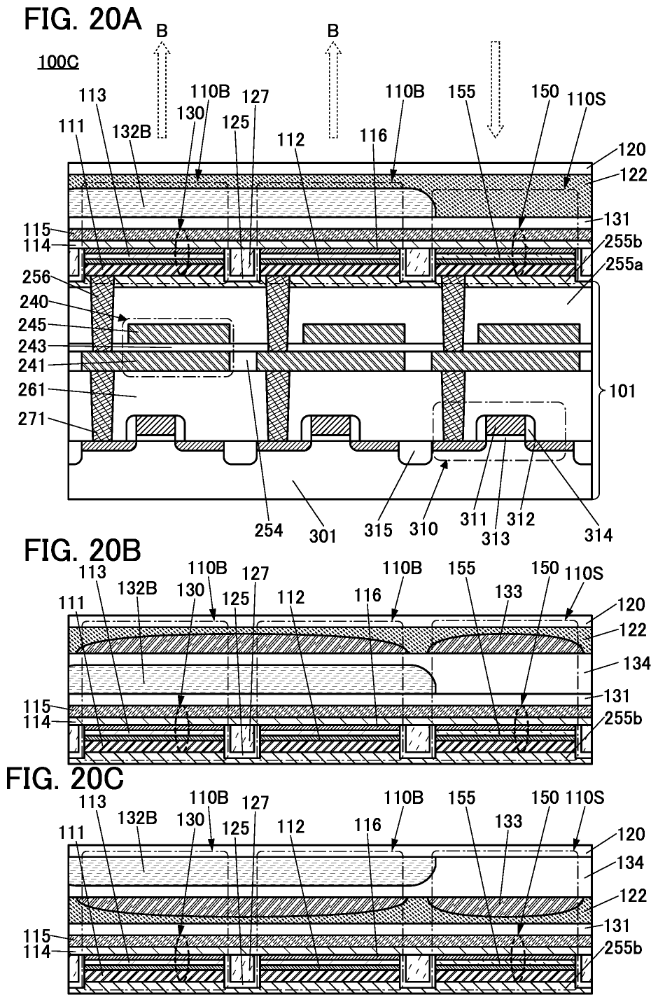

The display device 100C illustrated in FIG. 20A includes a substrate 301, the light-emitting device 130, the light-receiving device 150, a coloring layer 132B, a capacitor 240, a transistor 310, and the like.

The subpixel 110B includes the light-emitting device 130 and the coloring layer 132B. The light-emitting device 130 emits white light. In the subpixel 110B, light emitted from the light-emitting device 130 is extracted as blue light to the outside of the display device 100C through the coloring layer 132B. Although not illustrated, also in the subpixels 110R and 110G, light emitted from the light-emitting device 130 which emits white light is extracted as red light or green light to the outside of the display device 100C through the coloring layer which transmits red light or green light.

The subpixel 110S includes the light-receiving device 150. Light enters the light-receiving device 150 from the substrate 120 side. The light-receiving device 150 detects visible light. Alternatively, the light-receiving device 150 may detect infrared light or may detect both visible light and infrared light.

The pixel layout described in Embodiment 1 can be employed for the display device 100C. Thus, the pixel portion 284 includes a portion where subpixels emitting light of the same color are provided to be adjacent to each other. FIG. 20A illustrates a portion where two subpixels emitting blue light are adjacent to each other.

The two subpixels 110B shares one coloring layer 132B. The first layers 112, the light-emitting layers 113, and the second layers 116 included in the light-emitting device 130 are separated from one another between the two subpixels 110B. The light-emitting devices 130 in the two subpixels 110B can be driven independently of each other.

The same structure can be employed for the light-emitting devices included in subpixels emitting different colors, and for example, a structure emitting white light can be employed. Specifically, the first layer 112, the light-emitting later 113, and the second layer 116 included in respective light-emitting devices can have the same structure. In contrast, the first layers 112, the light-emitting layers 113, and the second layers 116 included in respective light-emitting device are separated from each other, which can inhibit generation of leakage current between light-emitting devices. Thus, the display quality of the display device can be improved.

The first layer 112 included in the light-emitting device 130 and the first layer 112 included in the light-receiving device 150 can have the same structure. The first layers 112 are separated from each other in each subpixel. Similarly, the second layer 116 included in the light-emitting device 130 and the second layer 116 included in the light-receiving device 150 can have the same structure. The second layers 116 are separated from each other in each subpixel. Since the first layers 112 and the second layers 116 that are included in each subpixel are separated from one another, generation of leakage current between the light-emitting device and the light-receiving device, between the light-emitting devices, and between the light-receiving devices can be inhibited. Accordingly, the display quality and light detection accuracy of the display device can be improved.

The substrate 301 corresponds to the substrate 291 illustrated in FIG. 19A and FIG. 19B. A stacked-layer structure including the substrate 301 and the components thereover up to an insulating layer 255b corresponds to the layer 101 including a transistor in Embodiment 1.

The transistor 310 includes a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance regions 312 are regions where the substrate 301 is doped with an impurity, and function as one of a source and a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layer 241 and the conductive layer 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of a source and a drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255a is provided to cover the capacitor 240, and the insulating layer 255b is provided over the insulating layer 255a.

As each of the insulating layer 255a and the insulating layer 255b, a variety of inorganic insulating films such as an oxide insulating film, a nitride insulating film, an oxynitride insulating film, and a nitride oxide insulating film can be suitably used. As the insulating layer 255a, an oxide insulating film or an oxynitride insulating film, such as a silicon oxide film, a silicon oxynitride film, or an aluminum oxide film, is preferably used. As the insulating layer 255b, a nitride insulating film or a nitride oxide insulating film, such as a silicon nitride film or a silicon nitride oxide film, is preferably used. Specifically, it is preferred that a silicon oxide film be used as the insulating layer 255a and a silicon nitride film be used as the insulating layer 255b. The insulating layer 255b preferably has a function of an etching protective film. Alternatively, a nitride insulating film or a nitride oxide insulating film may be used as the insulating layer 255a, and an oxide insulating film or an oxynitride insulating film may be used as the insulating layer 255b. Although this embodiment describes an example in which a depressed portion is provided in the insulating layer 255b, a depressed portion is not necessarily provided in the insulating layer 255b.

The light-emitting device 130 and the light-receiving device 150 are provided over the insulating layer 255b. In this embodiment, the light-emitting device 130 and the light-receiving device 150 have a structure similar to that of the stacked-layer structure illustrated in FIG. 2A. The side surfaces of the pixel electrode 111, the first layer 112, the light-emitting layer 113, the active layer 155, and the second layer 116 are each covered with the insulating layer 125 and overlap with the insulating layer 127 with the insulating layer 125 provided therebetween. The common layer 114 is provided over the second layer 116, the insulating layer 125, and the insulating layer 127, and the common electrode 115 is provided over the common layer 114.

The pixel electrode 111 of the light-emitting device and the light-receiving device is electrically connected to one of the source and the drain of the transistor 310 through a plug 256 embedded in the insulating layer 255a and the insulating layer 255b, the conductive layer 241 embedded in the insulating layer 254, and the plug 271 embedded in the insulating layer 261. The top surface of the insulating layer 255b and the top surface of the plug 256 are level with or substantially level with each other. A variety of conductive materials can be used for the plugs.

The protective layer 131 is provided over the light-emitting device 130 and the light-receiving device 150. The coloring layer 132B is provided over the protective layer 131. The substrate 120 is bonded to the coloring layer 132B with the resin layer 122. Embodiment 1 can be referred to for the details of the light-emitting devices (or the light-receiving devices) and the components thereover up to the substrate 120. The substrate 120 corresponds to the substrate 292 in FIG. 19A.

The end portions of the top surfaces of the pixel electrodes 111 are not covered with insulating layers. Thus, the distance between adjacent light-emitting devices, the distance between adjacent light-receiving devices, and the distance between adjacent light-emitting device and the light-receiving device can be extremely shortened. Accordingly, the display device can have high resolution or high definition.

As illustrated in FIG. 20B and FIG. 20C, a lens array 133 may be provided. Using the lens array 133 enables light emitted from the light-emitting devices 130 to be collected. In addition, with the use of the lens array 133, the image capturing range of the light-receiving device 150 can be narrowed and overlap with the image capturing range of an adjacent light-receiving device 150 can be inhibited. Thus, a clear image with little blurring can be captured. In the case where the image capturing range of the light-receiving device 150 is unchanged, providing the lens array 133 allows the size of a pinhole to be increased, compared to the case where the lens array 133 is not provided. Hence, providing the lens array 133 can increase the amount of light entering the light-receiving device 150.

FIG. 20B illustrates an example in which the coloring layer 132B is provided over the light-emitting devices 130 with the protective layer 131 provided therebetween, an insulating layer 134 is provided over the coloring layer 132B, and the lens array 133 is provided over the insulating layer 134. The coloring layer 132B and the lens array 133 are directly formed over the substrate provided with the light-emitting devices 130, whereby the accuracy of positional alignment of the light-emitting device and the coloring layer or the lens array can be enhanced.

For the insulating layer 134, one or both of an inorganic insulating material and an organic insulating material can be used. The insulating layer 134 may have either a single-layer structure or a stacked-layer structure. The insulating layer 134 can be formed using a material that can be used for the protective layer 131, for example. When light emitted by the light-emitting device is extracted through the insulating layer 134, the insulating layer 134 preferably has a high visible-light-transmitting property.

In FIG. 20B, light emitted by the light-emitting device 130 passes through the coloring layer and then passes through the lens array 133, resulting in being extracted to the outside of the display device. It is preferable to shorten the distance between the light-emitting device and the coloring layer because color mixing can be inhibited and the viewing angle characteristics can be improved. Note that such a structure that the lens array 133 is provided over the light-emitting device 130 and the coloring layer is provided over the lens array 133 may be employed.

FIG. 20C illustrates an example in which the substrate 120 provided with the coloring layer 132B and the lens array 133 is bonded onto the protective layer 131 with the resin layer 122. The substrate 120 is provided with the coloring layer 132B and the lens array 133, whereby the heat treatment temperature in the forming step of them can be increased.

In the example of FIG. 20C, the coloring layer 132B is provided in contact with the substrate 120, the insulating layer 134 is provided in contact with the coloring layer 132B, and the lens array 133 is provided in contact with the insulating layer 134.

In FIG. 20C, light emitted by the light-emitting device 130 passes through the lens array 133 and then passes through the coloring layer 132B, resulting in being extracted to the outside of the display device. Note that such a structure that the lens array 133 is provided in contact with the substrate 120, the insulating layer 134 is provided in contact with the lens array 133, and the coloring layer 132B is provided in contact with the insulating layer 134 may be employed. In this case, light emitted by the light-emitting device 130 passes through the coloring layer 132B and then passes through the lens array 133, resulting in being extracted to the outside of the display device.

The lens array 133 may have a convex surface facing the substrate 120 side or a convex surface facing the light-emitting device 130 side.

The lens array 133 can be formed using at least one of an inorganic material and an organic material. For example, a material containing a resin can be used for the lens. Moreover, a material containing at least one of an oxide and a sulfide can be used for the lens. As the lens array 133, a microlens array can be used. The lens array 133 may be directly formed over the substrate or the light-emitting device. Alternatively, a lens array separately formed may be bonded thereto.

### [Display Device 100D]

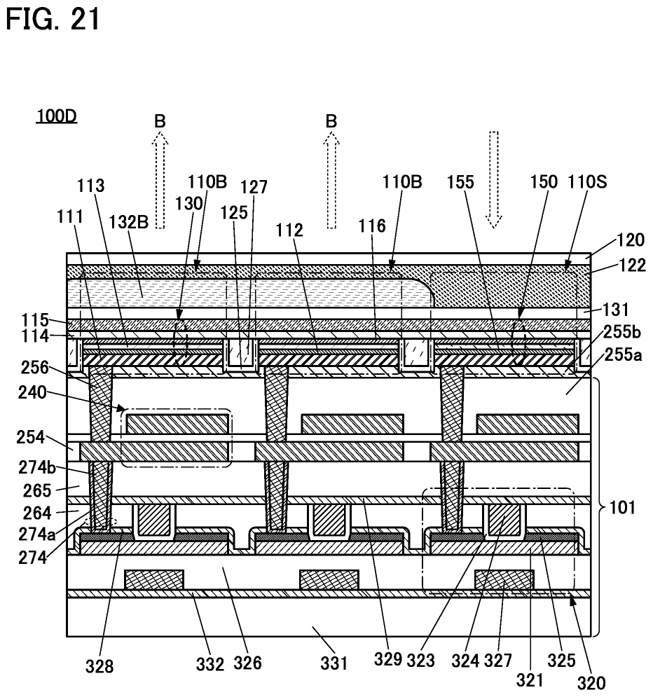

The display device 100D illustrated in FIG. 21 differs from the display device 100C mainly in a structure of a transistor. Note that in the following description of display devices, the description of portions similar to those of the above-described display devices may be omitted.

A transistor 320 is a transistor that contains a metal oxide (also referred to as an oxide semiconductor) in a semiconductor layer where a channel is formed (i.e., an OS transistor).

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 in FIG. 19A and FIG. 19B. A stacked-layer structure including the substrate 331 and the components thereover up to the insulating layer 255b corresponds to the layer 101 including a transistor in Embodiment 1. As the substrate 331, an insulating substrate or a semiconductor substrate can be used.

An insulating layer 332 is provided over the substrate 331. The insulating layer 332 functions as a barrier layer that prevents diffusion of impurities such as water or hydrogen from the substrate 331 into the transistor 320 and release of oxygen from the semiconductor layer 321 to the insulating layer 332 side. As the insulating layer 332, it is possible to use, for example, a film in which hydrogen or oxygen is less likely to diffuse than in a silicon oxide film, such as an aluminum oxide film, a hafnium oxide film, or a silicon nitride film.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 that is in contact with the semiconductor layer 321. The top surface of the insulating layer 326 is preferably planarized.

The semiconductor layer 321 is provided over the insulating layer 326. A metal oxide (also referred to as an oxide semiconductor) film having semiconductor characteristics is preferably used as the semiconductor layer 321.

The pair of conductive layers 325 is provided on and in contact with the semiconductor layer 321, and functions as a source electrode and a drain electrode.

An insulating layer 328 is provided to cover top and the side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water or hydrogen from the insulating layer 264 and the like into the semiconductor layer 321 and release of oxygen from the semiconductor layer 321. As the insulating layer 328, an insulating film similar to the insulating layer 332 can be used.

An opening reaching the semiconductor layer 321 is provided in the insulating layer 328 and the insulating layer 264. The insulating layer 323 that is in contact with the side surfaces of the insulating layer 264, the insulating layer 328, and the conductive layer 325, and the top surface of the semiconductor layer 321 and the conductive layer 324 are embedded in the opening. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so that they are level with or substantially level with each other, and an insulating layer 329 and an insulating layer 265 are provided to cover these layers.

The insulating layer 264 and the insulating layer 265 each function as an interlayer insulating layer. The insulating layer 329 functions as a barrier layer that prevents diffusion of impurities such as water or hydrogen from the insulating layer 265 and the like into the transistor 320. As the insulating layer 329, an insulating film similar to the insulating layer 328 and the insulating layer 332 can be used.

A plug 274 electrically connected to one of the pair of conductive layers 325 is provided to be embedded in the insulating layer 265, the insulating layer 329, and the insulating layer 264. Here, the plug 274 preferably includes a conductive layer 274a that covers the side surfaces of openings formed in the insulating layer 265, the insulating layer 329, the insulating layer 264, and the insulating layer 328 and part of the top surface of the conductive layer 325, and a conductive layer 274b in contact with the top surface of the conductive layer 274a. For the conductive layer 274a, a conductive material in which hydrogen and oxygen are less likely to diffuse is preferably used.

The structures of the insulating layer 254 and the components thereover up to the substrate 120 in the display device 100D are similar to those in the display device 100C.

### [Display Device 100E]

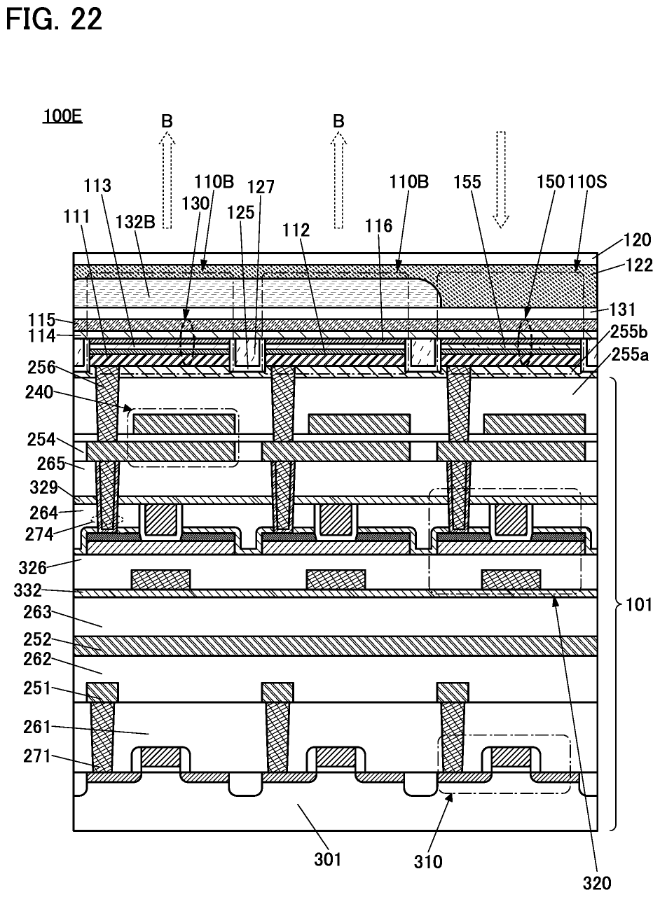

The display device 100E illustrated in FIG. 22 has a structure in which the transistor 310 whose channel is formed in the substrate 301 and the transistor 320 including a metal oxide in the semiconductor layer where the channel is formed are stacked.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layer 251 and the conductive layer 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit for driving the pixel circuit (a gate line driver circuit or a source line driver circuit). The transistor 310 and the transistor 320 can also be used as transistors included in a variety of circuits such as an arithmetic circuit and a memory circuit.

With such a structure, not only the pixel circuit but also the driver circuit and the like can be formed directly under the light-emitting devices and the light-receiving devices; thus, the display device can be downsized as compared with the case where a driver circuit is provided around a display portion.

### [Display Device 100F]

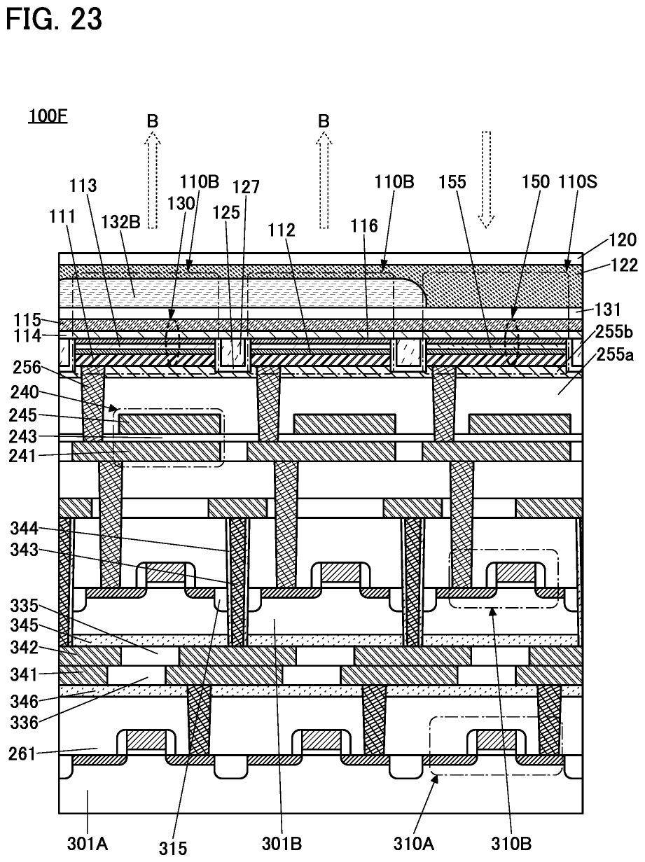

The display device 100F illustrated in FIG. 23 has a structure where a transistor 310A and a transistor 310B in each of which a channel is formed in a semiconductor substrate are stacked.

In the display device 100F, a substrate 301B provided with the transistor 310B, the capacitor 240, the light-receiving device, and the light-emitting devices is attached to a substrate 301A provided with the transistor 310A.

Here, an insulating layer 345 is preferably provided on the bottom surface of the substrate 301B. An insulating layer 346 is preferably provided over the insulating layer 261 over the substrate 301A. The insulating layers 345 and 346 function as protective layers and can inhibit diffusion of impurities into the substrate 301B and the substrate 301A. As the insulating layers 345 and 346, an inorganic insulating film that can be used as the protective layer 131 can be used.

The substrate 301B is provided with a plug 343 that penetrates the substrate 301B and the insulating layer 345. Here, an insulating layer 344 is preferably provided to cover the side surface of the plug 343. The insulating layer 344 functions as a protective layer and can inhibit diffusion of impurities into the substrate 301B. As the insulating layer 344, an inorganic insulating film that can be used as the protective layer 131 can be used.

A conductive layer 342 is provided under the insulating layer 345 on the rear surface of the substrate 301B (the surface opposite to the substrate 120). The conductive layer 342 is preferably provided to be embedded in an insulating layer 335. The bottom surfaces of the conductive layer 342 and the insulating layer 335 are preferably planarized. Here, the conductive layer 342 is electrically connected to the plug 343.

A conductive layer 341 is provided over the insulating layer 346 over the substrate 301A. The conductive layer 341 is preferably provided to be embedded in an insulating layer 336. The top surfaces of the conductive layer 341 and the insulating layer 336 are preferably planarized.

The conductive layer 341 and the conductive layer 342 are bonded to each other, whereby the substrate 301A and the substrate 301B are electrically connected to each other. Here, improving the flatness of a plane formed by the conductive layer 342 and the insulating layer 335 and a plane formed by the conductive layer 341 and the insulating layer 336 allows the conductive layer 341 and the conductive layer 342 to be bonded to each other favorably.

The conductive layer 341 and the conductive layer 342 are preferably formed using the same conductive material. For example, a metal film containing an element selected from A1, Cr, Cu, Ta, Ti, Mo, and W, or a metal nitride film containing any of the above elements as a component (a titanium nitride film, a molybdenum nitride film, or a tungsten nitride film) can be used. Copper is particularly preferably used for the conductive layer 341 and the conductive layer 342.

In that case, it is possible to employ a Cu-to-Cu (copper-to-copper) direct bonding technique (a technique for achieving electrical continuity by connecting Cu (copper) pads).

### [Display Device 100G]

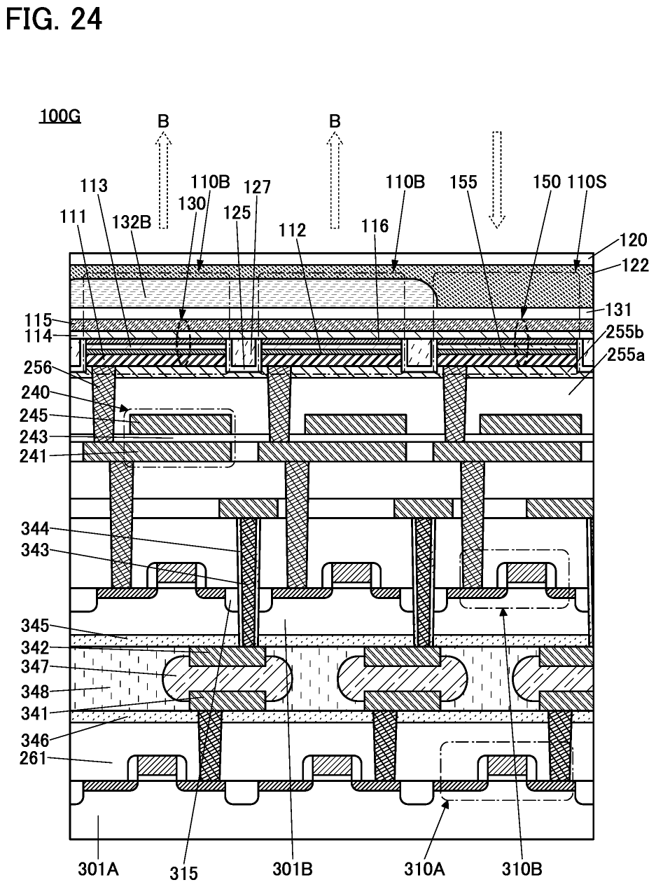

Although FIG. 23 illustrates an example in which Cu-to-Cu direct bonding technique is used to bond the conductive layer 341 and the conductive layer 342, the present invention is not limited thereto. As illustrated in FIG. 24, the conductive layer 341 and the conductive layer 342 may be bonded to each other through a bump 347 in the display device 100G.

As illustrated in FIG. 24, providing the bump 347 between the conductive layer 341 and the conductive layer 342 enables the conductive layer 341 and the conductive layer 342 to be electrically connected to each other. The bump 347 can be formed using a conductive material containing gold (Au), nickel (Ni), indium (In), tin (Sn), or the like, for example. As another example, solder may be used for the bump 347. An adhesive layer 348 may be provided between the insulating layer 345 and the insulating layer 346. In the case where the bump 347 is provided, the insulating layer 335 and the insulating layer 336 may be omitted.

This embodiment can be combined with any of the other embodiments as appropriate.

### Embodiment 4

In this embodiment, a light-emitting device that can be used in the display device of one embodiment of the present invention will be described.

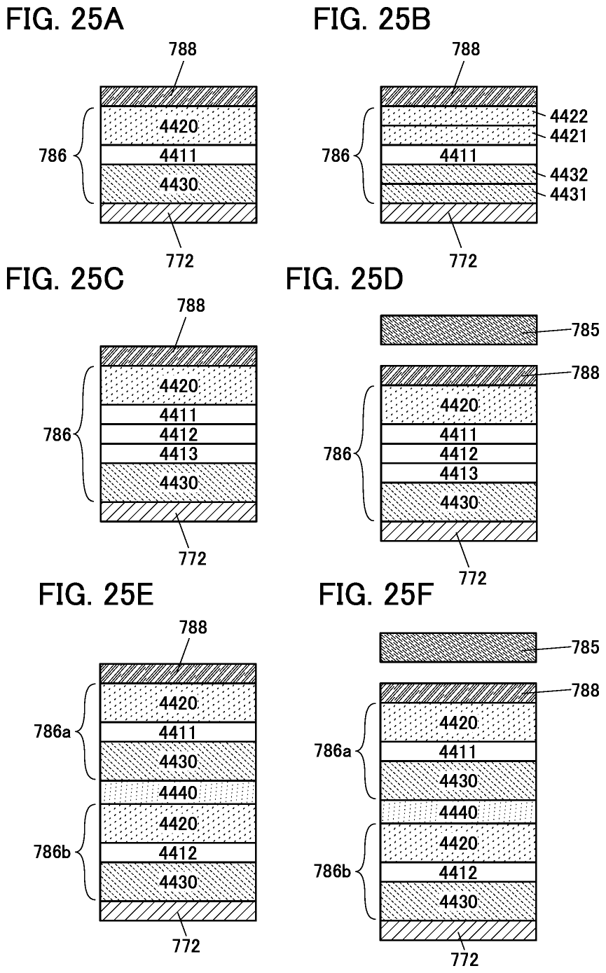

As illustrated in FIG. 25A, the light-emitting device includes an EL layer 786 between a pair of electrodes (a lower electrode 772 and an upper electrode 788). The EL layer 786 can be formed of a plurality of layers such as a layer 4420, a light-emitting layer 4411, and a layer 4430. The layer 4420 can include, for example, a layer containing a substance with a high electron-injection property (an electron-injection layer) and a layer containing a substance with a high electron-transport property (an electron-transport layer). The light-emitting layer 4411 contains a light-emitting compound, for example. The layer 4430 can include, for example, a layer containing a substance with a high hole-injection property (a hole-injection layer) and a layer containing a substance with a high hole-transport property (a hole-transport layer).

The structure including the layer 4420, the light-emitting layer 4411, and the layer 4430, which is provided between a pair of electrodes, can function as a single light-emitting unit, and the structure in FIG. 25A is referred to as a single structure in this specification.

FIG. 25B is a variation example of the EL layer 786 included in the light-emitting device illustrated in FIG. 25A. Specifically, the light-emitting device illustrated in FIG. 25B includes a layer 4431 over the lower electrode 772, a layer 4432 over the layer 4431, the light-emitting layer 4411 over the layer 4432, a layer 4421 over the light-emitting layer 4411, a layer 4422 over the layer 4421, and the upper electrode 788 over the layer 4422. For example, when the lower electrode 772 is an anode and the upper electrode 788 is a cathode, the layer 4431 functions as a hole-injection layer, the layer 4432 functions as a hole-transport layer, the layer 4421 functions as an electron-transport layer, and the layer 4422 functions as an electron-injection layer. Alternatively, when the lower electrode 772 is a cathode and the upper electrode 788 is an anode, the layer 4431 functions as an electron-injection layer, the layer 4432 functions as an electron-transport layer, the layer 4421 functions as a hole-transport layer, and the layer 4422 functions as a hole-injection layer. With such a layered structure, carriers can be efficiently injected to the light-emitting layer 4411, and the efficiency of the recombination of carriers in the light-emitting layer 4411 can be enhanced.

Note that structures in which a plurality of light-emitting layers (light-emitting layers 4411, 4412, and 4413) are provided between the layer 4420 and the layer 4430 as illustrated in FIG. 25C and FIG. 25D are other variations of the single structure.

Structures in which a plurality of light-emitting units (an EL layer 786a and an EL layer 786b) are connected in series with a charge-generation layer 4440 therebetween as illustrated in FIG. 25E and FIG. 25F are referred to as a tandem structure in this specification. A tandem structure may be referred to as a stack structure. The tandem structure enables a light-emitting device capable of high luminance light emission.

In FIG. 25C and FIG. 25D, light-emitting materials that emit light of the same color, or moreover, the same light-emitting material may be used for the light-emitting layer 4411, the light-emitting layer 4412, and the light-emitting layer 4413. For example, a light-emitting material that emits blue light may be used for the light-emitting layer 4411, the light-emitting layer 4412, and the light-emitting layer 4413. A color conversion layer may be provided as a layer 785 illustrated in FIG. 25D.

Alternatively, light-emitting materials that emit light of different colors may be used for the light-emitting layer 4411, the light-emitting layer 4412, and the light-emitting layer 4413. White light can be obtained when the light-emitting layer 4411, the light-emitting layer 4412, and the light-emitting layer 4413 emit light of complementary colors. A color filter (also referred to as a coloring layer) may be provided as the layer 785 illustrated in FIG. 25D. When white light passes through a color filter, light of a desired color can be obtained.

In FIG. 25E and FIG. 25F, light-emitting materials that emit light of the same color, or moreover, the same light-emitting material may be used for the light-emitting layer 4411 and the light-emitting layer 4412. Alternatively, light-emitting materials that emit light of different colors may be used for the light-emitting layer 4411 and the light-emitting layer 4412. White light can be obtained when the light-emitting layer 4411 and the light-emitting layer 4412 emit light of complementary colors. FIG. 25F illustrates an example in which the layer 785 is further provided. One or both of a color conversion layer and a color filter (a coloring layer) can be used as the layer 785.

In FIG. 25C, FIG. 25D, FIG. 25E, and FIG. 25F, the layer 4420 and the layer 4430 may each have a stacked-layered structure of two or more layers as in FIG. 25B.

A structure in which light-emitting devices of different emission colors (e.g., blue (B), green (G), and red (R)) are separately formed is referred to as an SBS (Side By Side) structure in some cases.

The emission color of the light-emitting device can be changed to red, green, blue, cyan, magenta, yellow, white, or the like depending on the material of the EL layer 786. When the light-emitting device has a microcavity structure, the color purity can be further increased.

In the light-emitting device that emits white light, the light-emitting layer preferably contains two or more kinds of light-emitting substances. In order to obtain white light, light-emitting substances may be selected so that colors of light emitted by the two light-emitting substances are complementary colors, or light-emitting substances may be selected so that colors of light emitted by two or more light-emitting substances are combined to be white. For example, in the case where white light is obtained with use of two light-emitting layers, the emission colors of the two light-emitting layers are complementary, so that the light-emitting device can emit white light as a whole. In the case where three or more light-emitting layers are used to obtain white light emission, a light-emitting device is configured to emit white light as a whole by combining emission colors of the three or more light-emitting layers.

The light-emitting layer preferably contains two or more selected from light-emitting substances that emit light of R (red), G (green), B (blue), Y (yellow), O (orange), and the like. Alternatively, the light-emitting layer preferably contains two or more light-emitting substances that emit light containing two or more of spectral components of R, G, and B.

This embodiment can be combined with any of the other embodiments as appropriate.

### Embodiment 5

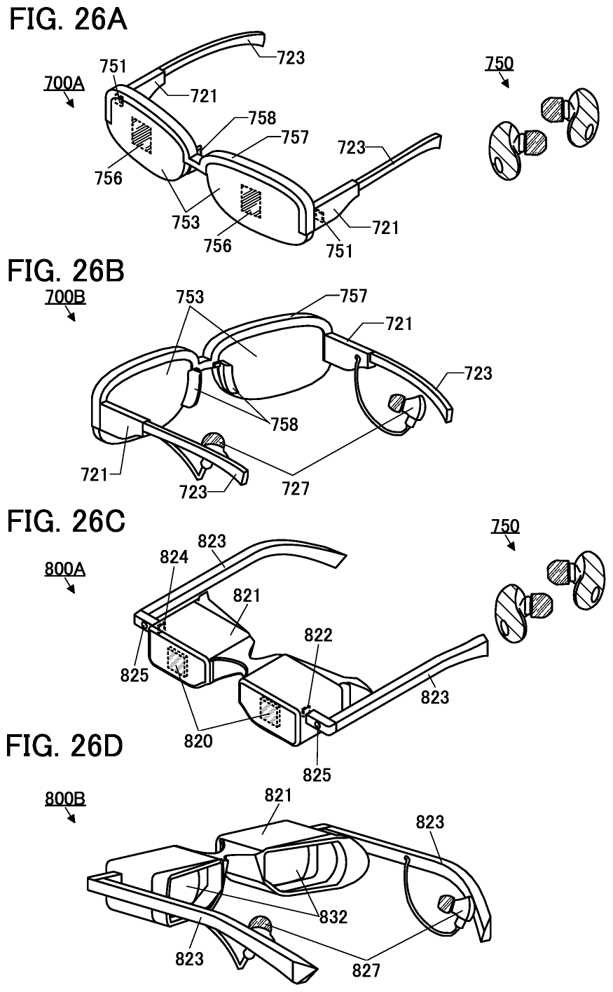

In this embodiment, electronic devices of one embodiment of the present invention will be described with reference to FIG. 26 to FIG. 29.

Electronic devices of this embodiment are each provided with the display device of one embodiment of the present invention in a display portion. The display device of one embodiment of the present invention can be easily increased in resolution and definition. Thus, the display device of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and laptop personal computers, a monitor of a computer and the like, digital signage, and a large game machine such as a pachinko machine.

In particular, the display device of one embodiment of the present invention can have a high resolution, and thus can be suitably used for an electronic device having a relatively small display portion. Examples of such an electronic device include watch-type and bracelet-type information terminal devices (wearable devices) and wearable devices worn on the head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680× 4320). In particular, a definition of 4K, 8K, or higher is preferable. The pixel density (resolution) of the display device of one embodiment of the present invention is preferably 100 ppi or higher, further preferably 300 ppi or higher, further preferably 500 ppi or higher, further preferably 1000 ppi or higher, still further preferably 2000 ppi or higher, still further preferably 3000 ppi or higher, still further preferably 5000 ppi or higher, yet further preferably 7000 ppi or higher. The use of the display device having one or both of such high definition and high resolution can further increase realistic sensation, sense of depth, and the like in personal use such as portable use and home use. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device in this embodiment can have a function of displaying a variety of data (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of head-mounted wearable devices will be described with reference to FIG. 26A to FIG. 26D. These wearable devices have one or both of a function of displaying AR contents and a function of displaying VR contents. Note that these wearable devices may have a function of displaying SR or MR contents, in addition to AR and VR contents. The electronic device having a function of displaying contents of AR, VR, SR, MR, or the like enables the user to reach a higher level of immersion.

An electronic device 700A illustrated in FIG. 26A and an electronic device 700B illustrated in FIG. 26B each include a pair of display panels 751, a pair of housings 721, a communication portion (not illustrated), a pair of mounting portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic devices are capable of performing ultrahigh-resolution display.

The electronic device 700A and the electronic device 700B can each project images displayed on the display panels 751 onto display regions 756 of the optical members 753. Since the optical members 753 have a light-transmitting property, the user can see images displayed on the display regions 756, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be detected and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic device 700A and the electronic device 700B are provided with a battery so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

An electronic device 800A illustrated in FIG. 26C and an electronic device 800B illustrated in FIG. 26D each include a pair of display portions 820, a housing 821, a communication portion 822, a pair of mounting portions 823, a control portion 824, a pair of image capturing portions 825, and a pair of lenses 832.

The display device of one embodiment of the present invention can be used in the display portions 820. Thus, the electronic devices are capable of performing ultrahigh-resolution display. Such electronic devices can provide an enhanced sense of immersion to the user.

The display portions 820 are positioned inside the housing 821 so as to be seen through the lenses 832. When the pair of display portions 820 display different images, three-dimensional display using parallax can also be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B preferably include a mechanism for adjusting focus by changing the distance between the lenses 832 and the display portions 820.

The electronic device 800A or the electronic device 800B can be mounted on the user's head with the mounting portions 823. FIG. 26C and the like illustrate examples where the mounting portion 823 has a shape like a temple (also referred to as a joint or the like) of glasses; however, one embodiment of the present invention is not limited thereto. The mounting portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

Although an example where the image capturing portion 825 is provided is described here, a range sensor capable of measuring a distance between the user and an object (hereinafter also referred to as a detecting portion) just needs to be provided. In other words, the image capturing portion 825 is one embodiment of the detecting portion. As the detecting portion, an image sensor or a range image sensor such as LIDAR (Light Detection and Ranging) can be used, for example. By using images obtained by the camera and images obtained by the range image sensor, more information can be obtained and a gesture operation with higher accuracy is possible.

The electronic device 800A may include a vibration mechanism that functions as bone-conduction earphones. For example, at least one of the display portion 820, the housing 821, and the mounting portion 823 can include the vibration mechanism. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, power for charging the battery provided in the electronic device, and the like can be connected.

The electronic device of one embodiment of the present invention may have a function of performing wireless communication with earphones 750. The earphones 750 include a communication portion (not illustrated) and has a wireless communication function. The earphones 750 can receive information (e.g., audio data) from the electronic device with the wireless communication function. For example, the electronic device 700A in FIG. 26A has a function of transmitting information to the earphones 750 with the wireless communication function. As another example, the electronic device 800A in FIG. 26C has a function of transmitting information to the earphones 750 with the wireless communication function.

The electronic device may include an earphone portion. The electronic device 700B in FIG. 26B includes earphone portions 727. For example, the earphone portion 727 can be connected to the control portion by wire. Part of a wiring that connects the earphone portion 727 and the control portion may be positioned inside the housing 721 or the mounting portion 723.

Similarly, the electronic device 800B in FIG. 26D includes earphone portions 827. For example, the earphone portion 827 can be connected to the control portion 824 by wire. Part of a wiring that connects the earphone portion 827 and the control portion 824 may be positioned inside the housing 821 or the mounting portion 823. Alternatively, the earphone portions 827 and the mounting portions 823 may include magnets. This is preferred because the earphone portions 827 can be fixed to the mounting portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

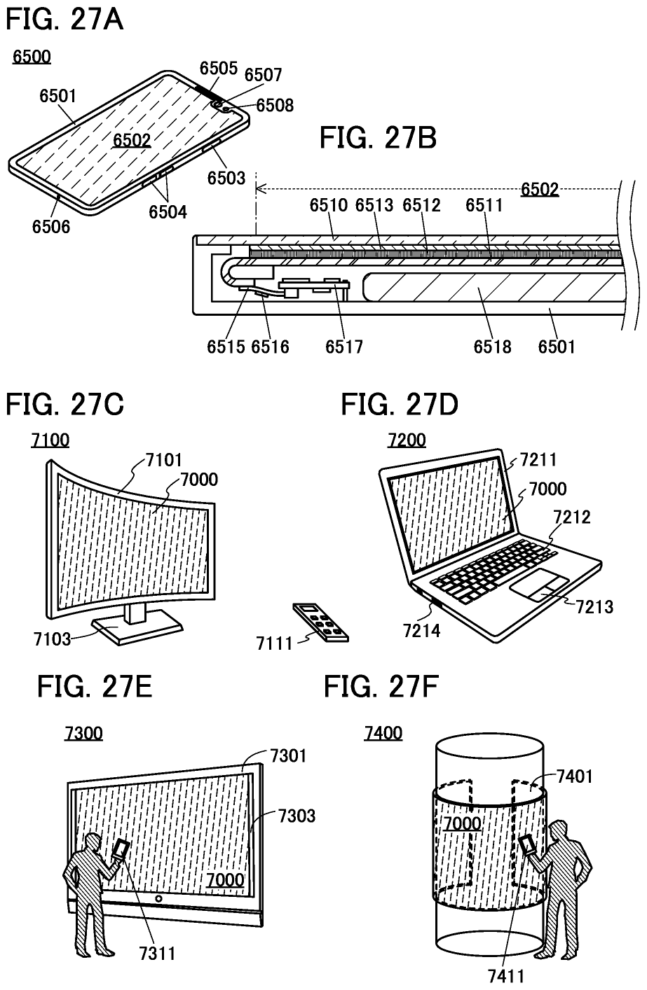

An electronic device 6500 illustrated in FIG. 27A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display device of one embodiment of the present invention can be used in the display portion 6502.

FIG. 27B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of the pixel portion, whereby an electronic device with a narrow bezel can be achieved.

FIG. 27C illustrates an example of a television device. In a television device 7100, a display portion 7000 is incorporated in a housing 7101. Here, the housing 7101 is supported by a stand 7103.

The display device of one embodiment of the present invention can be used in the display portion 7000.

Operation of the television device 7100 illustrated in FIG. 27C can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be operated and videos displayed on the display portion 7000 can be operated.

Note that the television device 7100 includes a receiver, a modem, and the like. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 27D illustrates an example of a laptop personal computer. A laptop personal computer 7200 includes a housing 7211, a keyboard 7212, a pointing device 7213, an external connection port 7214, and the like. The display portion 7000 is incorporated in the housing 7211.

The display device of one embodiment of the present invention can be used in the display portion 7000.

FIG. 27E and FIG. 27F illustrate examples of digital signage.

Digital signage 7300 illustrated in FIG. 27E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 27F is digital signage 7400 attached to a cylindrical pillar 7401. The digital signage 7400 includes the display portion 7000 provided along a curved surface of the pillar 7401.

The display device of one embodiment of the present invention can be used in the display portion 7000 illustrated in each of FIG. 27E and FIG. 27F.

A larger area of the display portion 7000 can increase the amount of data that can be provided at a time. The larger display portion 7000 attracts more attention, so that the effectiveness of the advertisement can be increased, for example.

The use of a touch panel in the display portion 7000 is preferable because in addition to display of an image or a moving image on the display portion 7000, intuitive operation by a user is possible. Moreover, for an application for providing information such as route information or traffic information, usability can be enhanced by intuitive operation.

As illustrated in FIG. 27E and FIG. 27F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

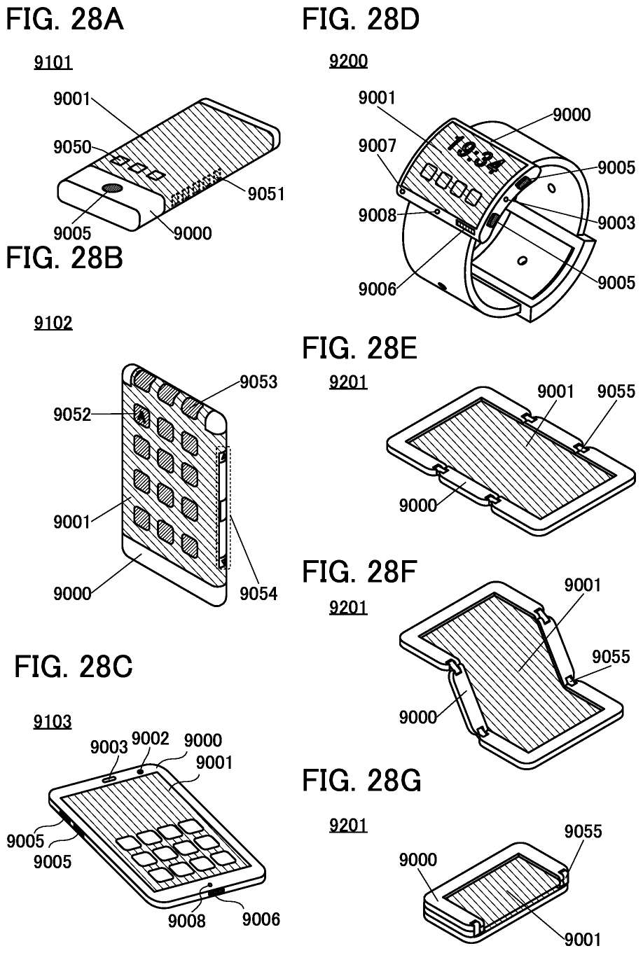

Electronic devices illustrated in FIG. 28A to FIG. 28G each include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, chemical substance, sound, time, hardness, electric field, current, voltage, power, radiation, flow rate, humidity, gradient, oscillation, odor, or infrared rays), a microphone 9008, and the like.

In FIG. 28A to FIG. 28G, the display device of one embodiment of the present invention can be used in the display portion 9001.

The electronic devices illustrated in FIG. 28A to FIG. 28G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. The electronic devices may be provided with a camera or the like and have a function of capturing a still image or a moving image, a function of storing the captured image in a storage medium (an external storage medium or a storage medium incorporated in the camera), a function of displaying the captured image on the display portion, and the like.

The electronic devices illustrated in FIG. 28A to FIG. 28G will be described in detail below.

FIG. 28A is a perspective view of a portable information terminal 9101. The portable information terminal 9101 can be used as a smartphone, for example. The portable information terminal 9101 may include the speaker 9003, the connection terminal 9006, the sensor 9007, or the like. The portable information terminal 9101 can display text and image information on its plurality of surfaces. FIG. 28A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 28B is a perspective view of a portable information terminal 9102. The portable information terminal 9102 has a function of displaying information on three or more surfaces of the display portion 9001. Here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. Thus, the user can see the display without taking out the portable information terminal 9102 from the pocket and decide whether to answer the call, for example.

FIG. 28C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 28D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIG. 28E to FIG. 28G are perspective views of a foldable portable information terminal 9201. FIG. 28E is a perspective view illustrating the portable information terminal 9201 that is opened. FIG. 28G is a perspective view illustrating the portable information terminal 9201 that is folded. FIG. 28F is a perspective view illustrating the portable information terminal 9201 that is shifted from one of the states in FIG. 28E and FIG. 28G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

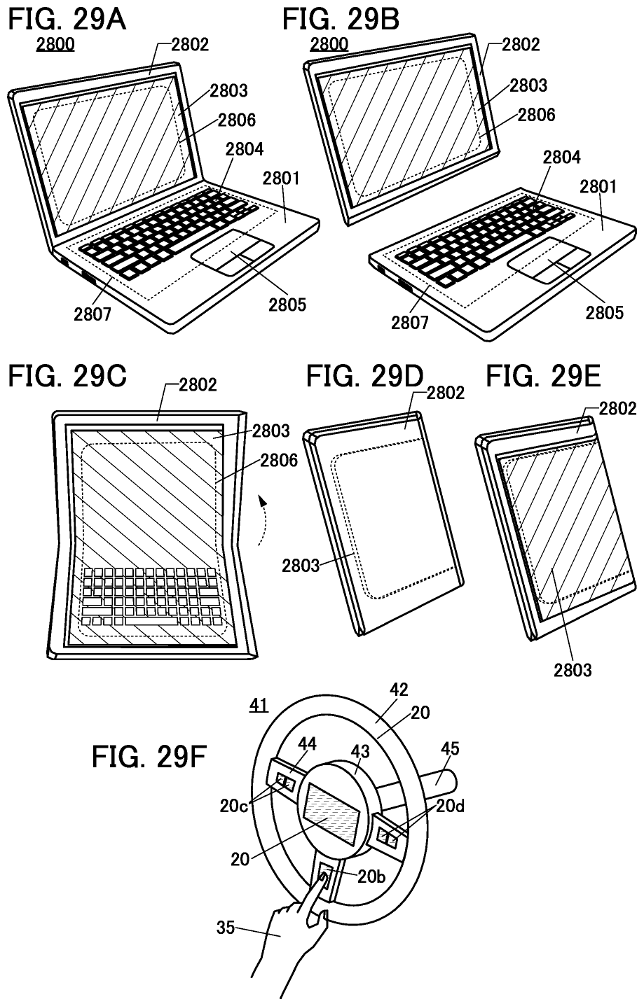

A personal computer 2800 illustrated in FIG. 29A includes a housing 2801, a housing 2802, a display portion 2803, a keyboard 2804, a pointing device 2805, and the like. A secondary battery 2807 is provided inside the housing 2801 and a secondary battery 2806 is provided inside the housing 2802. The display portion 2803 is the display device of one embodiment of the present invention, and has a touch panel function. As illustrated in FIG. 29B, the housing 2801 and the housing 2802 of the personal computer 2800 can be separated and the housing 2802 can be used alone as a tablet terminal.

In a variation example of a personal computer illustrated in FIG. 29C, a flexible display is employed for the display portion 2803. With use of a flexible film as an exterior body, the secondary battery 2806 can be bendable secondary battery. Accordingly, the housing 2802, the display portion 2803, and the secondary battery 2806 can be used in a bent state as illustrated in FIG. 29C. At this time, part of the display portion 2803 can also be used as a keyboard as illustrated in FIG. 29C.

Furthermore, the housing 2802 can be folded so that the display portion 2803 is placed inward as illustrated in FIG. 29D, and the housing 2802 can be folded so that the display portion 2803 faces outward as illustrated in FIG. 29E.

FIG. 29F is a perspective view of a steering wheel of a vehicle. A steering wheel 41 includes a rim 42, a hub 43, spokes 44, a shaft 45, and the like. A display portion 20 is provided on the surface of the hub 43. The display device of one embodiment of the present invention can be used in the display portion 20. The three spokes 44 are each provided with a light-emitting and light-receiving portion. Specifically, the spoke 44 located on the lower side is provided with a light-emitting and light-receiving portion 20b; the spoke 44 located on the left side is provided with a plurality of light-emitting and light-receiving portions 20c; and the spoke 44 located on the right side is provided with a plurality of light-emitting and light-receiving portions 20d. When a driver holds a finger of a hand 35 over the light-receiving and light-emitting portion 20b, information on a fingerprint of the driver is acquired, and user authentication can be performed with the information. Touching the light-emitting and light-receiving portion 20c and the light-emitting and light-receiving portion 20d and the like, the driver can operate systems such as a navigation system, an audio system, and a call system provided in the vehicle. In addition, a variety of operations such as adjustment of a rearview mirror and a sideview mirror, turning on/off of an interior light, adjustment of luminance, and opening/closing a window are possible.

This embodiment can be combined with any of the other embodiments as appropriate.

### REFERENCE NUMERALS

La: light, Lb: light, Lc: light, 20b: light-emitting and light-receiving portion, 20c: light-emitting and light-receiving portion, 20d: light-emitting and light-receiving portion, 20: display portion, 35: hand, 41: steering wheel, 42: rim, 43: hub, 44: spoke, 45: shaft, 100A: display device, 100B: display device, 100C: display device, 100D: display device, 100E: display device, 100F: display device, 100G: display device, 100: display device, 101: layer, 103[1,1]: pixel, 103[1,2]: pixel, 103[1,3]: pixel, 103[1,4]: pixel, 103[2,1]: pixel, 103[2,2]: pixel, 103[2,3]: pixel, 103[2,4]: pixel, 103[3,2]: pixel, 103[3,3]: pixel, 103: pixel, 110a: subpixel, 110B: subpixel, 110b: subpixel, 110c: subpixel, 110d: subpixel, 110G: subpixel, 110R: subpixel, 110S: subpixel, 110: subpixel, 111a: pixel electrode, 111b: pixel electrode, 111: pixel electrode, 112A: first layer, 112: first layer, 113A: light-emitting layer, 113a: light-emitting layer, 113B: light-emitting layer, 113b: light-emitting layer, 113c: light-emitting layer, 113: light-emitting layer, 114: common layer, 115: common electrode, 116A: second layer, 116: second layer, 117: light-blocking layer, 118A: sacrificial layer, 118: sacrificial layer, 119A: sacrificial layer, 119: sacrificial layer, 120: substrate, 121: insulating layer, 122: resin layer, 123: conductive layer, 125A: insulating film, 125: insulating layer, 126: conductive layer, 127A: insulating film, 127: insulating layer, 128: layer, 129: conductive layer, 130: light-emitting device, 131: protective layer, 132a: coloring layer, 132B: coloring layer, 132b: coloring layer, 132c: coloring layer, 132R: coloring layer, 133: lens array, 134: insulating layer, 138: region, 139: region, 140: connection portion, 142: adhesive layer, 150: light-receiving device, 151: substrate, 152: substrate, 153: insulating layer, 155A: active layer, 155: active layer, 162: display portion, 164: circuit, 165: wiring, 166: conductive layer, 172: FPC, 173: IC, 181a: nozzle, 181b: nozzle, 182a: droplet, 182b: droplet, 190: resist mask, 191a: fine metal mask, 191b: fine metal mask, 191c: fine metal mask, 191d: fine metal mask, 192: mask, 201: transistor, 204: connection portion, 205: transistor, 209: transistor, 210: transistor, 211: insulating layer, 213: insulating layer, 214: insulating layer, 215: insulating layer, 218: insulating layer, 221: conductive layer, 222a: conductive layer, 222b: conductive layer, 223: conductive layer, 225: insulating layer, 231i: channel formation region, 231n: low-resistance region, 231: semiconductor layer, 240: capacitor, 241: conductive layer, 242: connection layer, 243: insulating layer, 245: conductive layer, 251: conductive layer, 252: conductive layer, 254: insulating layer, 255a: insulating layer, 255b: insulating layer, 256: plug, 261: insulating layer, 262: insulating layer, 263: insulating layer, 264: insulating layer, 265: insulating layer, 271: plug, 274a: conductive layer, 274b: conductive layer, 274: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301A: substrate, 301B: substrate, 301: substrate, 310A: transistor, 310B: transistor, 310: transistor, 311: conductive layer, 312: low-resistance region, 313: insulating layer, 314: insulating layer, 315: element isolation layer, 320: transistor, 321: semiconductor layer, 323: insulating layer, 324: conductive layer, 325: conductive layer, 326: insulating layer, 327: conductive layer, 328: insulating layer, 329: insulating layer, 331: substrate, 332: insulating layer, 335: insulating layer, 336: insulating layer, 341: conductive layer, 342: conductive layer, 343: plug, 344: insulating layer, 345: insulating layer, 346: insulating layer, 347: bump, 348: adhesive layer, 700A: electronic device, 700B: electronic device, 721: housing, 723: mounting portion, 727: earphone portion, 750: earphone, 751: display panel, 753: optical member, 756: display region, 757: frame, 758: nose pad, 772: lower electrode, 785: layer, 786a: EL layer, 786b: EL layer, 786: EL layer, 788: upper electrode, 800A: electronic device, 800B: electronic device, 820: display portion, 821: housing, 822: communication portion, 823: mounting portion, 824: control portion, 825: image capturing portion, 827: earphone portion, 832: lens, 2800: personal computer, 2801: housing, 2802: housing, 2803: display portion, 2804: keyboard, 2805: pointing device, 2806: secondary battery, 2807: secondary battery, 4411: light-emitting layer, 4412: light-emitting layer, 4413: light-emitting layer, 4420: layer, 4421: layer, 4422: layer, 4430: layer, 4431: layer, 4432: layer, 4440: charge-generation layer, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote controller, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display device comprising a first subpixel, a second subpixel, a third subpixel, and a fourth subpixel, which are arranged to be adjacent to one another in this order in a first direction,
wherein the first subpixel and the second subpixel emit light of the same color,
wherein the third subpixel and the fourth subpixel sense light of the same color,
wherein the first subpixel comprises a first light-emitting device and a first coloring layer overlapping with the first light-emitting device,
wherein the second subpixel comprises a second light-emitting device and the first coloring layer overlapping with the second light-emitting device,
wherein the third subpixel comprises a first light-receiving device,
wherein the fourth subpixel comprises a second light-receiving device,
wherein the first light-emitting device and the second light-emitting device are configured to be driven independently, and
wherein the first light-receiving device and the second light-receiving device are configured to be driven independently.

2. A display device comprising:
a first subpixel, a second subpixel, a third subpixel, and a fourth subpixel, which are arranged to be adjacent to one another in this order in a first direction; and
the first subpixel, a fifth subpixel, a sixth subpixel, and a seventh subpixel, which are arranged to be adjacent to one another in this order in a second direction,
wherein the first direction and the second direction intersect with each other,
wherein the first subpixel, the second subpixel, and the fifth subpixel emit light of a first color,
wherein the third subpixel and the fourth subpixel sense light of the same color,
wherein the sixth subpixel and the seventh subpixel emit light of a second color,
wherein the first color and the second color are different from each other,
wherein the first subpixel comprises a first light-emitting device and a first coloring layer overlapping with the first light-emitting device,
wherein the second subpixel comprises a second light-emitting device and the first coloring layer overlapping with the second light-emitting device,
wherein the third subpixel comprises a first light-receiving device,
wherein the fourth subpixel comprises a second light-receiving device,
wherein the fifth subpixel comprises a third light-emitting device and the first coloring layer overlapping with the third light-emitting device,
wherein the sixth subpixel comprises a fourth light-emitting device and a second coloring layer overlapping with the fourth light-emitting device,
wherein the seventh subpixel comprises a fifth light-emitting device and the second coloring layer overlapping with the fifth light-emitting device,
wherein the first to fifth light-emitting devices are configured to emit light of the same color,
wherein the first to fifth light-emitting devices are configured to be driven independently,
wherein the first light-receiving device and the second light-receiving device are configured to be driven independently, and
wherein the first coloring layer and the second coloring layer transmit light of different colors.

3. A display device comprising a first subpixel, a second subpixel, a third subpixel, a fourth subpixel, a fifth subpixel, and a sixth subpixel,
wherein the first subpixel, the second subpixel, and the third subpixel emit light of the same color,
wherein the fourth subpixel, the fifth subpixel, and the sixth subpixel sense light of the same color,
wherein the first subpixel is adjacent to the second subpixel in a first direction and is adjacent to the third subpixel in a second direction,
wherein the fourth subpixel is adjacent to the fifth subpixel in the first direction and is adjacent to the sixth subpixel in the second direction,
wherein the first direction and the second direction intersect with each other,
wherein the first subpixel comprises a first light-emitting device and a first coloring layer overlapping with the first light-emitting device,
wherein the second subpixel comprises a second light-emitting device and the first coloring layer overlapping with the second light-emitting device,
wherein the third subpixel comprises a third light-emitting device and the first coloring layer overlapping with the third light-emitting device,
wherein the fourth subpixel comprises a first light-receiving device,
wherein the fifth subpixel comprises a second light-receiving device,
wherein the sixth subpixel comprises a third light-receiving device,
wherein the first to third light-emitting devices are configured to emit light of the same color,
wherein the first to third light-emitting devices are configured to be driven independently, and
wherein the first to third light-receiving devices are configured to be driven independently.

4. The display device according to claim 1, wherein the first light-emitting device emits white light.

5. The display device according to claim 1,
wherein the first light-emitting device comprises an island-shaped first EL layer, and
wherein the second light-emitting device comprises an island-shaped second EL layer.

6. The display device according to claim 5, further comprising an insulating layer,
wherein the insulating layer covers at least part of a side surface of the first EL layer and at least part of a side surface of the second EL layer.

7. The display device according to claim 6,
wherein the insulating layer comprises an inorganic insulating layer in contact with at least part of the side surface of the first EL layer and at least part of the side surface of the second EL layer.

8. The display device according to claim 7,
wherein the insulating layer comprises an organic insulating layer overlapping with at least part of the side surface of the first EL layer and at least part of the side surface of the second EL layer.

9. The display device according to claim 5,
wherein the first light-emitting device comprises a common layer over the first EL layer,
wherein the second light-emitting device comprises the common layer over the second EL layer, and
wherein the common layer comprises at least one of a hole-injection layer, a hole-transport layer, a hole-blocking layer, an electron-blocking layer, an electron-transport layer, and an electron-injection layer.

10. A display module comprising:
the display device according to claim 1; and
at least one of a connector and an integrated circuit.

11. An electronic device comprising:
the display module according to claim 10; and
at least one of a housing, a battery, a camera, a speaker, and a microphone.

12. A method for manufacturing a display device, the method comprising the steps of:
forming a first pixel electrode, a second pixel electrode, a third pixel electrode, and a fourth pixel electrode so as to be arranged in this order in a first direction:
forming a first film comprising a light-emitting layer over the first pixel electrode and the second pixel electrode using a first metal mask;
forming a second film comprising an active layer over the third pixel electrode and the fourth pixel electrode using a second metal mask;
processing the first film and the second film using a photolithography method to form a first layer over the first pixel electrode, a second layer over the second pixel electrode, a third layer over the third pixel electrode, and a fourth layer over the fourth pixel electrode;
forming a common electrode over the first layer, the second layer, the third layer, and the fourth layer; and
providing a coloring layer overlapping with the first pixel electrode and the second pixel electrode over the common electrode.

13. The display device according to claim 2, wherein the first light-emitting device emits white light.

14. The display device according to claim 2,
wherein the first light-emitting device comprises an island-shaped first EL layer, and
wherein the second light-emitting device comprises an island-shaped second EL layer.

15. A display module comprising:
the display device according to claim 2; and
at least one of a connector and an integrated circuit.

16. The display device according to claim 3, wherein the first light-emitting device emits white light.

17. The display device according to claim 3,
wherein the first light-emitting device comprises an island-shaped first EL layer, and
wherein the second light-emitting device comprises an island-shaped second EL layer.

18. A display module comprising:
the display device according to claim 3; and
at least one of a connector and an integrated circuit.
